(19) United States
(12) Patent Application Publication
(10) Pub. No.: US 2016/0071992 A1
(43) Pub. Date: Mar. 10, 2016

(54) BACK SHEET FOR SOLAR CELLS AND SOLAR CELL MODULE

(71) Applicant: FUJIFILM Corporation, Tokyo (JP)

(72) Inventors: HIDEKI TOMIZAWA, SHIZUOKA (JP); NAOHIRO MATSUNAGA, SHIZUOKA (JP); NAOKI KOITO, SHIZUOKA (JP)

(73) Assignee: FUJIFILM Corporation, Tokyo (JP)

(21) Appl. No.: 14/872,143

(22) Filed: Oct. 1, 2015

Related U.S. Application Data
(63) Continuation of application No. PCT/JP2014/057617, filed on Mar. 19, 2014.

(30) Foreign Application Priority Data
Apr. 3, 2013 (JP) 2013-078078
Aug. 16, 2013 (JP) 2013-169244
Dec. 26, 2013 (JP) 2013-269889

(51) Int. Cl. H01L 31/049; H01L 31/048

(52) U.S. Cl. CPC H01L 31/049; H01L 31/0481

(57) ABSTRACT

Disclosed is a back sheet for solar cells including a supporter and an A layer including at least a nonionic surfactant which has an ethylene glycol chain but does not have a carbon-carbon triple bond on at least one surface side of the supporter, in which the surface resistance value SR on the side provided with the A layer is in a range of 1.0×10¹⁰Ω/□ to 5.5×10¹⁵Ω/□, and the improvement of the partial discharge voltage and the adhesiveness to an encapsulating material that encapsulates a solar cell are both achieved and a solar cell module including the back sheet for solar cells.

### CROSS-REFERENCE TO RELATED APPLICATION

This application is a Continuation of PCT International Application No. PCT/JP2014/057617, filed Mar. 19, 2014, which claims priority under 35 U.S.C. §119(a) to Japanese Patent Application Nos. 2013-078078 filed Apr. 3, 2013, 2013-169244 filed Aug. 16, 2013, and 2013-269889 filed Dec. 26, 2013. Each of the above applications is hereby expressly incorporated by reference, in its entirety, into the present application.

### BACKGROUND OF THE INVENTION

1. Field of the Invention

The present invention relates to a back sheet for solar cells and a solar cell module.

2. Description of the Related Art

A solar cell is a power-generation method which exhausts a small amount of carbon dioxide during power generation and causes a small environmental burden and has been widely distributed in recent years. A solar cell module has a structure in which a solar cell, in which a solar cell element is encapsulated with an encapsulating material, is sandwiched between a front base material disposed on the front surface side on which, generally, sunlight is incident and a so-called backsheet disposed on the side (rear surface side) opposite to the front surface side on which sunlight is incident, and a space between the front base material and the solar cell and a space between the solar cell and the backsheet are respectively encapsulated with an ethylene-vinyl acetate (EVA) copolymer resin or the like.

As a backsheet for a solar cell module, there have been proposals regarding back sheets for solar cells in which the surface resistance value is set in a predetermined range in order to improve the partial discharge voltage (refer to JP2009-147063A, JP2009-158952A, and JP2010-92958A).

According to an aspect of the present invention, provided are a back sheet for solar cells including a supporter and an A layer including at least a nonionic surfactant which has an ethylene glycol chain but does not have a carbon-carbon triple bond on at least one surface side of the supporter, in which the surface resistance value SR on the side provided with the A layer is in a range of 1.0×110¹⁰Ω/□ to 5.5×10¹⁵Ω/□, and the improvement of the partial discharge voltage and the adhesiveness to an encapsulating material that encapsulates a solar cell are both achieved and a solar cell module including the back sheet for solar cells.

### SUMMARY OF THE INVENTION

However, in the back sheets for solar cells of JP2009-147063A, JP2009-158952A, and JP2010-92958A, in order to obtain a predetermined surface resistance value, it is necessary to add a large amount of an antistatic material such as a cationic or nonionic surfactant, a conductive polymer (for example, polythiophene), or inorganic conductive particles to the outermost layer.

Meanwhile, a solar cell module is produced by attaching the back sheet for solar cells to the surface of an encapsulating material that encapsulates a solar cell element, and thus, when a large amount of the antistatic material is included in the outermost layer which is brought into contact with the encapsulating material of the back sheet for solar cells, the adhesiveness to the encapsulating material is impaired.

Therefore, there is an ongoing demand for effective means for achieving both the improvement of the partial discharge voltage and the adhesiveness to the encapsulating material that encapsulates a solar cell element.

Therefore, in consideration of the above-described circumstances, an object of the present invention is to provide a back sheet for solar cells which achieves both the improvement of the partial discharge voltage and the adhesiveness to the encapsulating material that encapsulates a solar cell element and a solar cell module including the back sheet for solar cells.

Specific means for achieving the above-described object is as described below.

<1> A back sheet for solar cells including:
a supporter; and
an A layer including at least a nonionic surfactant which has an ethylene glycol chain but does not have a carbon-carbon triple bond on at least one surface side of the supporter,
in which a surface resistance value SR on the side provided with the A layer is in a range of 1.0×10¹⁰Ω/□ to 5.5×10¹⁵Ω/□.

<2> The back sheet for solar cells according to <1>, in which the surface resistance value SR is in a range of 1.0×10¹⁰Ω/□ to 1.0×10¹⁵Ω/□.

<3> The back sheet for solar cells according to <1> or <2>, in which the A layer is an outermost layer.

<4> The back sheet for solar cells according to any one of <1> to <3>, in which the repetition number n of the ethylene glycol chain in the nonionic surfactant is in a range of 7 to 30.

<5> The back sheet for solar cells according to any one of <1> to <4>, in which the repetitions number n of the ethylene glycol chain in the nonionic surfactant is in a range of 10 to 20.

<6> The back sheet for solar cells according to any one of <1> to <5>, in which the nonionic surfactant is at least one selected from a group consisting of nonionic surfactants represented by General Formula (SI) described below, nonionic surfactants represented by General Formula (SII) described below, nonionic surfactants represented by General Formula (SIII-A) described below, and nonionic surfactants represented by General Formula (SIII-B) described below.

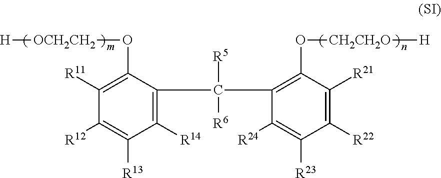

In General Formula (SI), each of R¹¹, R¹³, R²¹, and R²³ independently represents a substituted or unsubstituted alkyl group, aryl group, alkoxy group, halogen atom, acyl group, amide group, sulfonamide group, carbamoyl group, or sulfamoyl group, each of R¹², R¹⁴, R²², and R²⁴ independently represents a hydrogen atom or a substituted or unsubstituted alkyl group, aryl group, alkoxy group, halogen atom, acyl group, amide group, sulfonamide group, carbamoyl group, or sulfamoyl group, and each of R⁵ and R⁶ independently represents a hydrogen atom or a substituted or unsubstituted alkyl group or aryl group.

R¹¹ and R¹², R¹³ and R¹⁴, R²¹ and R²², R²³ and R²⁴, and R⁵ and R⁶ may be bonded to each other so as to form a substituted or unsubstituted ring. Each of m and n independently represents the average repetition number of a polyoxyethylene chain and is a number from 2 to 50.

H₂ₘ₊₁Cₘ—O—(CH₂CH₂O)ₙ—H (SII):

In General Formula (SII), m represents an integer from 0 to 40, and n represents the average repetition number of the polyoxyethylene chain and is a number from 2 to 50.

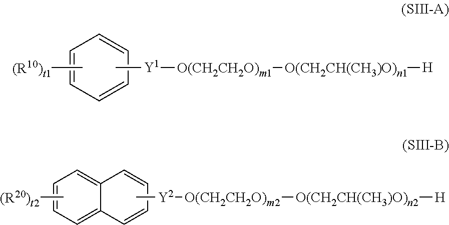

In General Formulae (SIII-A) and (SIII-B), each of R¹⁰ and R²⁰ independently represents a hydrogen atom or an organic group having 1 to 100 carbon atoms, each of t1 and t2 independently represents 1 or 2, each of Y¹ and Y² independently represents a single bond or an alkylene group having 1 to 10 carbon atoms, each of m1 and n1 independently represents 0 or a number from 1 to 100; here, m1 is not 0, and is not 1 in a case in which n1 is 0, and each of m2 and n2 independently represents 0 or a number from 1 to 100; here, m2 is not 0, and is not 1 in a case in which n2 is 0.

<7> The back sheet for solar cells according to <6>, in which each of R¹¹, R¹³, R²¹, and R²³ in General Formula (SI) independently represents a substituted or unsubstituted alkyl group, aryl group, or alkoxy group, m and n in General Formula (SII) respectively represent an integer from 0 to 20 and a number from 7 to 30, and each of R¹⁰ and R²⁰ in General Formula (SIII-A) and General Formula (SIII-B) is independently a hydrogen atom, a straight-chain or branched-chain alkyl group having 1 to 10 carbon atoms, an alkoxy group having 1 to 10 carbon atoms, an alkoxycarbonyl group, an N-alkylamino group, an N,N-dialkylamino group, an N-alkylcarbamoyl group, an acyloxy group, an acylamino group, a polyoxyalkylene chain having 5 to 20 repetition units, an aryl group having 6 to 20 carbon atoms, or an aryl group to which a polyoxyalkylene chain having 5 to 20 repetition units is bonded.

<8> The back sheet for solar cells according to any one of <1> to <7>, in which a content of the nonionic surfactant in the A layer is in a range of 2.5% by mass to 50% by mass of the total amount of a solid content in the A layer.

<9> The back sheet for solar cells according to any one of <1> to <8> further including: an intermediate layer including a resin between the supporter and the A layer.

<10> The back sheet for solar cells according to <9>, in which the intermediate layer includes a white coloring material.

<11> The back sheet for solar cells according to <9> or <10>, in which the intermediate layer includes a black coloring material.

<12> A solar cell module including: a transparent base material on which sunlight is incident; an element structure portion which is provided on the base material and has a solar cell element and an encapsulating material that encapsulates the solar cell element; and the back sheet for solar cells according to any one of <1> to <11> disposed on a side opposite to a side on which the base material of the element structure portion is located.

According to the present invention, it is possible to provide a back sheet for solar cells which achieves both the improvement of the partial discharge voltage and the adhesiveness to an encapsulating material that encapsulates a solar cell element and a solar cell module including the back sheet for solar cells.

### DESCRIPTION OF THE PREFERRED EMBODIMENTS

Hereinafter, a back sheet for solar cells and a solar cell module of the present invention will be described in detail. Meanwhile, in the present specification, numerical ranges expressed using “to” refer to ranges including the numerical values before and after the “to” as the upper limit value and the lower limit value.

[Back Sheet for Solar Cells]

The back sheet for solar cells (hereinafter, referred to as “backsheet”) of the present invention includes a supporter and a layer (hereinafter, referred to as “A layer”) including at least a nonionic surfactant (hereinafter, referred to as “nonionic surfactant (S)”) which has an ethylene glycol chain but does not have a carbon-carbon triple bond on at least one surface side of the supporter.

In addition, the surface resistance value SR (hereinafter, also referred to as “surface resistance value of the backsheet”) on the side provided with the A layer of the backsheet of the present invention is in a range of 1.0×10¹⁰Ω/□ to 5.0×10¹⁵Ω/□.

When the surface resistance value SR on the side provided with the A layer is set in the above-described range, the backsheet of the present invention improves the partial discharge voltage. Meanwhile, when the nonionic surfactant (S) is applied as an antistatic material included in the A layer provided on at least one surface side of the supporter, it becomes possible to control the surface resistance value SR with a small content of the nonionic surfactant. This is considered to be because the nonionic surfactant is easily localized and has a favorable efficiency.

Therefore, in a case in which the A layer is used as the outermost layer (a layer that is brought into contact with an encapsulating material that encapsulates a solar cell element, which shall apply below) of the backsheet, when a small amount of the nonionic surfactant (S) is added to the A layer, the surface resistance value SR of the backsheet falls in the above-described range. In addition, the A layer serving as the outermost layer which is brought into contact with the encapsulating material that encapsulates the solar cell element includes a small content of the nonionic surfactant (S), and thus the adhesiveness to the encapsulating material that encapsulates the solar cell element is not easily impaired.

In addition, even in a case in which a layer other than the A layer is used as the outermost layer, the surface resistance value SR of the backsheet can be set in the above-described range by adding the nonionic surfactant (S) to the A layer serving as an interior layer between the supporter and the outermost layer. In this case, when the amount of the nonionic surfactant (S) in the A layer is adjusted to a desired amount, the surface resistance value SR is set in the above-described range, and the adhesiveness to the encapsulating material that encapsulates the solar cell element is not easily impaired. In addition, the outermost layer that is brought into contact with the encapsulating material that encapsulates the solar cell element does not need to include the antistatic material and, even when including the antistatic material, includes only a small amount of the antistatic material, and thus the adhesiveness to the encapsulating material that encapsulates the solar cell element is not easily impaired.

As a result, the backsheet of the present invention is capable of achieving both the improvement of the partial discharge voltage and the adhesiveness to the encapsulating material that encapsulates the solar cell element.

In the related art, in a technique for adjusting the surface resistance value of the backsheet in order to improve the partial discharge voltage, an antistatic material such as a cationic or nonionic surfactant, a conductive polymer (for example, polythiophene), or inorganic conductive particles or the like is added to the outermost layer. However, in order to improve the partial discharge voltage, the amount of the antistatic material or the like added needs to be equal to or larger than a predetermined amount. In a case in which the predetermined amount or more of the antistatic material or the like, which is required to improve the partial discharge voltage, is added as described above, the adhesiveness to the encapsulating material that encapsulates the solar cell element is impaired. Additionally, there are cases in which the cationic surfactant agglomerates an aqueous-coating binder (latex). Furthermore, even in the case of the nonionic surfactant, particularly, a nonionic surfactant having an acetylene glycol structure or an acetylene alcohol structure with an acetylene group (for example, “OLFINE (manufactured by Nissin Chemical Co., Ltd.)”), the surfactant self-assembles, cissing is caused, it is difficult to ensure a uniform surface shape, and the adhesiveness is likely to be impaired. In the case of the inorganic conductive particles and the conductive polymer, compared with other materials, a larger amount thereof needs to be added in order to decrease the surface resistance value SR, and in this case, the adhesiveness is likely to be impaired. Therefore, in the backsheet of the related art, it is difficult to achieve both the improvement of the partial discharge voltage and the adhesiveness to the encapsulating material that encapsulates a solar cell element, and thus the backsheet of the present invention has an advantage in such a sense.

Here, the surface resistance value SR of the backsheet of the present invention is set in a range of 1.0×10¹⁰Ω/□ to 5.5×10¹⁵Ω/□; however, from the viewpoint of further improving the partial discharge voltage, the surface resistance value is preferably set in a range of 1.0×10¹¹Ω/□ to 1.0×10¹⁵Ω/□ and more preferably set in a range of 1.0×10¹²Ω/□ to 5.0×10¹⁴Ω/□.

When the surface resistance value SR is set to 10¹⁰Ω/□ or greater, not only the desired partial discharge voltage but also the adhesiveness to the encapsulating material are ensured. Meanwhile, when the surface resistance value SR is set to 5.5×10¹⁵Ω/□ or lower, a desired partial discharge voltage can be ensured.

The method for measuring the surface resistance value SR is as described below.

Ten 10 cm×10 cm pieces were cut out from the backsheet (film) and were left to stand indoors for one night at 23° C. and 65% Rh, and the surface resistance values of the ten produced pieces were measured using a digital ultra-high resistance/fine current meter 8340 (manufactured by Advantest Corporation) and a resistivity chamber 12702 (manufactured by Advantest Corporation), and the average value thereof was used as the surface resistance value of the backsheet.

Hereinafter, the backsheet of the present invention will be described in detail.

The backsheet of the present invention includes a supporter and the A layer on at least one surface side of the supporter. The A layer may be the outermost layer or an intermediate layer interposed between the supporter and the outermost layer. In addition, there may be a layer between the supporter and the A layer. In a case in which the A layer is the outermost layer, the A layer functions as an easy-adhesion layer for the layer between the outermost layer and the A layer. On the other hand, in a case in which the A layer is an interior layer, it is preferable to provide an easy-adhesion layer for an encapsulating material that encapsulates a solar cell element as the outermost layer.

The backsheet of the present invention, additionally, may be provided with well-known functional layers such as a coloration layer, a weather-resistant layer, an ultraviolet ray-absorbing layer, and a gas-barrier layer as necessary. These functional layers may be provided on any of the surface side of the supporter provided with the A layer and the surface side opposite to the above-described surface side. In addition, an undercoat layer may be provided between the supporter and the A layer or the functional layer provided so as to come into contact with the supporter. The A layer may also serve as a functional layer such as the coloration layer.

As a preferred aspect, it is preferable to provide between the supporter and the A layer an intermediate layer containing a resin having a function of buffering the differences in physical characteristics such as the coefficient of thermal expansion and thermal contraction ratio stresses between the supporter and the A layer. Furthermore, the intermediate layer may have a function of improving the adhesiveness between the supporter and the A layer.

The intermediate layer preferably has a function of visually shielding the circuit and the like of the solar cell element, a function of improving the conversion efficiency of a solar cell module by improving the reflectance, and the like. The intermediate layer is preferably colored using a colorant in order to impart the above-described functions.

The resin included in the intermediate layer is preferably a solvent-soluble resin. When the resin is a solvent-soluble resin, it is possible to prepare a coating fluid including the resin dissolved in a solvent and provide the intermediate layer using a coating method.

Examples of the preferred resin include an acrylic resin, a styrene resin, a butyral resin, a urethane resin, an olefin resin, a silicon resins, and the like.

The colorant included in the intermediate layer is preferably a white or black colorant. A white colorant is preferred since the detection of the intermediate layer becomes easy in a case in which a failure such as the peeling of the intermediate layer occurs. A black colorant is preferred since a concealing effect can be obtained so as to make the solar cell element less visible.

Examples of a white pigment that makes the intermediate layer white include titanium oxide, barium sulfate, calcium carbonate, and aluminum hydroxide. Titanium oxide is preferred from the viewpoint of improving the reflectance in consideration of the fraction of the white pigment added. Examples of a black pigment include carbon black, a metallic oxide-based black pigment, and a carbon nanotube black body, and carbon black is particularly preferred.

Furthermore, a mixture of the white material and the black material may also be used.

In the present invention, carbon black particles are preferably used as the carbon black in order to obtain a strong coloring strength with a small amount thereof. Carbon black particles having a primary particle diameter of 1 μm or smaller are more preferably used, and carbon black particles having a primary particle diameter in a range of 0.1 μm to 0.8 μm are particularly preferably used. Furthermore, it is preferable to use the carbon black particles in a state of being dispersed not only in a dispersant but also in water.

It is possible to use commercially-procurable carbon black, and, for example, MF-5630 black (manufactured by Dainichiseika Color & Chemicals Mfg. Co., Ltd.), carbon black described in Paragraph [0035] of JP2009-132887A, and the like can be used.

In a case in which the intermediate layer is provided, the thickness thereof is preferably in a range of 0.3 μm to 7.0 μm, more preferably in a range of 0.5 μm to 3.0 μm, and most preferably in a range of 0.5 μm to 2.0 μm.

Hereinafter, the supporter and the respective layers will be described in detail.

(Supporter)

The supporter includes a resin (hereinafter, referred to as “raw material resin”).

Raw Material Resin

Examples of the raw material resin include polyesters, polystyrenes, polystyrenes, polyphenylene ethers, polyphenylene sulfides, and the like, and polyesters are preferred from the viewpoint of cost, mechanical stability, or durability.

Examples of the polyesters include linear saturated polyesters synthesized from an aromatic dibasic acid or an ester-forming derivative thereof and a diol or an ester-forming derivative thereof. Specific examples of the linear saturated polyesters include polyethylene terephthalate, polyethylene isophthalate, polybutylene terephthalate, poly(1,4-cyclohexylene dimethylene terephthalate), polyethylene-2,6-naphthalate, and the like. Among these, polyethylene terephthalate, polyethylene-2,6-naphthalate, and poly(1,4-cyclohexylene dimethylene terephthalate) are particularly preferred in terms of the balance between mechanical properties and cost.

The polyester may be a homopolymer or a copolymer. Furthermore, a polyester obtained by blending a small amount of a different kind of resin, for example, a polyimide or the like into the polyester may be used.

The kind of the polyester is not limited to the above-described polyesters, and a well-known polyester may be used. As the well-known polyester, a polyester may be synthesized using a dicarboxylic acid component and a diol component, or a commercially-available polyester may be used.

In a case in which a polyester is synthesized, the polyester can be obtained by, for example, causing at least one of an esterification reaction and an ester exchange reaction between the dicarboxylic acid component (A) and the diol component (B) using a well-known method.

Examples of the dicarboxylic acid component (A) include dicarboxylic acids and ester derivatives thereof such as aliphatic dicarboxylic acids such as malonic acid, succinic acid, glutaric acid, adipic acid, suberic acid, sebacic acid, dodecanedioic acid, dimer acids, eicosanedioic acid, pimelic acid, azelaic acid, methylmalonic acid, and ethylmalonic acid; alicyclic dicarboxylic acids such as adamantanedicarboxylic acid, norbornene dicarboxylic acid, cyclohexanone dicarboxylic acid, and decalin dicarboxylic acid; aromatic dicarboxylic acids such as terephthalic acid, isophthalic acid, phthalic acid, 1,4-naphthalenedicarboxylic acid, 1,5-naphthalenedicarboxylic acid, 2,6-naphthalenedicarboxylic acid, 1,8-naphthalenedicarboxylic acid, 4,4′-diphenyldicarboxylic acid, 4,4′-diphenylether dicarboxylic acid, 5-sodium sulfoisophthalic acid, phenylindane dicarboxylic acid, anthracenedicarboxylic acid, phenanthrene dicarboxylic acid, and 9,9′-bis(4-carboxyphenyl) fluorenic acid.

Examples of the dialcohol component (B) include diol compounds such as aliphatic diols such as ethylene glycol, 1,2-propanediol, 1,3-propanediol, 1,4-butanediol, 1,2-butanediol, and 1,3-butanediol; alicyclic diols such as cyclohexanedimethanol, spiroglycol, and isosorbide; and aromatic diols such as bisphenol A, 1,3-benzenedimethanol, 1,4-benzenedimethanol, and 9,9′-bis(4-hydroxyphenyl)fluorene.

As the dicarboxylic acid component (A), at least one aromatic dicarboxylic acid is preferably used. More preferably, the polyester contains, in the dicarboxylic acid component, an aromatic dicarboxylic acid as a main component. Meanwhile, the “main component” means that the fraction of the aromatic dicarboxylic acid in the dicarboxylic acid component is 80% by mass or greater. The polyester may include a dicarboxylic acid component other than the aromatic dicarboxylic acid. Examples of the above-described dicarboxylic acid component include ester derivatives such as aromatic dicarboxylic acids and the like.

As the diol component (B), at least one of aliphatic diols is preferably used. As the aliphatic diol, ethylene glycol can be included and, preferably, ethylene glycol may be included as a main component. Meanwhile, the main component means that the fraction of ethylene glycol in the diol component is 80% by mass or greater.

The amount of the aliphatic diol (for example, ethylene glycol) used is preferably in a range of 1.015 mol to 1.50 mol in relation to 1 mol of the aromatic dicarboxylic acid (for example, terephthalic acid) and, as necessary, an ester derivative thereof. The amount of the aliphatic diol (for example, ethylene glycol) used is more preferably in a range of 1.02 mol to 1.30 mol, and still more preferably in a range of 1.025 mol to 1.10 mol. When the amount of the aliphatic diol used is in a range of 1.015 mol or greater, the esterification reaction favorably proceeds, and when the amount of the aliphatic diol used is in a range of 1.50 mol or less, for example, the generation of diethylene glycol as a byproduct due to the dimerization of ethylene glycol is suppressed, and it is possible to favorably maintain a number of characteristics such as melting point, glass transition temperature, crystallinity, heat resistance, hydrolysis resistance, and weather resistance.

In the esterification reaction or the ester exchange reaction, it has been possible so far to use a well-known reaction catalyst. Examples of the reaction catalyst include alkali metal compounds, alkaline-earth metal compounds, zinc compounds, lead compounds, manganese compounds, cobalt compounds, aluminum compounds, antimony compounds, titanium compounds, and phosphorous compounds. Generally, it is preferable to add an antimony compound, a germanium compound, or a titanium compound as a polymerization catalyst in an arbitrary phase ahead of the completion of the method for manufacturing the polyester. As the method for adding the above-described compound, when a germanium compound is used as an example, germanium compound powder is preferably added as it is.

For example, in the esterification reaction, the aromatic dicarboxylic acid and the aliphatic diol are polymerized in the presence of a catalyst containing a titanium compound. In this esterification reaction, it is preferable to use, as the titanium compound which serves as the catalyst, an organic chelate titanium complex having an organic acid as a ligand and to provide a process for adding at least the organic chelate titanium complex, a magnesium compound, and a pentavalent phosphoric acid ester not having an aromatic ring as a substituent in this order in the step.

Specifically, in the esterification reaction step, first, in the beginning, the aromatic dicarboxylic acid and the aliphatic diol are mixed with a catalyst containing the organic chelate titanium complex, which is a titanium compound, ahead of the addition of the magnesium compound and the phosphorous compound. The titanium compound such as the organic chelate titanium complex has a strong catalytic activity for the esterification reaction and is thus capable of causing the esterification reaction to favorably proceed. At this time, the titanium compound may be added during the mixing of the aromatic dicarboxylic acid component and the aliphatic diol component, or the aromatic dicarboxylic acid component (or the aliphatic diol component) and the titanium compound may be mixed together, and then the aliphatic diol component (or the aromatic dicarboxylic acid component) may be mixed with the mixture. In addition, the aromatic dicarboxylic acid component, the aliphatic diol component, and the titanium compound may be mixed together at the same time. There is no particular limitation regarding the mixing, and the components can be mixed together using a well-known method of the related art.

Here, during the polymerization of the polyester, the following compound is preferably added.

As a pentavalent phosphorous compound, at least one pentavalent phosphoric acid ester not having an aromatic ring as a substituent is used. Examples thereof include phosphoric acid esters [(OR)₃—P═O; R=an alkyl group having 1 or 2 carbon atoms] having a lower alkyl group having 2 or less carbon atoms as a substituent. Specifically, trimethyl phosphate and triethyl phosphate are particularly preferred.

The amount of the phosphorous compound added is preferably in a range of 50 ppm to 90 ppm in terms of the P element-equivalent value. The amount of the phosphorous compound is more preferably in a range of 60 ppm to 80 ppm, and still more preferably in a range of 60 ppm to 75 ppm.

When the polyester includes a magnesium compound, the electrostatic application property of the polyester improves.

Examples of the magnesium compound include magnesium salts such as magnesium oxide, magnesium hydroxide, magnesium alkoxides, magnesium acetate, and magnesium carbonate. Among these, magnesium acetate is most preferred from the viewpoint of the solubility in ethylene glycol.

In order to impart a high electrostatic application property, the amount of the magnesium compound added is preferably 50 ppm and more preferably in a range of 50 ppm to 100 ppm in terms of the Mg element-equivalent value. The amount of the magnesium compound added is preferably in a range of 60 ppm to 90 ppm and more preferably in a range of 70 ppm to 80 ppm in terms of imparting the electrostatic application property.

In the esterification reaction step, it is particularly preferable to add, melt, and polymerize the titanium compound, which is a catalyst component, and the magnesium compound and the phosphorous compound, which are additives, so that a value Z computed from the following expression (i) satisfies the following relational expression (ii). Here, the content of P refers to the amount of phosphorous derived from all phosphorous compounds including the pentavalent phosphoric acid ester not having an aromatic ring, and the content of Ti refers to the amount of titanium derived from all Ti compounds including the organic chelate titanium complex. As described above, when the joint use of the magnesium compound and the phosphorous compound in a catalyst system including a titanium compound is selected, and the addition timings and addition fractions thereof are controlled, it is possible to obtain a hue with a slight yellow tone while appropriately maintaining the catalytic activity of the titanium compound at a high level, and to impart heat resistance so that yellow coloration does not easily occur even when the polyester is exposed to a high temperature during a polymerization reaction, the formation of a film (melting), and the like.

Z=5×(the content of P [ppm]/the atomic weight of P)−2×(the content of Mg [ppm]/the atomic weight of Mg)−4×(the content of Ti [ppm]/the atomic weight of Ti) (i)

0≦Z≦5.0 (ii)

The phosphorous compound does not only act on titanium but also interacts with the magnesium compound, and thus the above-described expressions serve as indexes for quantitatively expressing the balance among these three components.

Expression (i) expresses the amount of phosphorous capable of acting on titanium by subtracting the amount of phosphorous acting on magnesium from the amount of all phosphorous capable of reacting with magnesium and titanium. It can be said that, in a case in which the Z value is a positive value, the amount of phosphorous hindering titanium is excessive, and, conversely, in a case in which the Z value is a negative value, the amount of phosphorous necessary to hinder titanium is not sufficient. In the reaction, since a Ti atom, a Mg atom, and a P atom do not have equal valences, weighting is carried out by multiplying the molar numbers of the respective atoms by the valences thereof.

Meanwhile, special synthesis or the like is not required for the synthesis of the polyester, and it is possible to obtain a polyester having a reaction activity required for the reaction and having a hue and coloration resistance to heat using a titanium compound which is inexpensive and can be easily procured, and the phosphorous compound and the magnesium compound which are described above.

In Expression (ii), from the viewpoint of further improving the hue and the coloration resistance to heat in a state of maintaining the polymerization reactivity, it is preferable to satisfy 1.0≦Z≦4.0 and it is more preferable to satisfy 1.5≦Z≦3.0.

As a preferred aspect of the esterification reaction step, 1 ppm to 30 ppm of a chelate titanium complex having citric acid or citrate as a ligand is preferably added to the aromatic dicarboxylic acid and the aliphatic diol before the end of the esterification reaction. After that, it is preferable to add 60 ppm to 90 ppm (more preferably 70 ppm to 80 ppm) of a weakly acidic magnesium salt in the presence of the chelate titanium complex and furthermore, after the above-described addition, add 60 ppm to 80 ppm (more preferably 65 ppm to 75 ppm) of the pentavalent phosphoric acid ester not having an aromatic ring as a substituent.

The esterification reaction step can be carried out while removing water or alcohols generated from the reaction outside of the system using a multistage apparatus including at least two reactors coupled in series under a condition in which ethylene glycol is refluxed.

The esterification reaction step may be carried out in a single stage or may be carried out in multiple divided stages.

In a case in which the esterification reaction step is carried out in a single stage, the esterification reaction temperature is preferably in a range of 230° C. to 260° C. and more preferably in a range of 240° C. to 250° C.

In a case in which the esterification reaction step is carried out in multiple divided stages, the temperature of the esterification reaction in a first reaction bath is preferably in a range of 230° C. to 260° C. and more preferably in a range of 240° C. to 250° C., and the pressure is preferably in a range of 1.0 kg/cm² to 5.0 kg/cm², and more preferably in a range of 2.0 kg/cm² to 3.0 kg/cm². The temperature of the esterification reaction in a second reaction bath is preferably in a range of 230° C. to 260° C. and more preferably in a range of 245° C. to 255° C., and the pressure is preferably in a range of 0.5 kg/cm² to 5.0 kg/cm², and more preferably in a range of 1.0 kg/cm² to 3.0 kg/cm². Furthermore, in a case in which the esterification reaction step is carried out in three or more divided stages, as the conditions for the esterification reaction in the intermediate stage, the reaction temperature and the pressure are preferably set to conditions between those in the first reaction bath and those in the final reaction bath.

Meanwhile, a polycondensation reaction of an esterification reaction product generated from the esterification reaction is caused so as to generate a polycondensate. The polycondensation reaction may be caused in a single stage or may be caused in multiple divided stages.

The esterification reaction product such as an oligomer generated from the esterification reaction is subsequently subjected to a polycondensation reaction. This polycondensation reaction can be preferably caused by supplying the esterification reaction product to a multistage polycondensation reaction bath.

For example, regarding the conditions for the polycondensation reaction caused in three-stage reaction baths, in the first reaction bath, the reaction temperature is preferably in a range of 255° C. to 280° C. and more preferably in a range of 265° C. to 275° C., and the pressure is preferably in a range of 100 Torr to 10 Torr (13.3×10⁻³ MPa to 1.3×10⁻³ MPa), and more preferably in a range of 50 Torr to 20 Torr (6.67×10⁻³ MPa to 2.67×10⁻³ MPa); in the second reaction bath, the reaction temperature is preferably in a range of 265° C. to 285° C. and more preferably in a range of 270° C. to 280° C., and the pressure is preferably in a range of 20 Torr to 1 Torr (2.67×10⁻³ MPa to 1.33×10⁻⁴ MPa), and more preferably in a range of 10 Torr to 3 Torr (1.33×10⁻³ MPa to 4.0×10⁻⁴ MPa); in the third reaction bath in the final reaction bath, the reaction temperature is preferably in a range of 270° C. to 290° C. and more preferably in a range of 275° C. to 285° C., and the pressure is preferably in a range of 10 Torr to 0.1 Torr (1.33×10⁻³ MPa to 1.33×10⁻⁵ MPa), and more preferably in a range of 5 Torr to 0.5 Torr (6.67×10⁻⁴ MPa to 6.67×10⁻⁵ MPa).

To the polyester synthesized as described above, additives such as a photostabilizing agent, an antioxidant, an ultraviolet absorber, a flame retardant, a lubricant (fine particles), a nucleating agent (crystallization agent), and a crystallization inhibitor may be further added.

In the synthesis of the polyester, it is preferable to carry out solid-phase polymerization after the polymerization using the esterification reaction. When solid-phase polymerization is carried out, it is possible to control the water content ratio of the polyester, the degree of crystallization, the acid value of the polyester, that is, the concentration of a terminal carboxyl group of the polyester, and the intrinsic viscosity.

Particularly, when the solid-phase polymerization is carried out, the concentration of ethylene glycol (EG) gas at the initiation of the solid-phase polymerization is set to be higher than the concentration of the EG gas at the end of the solid-phase polymerization preferably in a range of 200 ppm to 1000 ppm, more preferably in a range of 250 ppm to 800 ppm, and still more preferably in a range of 300 ppm to 700 ppm. At this time, AV (the amount of terminal COOH) can be controlled by adding EG of the average EG gas concentration (the average of the gas concentrations at the initiation and at the end of the solid-phase polymerization). That is, EG is added and is thus reacted with the terminal COOH, whereby AV can be reduced. The amount of EG added is preferably in a range of 100 ppm to 500 ppm, more preferably in a range of 150 ppm to 450 ppm, and still more preferably in a range of 200 ppm to 400 ppm.

In addition, the temperature of the solid-phase polymerization is preferably in a range of 180° C. to 230° C., more preferably in a range of 190° C. to 215° C., and still more preferably in a range of 195° C. to 209° C.

In addition, the solid-phase polymerization time is preferably in a range of 10 hours to 40 hours, more preferably in a range of 14 hours to 35 hours, and still more preferably in a range of 18 hours to 30 hours.

Here, the polyester preferably has strong hydrolysis resistance. Therefore, the content of a carboxyl group in the polyester is preferably 50 equivalents/t (t: ton) or less, more preferably 35 equivalents/t or less, and still more preferably 20 equivalents/t or less. When the content of the carboxyl group is 50 equivalents/t or less, it is possible to maintain the hydrolysis resistance and to suppress a decrease in strength to a small extent when the polyester is aged in a hot and humid environment. The lower limit of the content of the carboxyl group is desirably 2 equivalents/t, more preferably 3 equivalents/t, and still more preferably 3 equivalents/t in terms of maintaining the adhesiveness to a layer (for example, a coloring layer) formed in the polyester.

The content of the carboxyl group in the polyester can be adjusted using the kind of polymerization catalyst, film-forming conditions (film-forming temperature or time), solid-phase polymerization, and additives (a terminal-encapsulating agent and the like).

Carbodiimide Compound and Ketenimine Compound

In a case in which the raw material resin is the polyester, the supporter may include either or both a carbodiimide compound and a ketenimine compound. The carbodiimide compound and the ketenimine compound may be used singly respectively or may be jointly used. The inclusion of the carbodiimide compound and the ketenimine compound is effective in suppressing the deterioration of the polyester after thermo and maintain strong insulating properties even after thermo.

The content of the carbodiimide compound or the ketenimine compound is preferably in a range of 0.1% by mass to 10% by mass, more preferably in a range of 0.1% by mass to 4% by mass, and still more preferably in a range of 0.1% by mass to 2% by mass of the polyester. When the content of the carbodiimide compound or the ketenimine compound is set in the above-described range, the adhesiveness between layers in the supporter can be enhanced. In addition, the heat resistance of the supporter can be enhanced.

Meanwhile, in a case in which the carbodiimide compound and the ketenimine compound are jointly used, the total content ratio of the two compounds is preferably in the above-described range.

The carbodiimide compound will be described.

Examples of the carbodiimide compound include compounds having one or more carbodiimide groups in the molecule (including polycarbodiimide compounds), and specifically include, as monocarbodiimide compounds, dicyclohexylcarbodiimide, diisopropylcarbodiimide, dimethylcarbodiimide, diisobutylcarbodiimide, dioctylcarbodiimide, t-butylisopropylcarbodiimide, diphenylcarbodiimide, di-t-butylcarbodiimide, di-β-naphtylcarbodiimide, and N,N′-di-2,6-diisopropylphenyl carbodiimide. As the polycarbodiimide compound, a polycarbodiimide compound having a degree of polymerization having a lower limit of generally 2 or greater and preferably 4 or greater and an upper limit of generally 40 or less and preferably 30 or less is used, and examples thereof include polycarbodiimide compounds manufactured using the method described in the specification of U.S. Pat. No. 2,941,956A, JP1972-33279B (JP-S47-33279B), J. Org. Chem. Vol. 28, pp. 2069 to 2075 (1963), Chemical Review 1981, Vol. 81, Issue 4, pp. 619 to 621, and the like.

Examples of an organic diisocyanate, which is a raw material for manufacturing the polycarbodiimide compound, include aromatic diisocyanates, aliphatic diisocyanates, alicyclic diisocyanates, and mixtures thereof, and specifically include 1,5-naphthalene diisocyanate, 4,4′-diphenylmethane diisocyanate, 4,4′-diphenyldimethylmethane diisocyanate, 1,3-phenylene diisocyanate, 1,4-phenylene diisocyanate, 2,4-tolylene diisocyanate, 2,6-tolylene diisocyanate, mixtures of 2,4-tolylene diisocyanate and 2,6-tolylene diisocyanate, hexamethylene diisocyanate, cyclohexane-1,4-diisocyanate, xylylene diisocyanate, isophorone diisocyanate, 4,4′-dicyclohexylmethane diisocyanate, methylcyclohexane diisocyanate, tetramethylxylylene diisocyanate, 2,6-diisopropylphenyl isocyanate, and 1,3,5-triisopropylbenzene-2,4-diisocyanate.

Specific examples of the polycarbodiimide compounds that can be industrially procured include CARBODILITE HMV-8CA (manufactured by Nisshinbo Holdings Inc.), CARBODILITE LA-1 (manufactured by Nisshinbo holdings Inc.), STABAXOL P (manufactured by Rhein Chemie Corporation), STABAXOL P100 (manufactured by Rhein Chemie Corporation), STABAXOL P400 (manufactured by Rhein Chemie Corporation), STABILIZER 9000 (manufactured by Rhein Chemie Corporation), and the like.

The carbodiimide compound can be used singly, but a mixture of a plurality of the compounds can also be used.

Here, a cyclic carbodiimide compound which includes one carbodiimide group in a cyclic skeleton and has at least one cyclic structure in which a first nitrogen and a second nitrogen are bonded together through a bonding group in the molecule functions as a cyclic encapsulating agent.

The cyclic carbodiimide compound can be prepared using the method described in WO2011/093478A.

The cyclic carbodiimide compound has a cyclic structure. The cyclic carbodiimide compound may have a plurality of cyclic structures. The cyclic structure has one carbodiimide group (—N═C≡CN—), and the first nitrogen and the second nitrogen are bonded together through a bonding group. In a single cyclic structure, there is only one carbodiimide group; however, for example, in the case of a spirocycle or the like having a plurality of cyclic structures in the molecule, the compound may have a plurality of carbodiimide groups as long as individual cyclic structures bonded to spiro atoms have one carbodiimide group. The number of atoms in the cyclic structure is preferably in a range of 8 to 50, more preferably in a range of 10 to 30, still more preferably in a range of 10 to 20, and particularly preferably in a range of 10 to 15.

Here, the number of atoms in the cyclic structure refers to the number of atoms directly constituting the cyclic structure, and, for example, the number of atoms of an 8-membered ring is 8, and the number of atoms of a 50-membered ring is 50. The reasons for setting the number of atoms in the cyclic structure in the above-described ranges are as described below. When the number of atoms in the cyclic structure is smaller than 8, the stability of the cyclic carbodiimide compound degrades, and thus it becomes difficult to store and use the cyclic carbodiimide compound. In addition, there is no particular limitation regarding the upper limit value of the number of ring members from the viewpoint of reactivity, but the synthesis of a cyclic carbodiimide compound having more than 50 atoms is difficult, and there are cases in which the cost significantly increases. On the basis of the above-described viewpoints, the number of atoms in the cyclic structure is preferably in a range of 10 to 30, more preferably in a range of 10 to 20, and particularly in a range of 10 to 15.

As the cyclic carbodiimide compound, a cyclic carbodiimide compound represented by General Formula (O-A) or General Formula (O-B) described below is preferably used. Hereinafter, a preferred structure of the cyclic carbodiimide compound of the present invention will be described in the order of General Formula (O-A) and General Formula (O-B) described below.

First, the cyclic carbodiimide compound represented by General Formula (O-A) will be described.

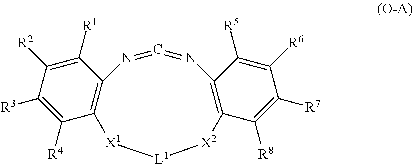

In General Formula (O-A), each of R¹ and R⁵ independently represents an alkyl group, an aryl group, or an alkoxy group. Each of R² to R⁴ and R⁶ to R⁸ independently represents a hydrogen atom, an alkyl group, an aryl group, or an alkoxy group. R¹ to R⁸ may be bonded to each other so as to form a ring. Each of X¹ and X² independently represents a single bond, —O—, —CO—, —S—, —SO₂—, —NH—, or —CH₂—. L¹ represents a divalent linking group.

In General Formula (O-A), each of R¹ and R⁵ independently represents an alkyl group, an aryl group, or an alkoxy group, preferably represents an alkyl group or an aryl group, more preferably represents a secondary or tertiary alkyl group or aryl group from the viewpoint of suppressing a reaction between isocyanate linked to the terminal of the polyester and the hydroxyl terminal of the polyester and suppressing an increase in the viscosity, and particularly preferably represents a secondary alkyl group.

In General Formula (O-A), the alkyl group represented by R¹ and R⁵ is preferably an alkyl group having 1 to 20 carbon atoms, more preferably an alkyl group having 1 to 12 carbon atoms, and particularly preferably an alkyl group having 2 to 6 carbon atoms. The alkyl group represented by R¹ and R⁵ may be a straight chain, a branched chain, or a cyclic chain, but is preferably a branched chain or a cyclic chain from the viewpoint of suppressing a reaction between isocyanate linked to the terminal of the polyester and the hydroxyl terminal of the polyester and suppressing an increase in the viscosity, and particularly preferably represents a secondary alkyl group. The alkyl group represented by R¹ and R⁵ is preferably a secondary or tertiary alkyl group and more preferably a secondary alkyl group. Examples of the alkyl group represented by R¹ and R⁵ include a methyl group, an ethyl group, an n-propyl group, a sec-propyl group, an iso-propyl group, an n-butyl group, a tert-butyl group, a sec-butyl group, an iso-butyl group, an n-pentyl group, a sec-pentyl group, an iso-pentyl group, an n-hexyl group, a sec-hexyl group, an iso-hexyl group, and a cyclohexyl group. Among these, an iso-propyl group, a tert-butyl group, an iso-butyl group, an iso-pentyl group, an iso-hexyl group, and a cyclohexyl group are preferred, and an iso-propyl group, a cyclohexyl group, and a tert-butyl group are more preferred, and an iso-propyl group and a cyclohexyl group are particularly preferred.

In General Formula (O-A), the alkyl group represented by R¹ and R⁵ may further have a substituent, and the substituent is not particularly limited. Here, the alkyl group represented by R¹ and R⁵ preferably does not have any further substituents from the viewpoint of the reactivity with a carboxylic acid.

In General Formula (O-A), the aryl group represented by R¹ and R⁵ is preferably an aryl group having 6 to 20 carbon atoms, more preferably an aryl group having 6 to 12 carbon atoms, and particularly preferably an aryl group having 6 carbon atoms. The aryl group represented by R¹ and R⁵ may be an aryl group formed through the condensation of R¹ and R² or the condensation of R⁵ and R⁶, but it is preferable that R¹ and R⁵ do not respectively condense with R² and R⁶ and thus do not form a ring. Examples of the aryl group represented by R¹ and R⁵ include a phenyl group and a naphthyl group, and, among these, a phenyl group is more preferred.

In General Formula (O-A), the aryl group represented by R¹ and R⁵ may further have a substituent, and the substituent is not particularly limited. Here, the aryl group represented by R¹ and R⁵ preferably does not have any further substituents from the viewpoint of the reactivity with a carboxylic acid.

In General Formula (O-A), the alkoxy group represented by R¹ and R⁵ is preferably an alkoxy group having 1 to 20 carbon atoms, more preferably an alkoxy group having 1 to 12 carbon atoms, and particularly preferably an alkoxy group having 2 to 6 carbon atoms. The alkoxy group represented by R¹ and R⁵ may be a straight chain, a branched chain, or a cyclic chain, but is preferably a branched chain or a cyclic chain from the viewpoint of suppressing a reaction between isocyanate linked to the terminal of the polyester and the hydroxyl terminal of the polyester and suppressing an increase in the viscosity. A preferred example of the alkoxy group represented by R¹ and R⁵ is a group in which —O— is linked to the terminal of the alkyl group represented by R¹ and R⁵, and the preferred range thereof is also, similarly, a group in which —O— is linked to the terminal of the alkyl group represented by R¹ and R⁵.

In General Formula (O-A), the alkoxy group represented by R¹ and R⁵ may further have a substituent, and the substituent is not particularly limited. Here, the alkoxy group represented by R¹ and R⁵ preferably does not have any further substituents from the viewpoint of the reactivity with a carboxylic acid.

In General Formula (O-A), R¹ and R⁵ may be identical to or different from each other, but are preferably identical to each other from the viewpoint of cost.

In General Formula (O-A), each of R² to R⁴ and R⁶ to R⁸ independently represents a hydrogen atom, an alkyl group, an aryl group, or an alkoxy group, are preferably a hydrogen atom, an alkyl group having 1 to 20 carbon atoms, or an alkoxy group having 1 to 20 carbon atoms, more preferably a hydrogen atom or an alkyl group having 1 to 6 carbon atoms, and particularly preferably a hydrogen atom.

In General Formula (O-A), the alkyl group, the aryl group, or the alkoxy group represented by R² to R⁴ and R⁶ to R⁸ may further have a substituent, and the substituent is not particularly limited.

In General Formula (O-A), both R² and R⁶ are preferably hydrogen atoms from the viewpoint of ease of introducing a bulky substituent into R¹ and R⁵. Here, in WO02010/071211A, compounds obtained by substituting portions (meta positions with respect to the carbodiimide group) corresponding to R² and R⁶ in General Formula (O-A) with an alkyl group or an aryl group are exemplified, but these compounds are not capable of suppressing the reaction between isocyanate linked to the terminal of the polyester and the hydroxyl terminal of the polyester, and thus it is difficult to introduce substituents into the portions (meta positions with respect to the carbodiimide group) corresponding to R² and R⁶ in General Formula (O-A).

In General Formula (O-A), R¹ to R⁸ may be bonded to each other so as to form a ring. There is no particular limitation regarding a ring formed at this time, but an aromatic ring is preferred. For example, two or more of R¹ to R⁴ may be bonded to each other so as to form a condensed ring or R¹ to R⁴ may form an arylene group or a heteroarylene group having 10 or more carbon atoms together with a benzene ring substituted with R¹ to R⁴. Examples of the arylene group having 10 or more carbon atoms formed at this time include aromatic groups having 10 to 15 carbon atoms such as a naphthalenediyl group.

In General Formula (O-A), similarly, for example, two or more of R⁵ to R⁸ may be bonded to each other so as to form a ring or R⁵ to R⁸ may form an arylene group or a heteroarylene group having 10 or more carbon atoms together with a benzene ring substituted with R⁵ to R⁸. The preferred range at this time is identical to the preferred range when R¹ to R⁴ form an arylene group or a heteroarylene group having 10 or more carbon atoms together with a benzene ring substituted with R¹ to R⁴.

However, In General Formula (O-A), it is preferable that R¹ to R⁸ are not bonded to each other and thus do not form a ring.

In General Formula (O-A), each of X¹ and X² independently represents at least one selected from a single bond, —O—, —CO—, —S—, —SO₂—, —NH—, or —CH₂—. Among these, each of X¹ and X² is preferably —O—, —CO—, —S—, —SO₂—, or —NH—, and more preferably —O— or —S— from the viewpoint of easy synthesis.

In General Formula (O-A), L¹ represents a divalent linking group and may respectively include a hetero atom and a substituent. L¹ is preferably a divalent aliphatic group having 1 to 20 carbon atoms, a divalent alicyclic group having 3 to 20 carbon atoms, a divalent aromatic group having 5 to 15 carbon atoms, or a combination thereof and more preferably a divalent aliphatic group having 1 to 20 carbon atoms.

In General Formula (O-A), examples of the divalent aliphatic group represented by L¹ include alkylene groups having 1 to 20 carbon atoms. Examples of the alkylene groups having 1 to 20 carbon atoms include a methylene group, an ethylene group, a propylene group, a butylene group, a pentylene group, a hexylene group, a heptylene group, an octylene group, a nonylene group, a decylene group, a dodecylene group, and a hexadecylene group, and a methylene group, an ethylene group, and a propylene group are preferred, and an ethylene group is particularly preferred. These aliphatic groups may be substituted. Examples of a substituent include an alkyl group having 1 to 20 carbon atoms, an aryl group having 6 to 15 carbon atoms, a halogen atom, a nitro group, an amide group, a hydroxyl group, an ester group, an ether group, and an aldehyde group.

In General Formula (O-A), examples of the divalent alicyclic group represented by L¹ include cycloalkylene groups having 3 to 20 carbon atoms. Examples of the cycloalkylene groups having 3 to 20 carbon atoms include a cyclopropylene group, a cyclobutylene group, a cyclopentylene group, a cyclohexylene group, a cycloheptylene group, a cyclooctylene group, a cyclononylene group, a cyclodecylene group, a cyclododecylene group, and a cyclohexadecylene group. These alicyclic groups may be substituted. Examples of a substituent include an alkyl group having 1 to 20 carbon atoms, an aryl group having 6 to 15 carbon atoms, a halogen atom, a nitro group, an amide group, a hydroxyl group, an ester group, an ether group, and an aldehyde group.

In General Formula (O-A), examples of the divalent aromatic group represented by L¹ include arylene groups having 5 to 15 carbon atoms which may include a hetero atom and thus have a heterocyclic structure. Examples of the arylene groups having 5 to 15 carbon atoms include a phenylene group and a naphthalenediyl group. These aromatic groups may be substituted. Examples of a substituent include an alkyl group having 1 to 20 carbon atoms, an aryl group having 6 to 15 carbon atoms, a halogen atom, a nitro group, an amide group, a hydroxyl group, an ester group, an ether group, and an aldehyde group.

The number of atoms in the cyclic structure including the carbodiimide group in General Formula (O-A) is preferably in a range of 8 to 50, more preferably in a range of 10 to 30, still more preferably in a range of 10 to 20, and particularly preferably in a range of 10 to 15.

Here, the number of atoms in the cyclic structure including the carbodiimide group refers to the number of atoms directly constituting the cyclic structure including the carbodiimide group, and, for example, the number of atoms of an 8-membered ring is 8, and the number of atoms of a 50-membered ring is 50. The reasons for setting the number of atoms in the cyclic structure in the above-described ranges are as described below. When the number of atoms in the cyclic structure is smaller than 8, the stability of the cyclic carbodiimide compound degrades, and thus it becomes difficult to store and use the cyclic carbodiimide compound. In addition, there is no particular limitation regarding the upper limit value of the number of ring members from the viewpoint of reactivity, but the synthesis of a cyclic carbodiimide compound having more than 50 atoms is difficult, and there are cases in which the cost significantly increases. On the basis of the above-described viewpoints, in General Formula (O-A), the number of atoms in the cyclic structure is preferably in a range of 10 to 30, more preferably in a range of 10 to 20, and particularly in a range of 10 to 15.

Next, the cyclic carbodiimide compound represented by General Formula (O-B) described below will be described.

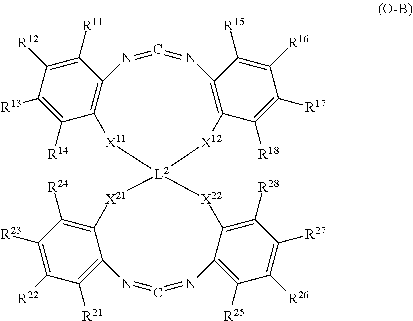

In General Formula (O-B), each of R¹¹, R¹⁵, R²¹, and R²⁵ independently represents an alkyl group, an aryl group, or an alkoxy group. Each of R¹² to R¹⁴, R¹⁶ to R¹⁸, R²² to R²⁴, and R²⁶ to R²⁸ independently represents a hydrogen atom, an alkyl group, an aryl group, or an alkoxy group. R¹¹ to R²⁸ may be bonded to each other so as to form a ring. Each of X¹¹, X¹², X²¹, and X²² independently represents a single bond, —O—, —CO—, —S—, —SO₂—, —NH—, or —CH₂—. L² represents a tetravalent linking group.

In General Formula (O-B), the preferred ranges of R¹¹, R¹⁵, R²¹, and R²⁵ are identical to the preferred ranges of R¹ and R⁵ in General Formula (O-A).

The aryl group represented by R¹¹, R¹⁵, R²¹, and R²⁵ may be an aryl group formed through the condensation of R¹¹ and R¹², the condensation of R¹⁵ and R¹⁶, the condensation of R²¹ and R²² or the condensation of R²⁵ and R²⁶, but it is preferable that R¹¹, R¹⁵, R²¹, and R²⁵ do not respectively condense with R¹², R¹⁶, R²², and R²⁶ and thus do not form a ring.

R¹¹, R¹⁵, R²¹, and R²⁵ may be identical to or different from each other, but are preferably identical to each other from the viewpoint of cost.

In General Formula (O-B), the preferred ranges of R¹² to R¹⁴, R¹⁶ to R¹⁸, R²² to R²⁴, and R²⁶ to R²⁸ are identical to the preferred ranges of R² to R⁴ and R⁶ to R⁸ in General Formula (O-A).

Among R¹² to R¹⁴, R¹⁶ to R¹⁸, R²² to R²⁴, and R²⁶ to R²⁸, R¹², R¹⁶, R²², and R²⁶ are preferably all hydrogen atoms from the viewpoint of ease of introducing a bulky substituent into R¹¹, R¹⁵, R²¹, and R²⁵.

Here, when a bulky group such as an alkyl group, an aryl group, or an alkoxy group is introduced into the vicinity of the carbodiimide group as described above, the cyclic carbodiimide compound represented by General Formula (O-B) is capable of suppressing a reaction between an isocyanate group, which is generated after the reaction between the carbodiimide group and the terminal carboxylic acid of the polyester, and a terminal hydroxyl group of the polyester. As a result, it is possible to suppress an increase in the molecular weight of the polyester and to suppress the generation of chips caused by the above-described increase in the viscosity of the polyester.

In General Formula (O-B), R¹¹ to R²⁸ may be bonded to each other so as to form a ring, and a range of a preferred ring is identical to a range of a preferred ring formed by the mutual bonding of R¹ to R⁸ in General Formula (O-A).

In General Formula (O-B), the preferred ranges of X¹¹, X¹², X²¹, and X²² are identical to the preferred ranges of X¹ and X² in General Formula (O-A).

In General Formula (O-B), L² represents a tetravalent linking group and may respectively include a hetero atom and a substituent. L² is preferably a tetravalent aliphatic group having 1 to 20 carbon atoms, a tetravalent alicyclic group having 3 to 20 carbon atoms, a tetravalent aromatic group having 5 to 15 carbon atoms, or a combination thereof and more preferably a tetravalent aliphatic group having 1 to 20 carbon atoms.

In General Formula (O-B), examples of the tetravalent aliphatic group represented by L² include alkanetetrayl groups having 1 to 20 carbon atoms and the like. Examples of the alkanetetrayl groups having 1 to 20 carbon atoms include a methanetetrayl group, an ethanetetrayl group, a propanetetrayl group, a butanetetrayl group, a pentanetetrayl group, a hexanetetrayl group, a heptanetetrayl group, an octanetetrayl group, a nonanetetrayl group, a decanetetrayl group, a dodecanetetrayl group, and a hexadecanetetrayl group, a methanetetrayl group, an ethanetetrayl group, and a propanetetrayl group are more preferred, and an ethanetetrayl group is particularly preferred. These aliphatic groups may include a substituent. Examples of the substituent include an alkyl group having 1 to 20 carbon atoms, an aryl group having 6 to 15 carbon atoms, a halogen atom, a nitro group, an amide group, a hydroxyl group, an ester group, an ether group, and an aldehyde group.

In General Formula (O-B), examples of the tetravalent alicyclic group represented by L² include, as alicyclic groups, cycloalkanetetrayl groups having 3 to 20 carbon atoms. Examples of the cycloalkanetetrayl groups having 3 to 20 carbon atoms include a cyclopropanetetrayl group, a cyclobutanetetrayl group, a cyclopentanetetrayl group, a cyclohexanetetrayl group, a cycloheptanetetrayl group, a cyclooctanetetrayl group, a cyclononanetetrayl group, a cyclodecanetetrayl group, a cyclododecanetetrayl group, and a cyclohexadecanetetrayl group. These alicyclic groups may include a substituent. Examples of the substituent include an alkyl group having 1 to 20 carbon atoms, an arylene group having 6 to 15 carbon atoms, a halogen atom, a nitro group, an amide group, a hydroxyl group, an ester group, an ether group, and an aldehyde group.

In General Formula (O-B), examples of the tetravalent aromatic group represented by L² include arenetetrayl groups having 5 to 15 carbon atoms which may include a hetero atom and thus have a heterocyclic structure. Examples of the (tetravalent) arenetetrayl groups having 5 to 15 carbon atoms include a benzenetetrayl group and a naphthalenetetrayl group. These aromatic groups may be substituted. Examples of a substituent include an alkyl group having 1 to 20 carbon atoms, an aryl group having 6 to 15 carbon atoms, a halogen atom, a nitro group, an amide group, a hydroxyl group, an ester group, an ether group, and an aldehyde group.

In General Formula (O-B), two cyclic structures including the carbodiimide group are included through L² which is a tetravalent linking group.

The preferred ranges of the numbers of atoms in the respective cyclic structures including the carbodiimide group in General Formula (O-B) are respectively identical to the preferred range of the number of atoms in the cyclic structure including the carbodiimide group in General Formula (O-A).

Here, the cyclic carbodiimide compound is preferably an aromatic carbodiimide not having a cyclic structure in which the first nitrogen and the second nitrogen of two or more carbodiimide groups in the molecule are bonded to each other through linking groups, that is, the cyclic carbodiimide compound is preferably a single ring and is represented by General Formula (O-A) from the viewpoint of difficulty of the viscosity being increased.

However, from the viewpoint of being capable of suppressing sublimation and the generation of isocyanate gas during manufacturing, the cyclic carbodiimide compound of the present invention also preferably has a plurality of cyclic structures and is represented by General Formula (O-B).

The molecular weight of the cyclic carbodiimide compound is preferably in a range of 400 to 1500 in terms of the weight-average molecular weight. When the molecular weight of the cyclic carbodiimide compound is 400 or higher, sublimation properties are weak, and the generation of isocyanate gas during manufacturing can be suppressed, which is preferable. In addition, there is no particular limitation regarding the upper limit of the molecular weight of the cyclic carbodiimide compound, but the molecular weight thereof is preferably 1500 or lower from the viewpoint of reactivity with carboxylic acid.

The molecular weight of the cyclic carbodiimide compound is more preferably in a range of 500 to 1200.

Specific examples of the cyclic carbodiimide compound represented by General Formula (O-A) or General Formula (O-B) include the following compounds. However, the present invention is not limited to the following specific examples.

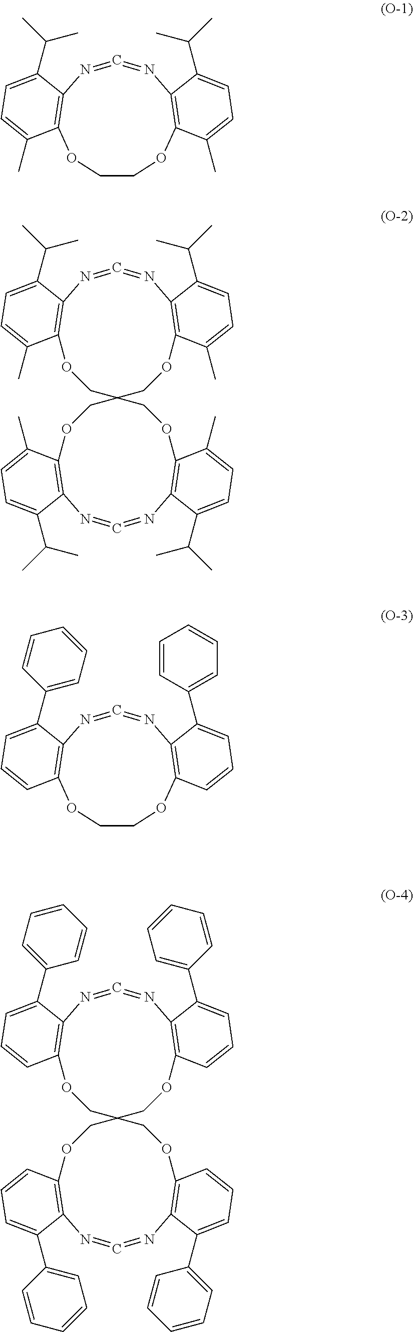

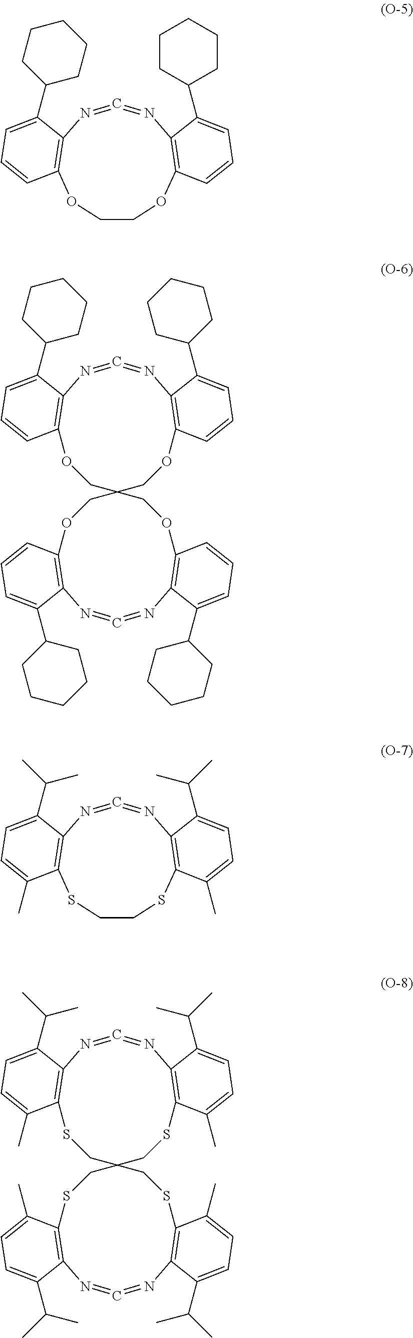

The cyclic carbodiimide compound is preferably a compound having at least one structure represented by —N═C≡N— (carbodiimide group) adjacent to an aromatic ring and can be manufactured by, for example, heating an organic isocyanate in the presence of an appropriate catalyst and causing a decarboxylation reaction. In addition, the cyclic carbodiimide compound of the present invention can be synthesized with reference to the method described in JP2011-256337A.

In the synthesis of the cyclic carbodiimide compound, there is no particular limitation regarding the method for introducing a specific bulky substituent into the ortho position of an arylene group adjacent to the first nitrogen and the second nitrogen of the carbodiimide group, and nitrobenzene substituted with an alkyl group can be synthesized by nitrating an alkyl benzene using, for example, a known method, and a cyclic carbodiimide can be synthesized using the method described in WO2011/158958A on the basis of the nitrobenzene.

The ketenimine compound will be described.

As the ketenimine compound, a ketenimine compound represented by General Formula (K-A) described below is preferably used.

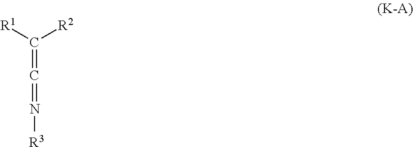

In General Formula (K-A), each of R¹ and R² independently represents an alkyl group, an aryl group, or an alkoxy group, an alkoxycarbonyl group, an aminocarbonyl group, an aryloxy group, an acyl group, or an aryloxycarbonyl group, and R³ represents an alkyl group or an aryl group.

Here, the molecular weight of a portion excluding the nitrogen atom and the substituent bonded to the nitrogen atom in the ketenimine compound is preferably 320 or more. That is, in General Formula (K-A), the molecular weight of a R¹—C(═C)—R² group is preferably 320 or more. The molecular weight of the portion excluding the nitrogen atom and the substituent bonded to the nitrogen atom in the ketenimine compound is preferably 320 or more, more preferably in a range of 500 to 1500, and still more preferably in a range of 600 to 1000. As described above, when the molecular weight of the portion excluding the nitrogen atom and the substituent bonded to the nitrogen atom in the ketenimine compound is in the above-described range, it is possible to enhance the adhesiveness between the supporter and a layer in contact with the supporter. This is because, when the portion excluding the nitrogen atom and the substituent bonded to the nitrogen atom in the ketenimine compound has a certain range of molecular weight, the polyester terminal which is bulky to a certain extent diffuses into the layer in contact with the supporter, and an anchorage effect is exhibited.

In General Formula (K-A), the alkyl group represented by R¹ and R² is preferably an alkyl group having 1 to 20 carbon atoms and more preferably an alkyl group having 1 to 12 carbon atoms. The alkyl group represented by R¹ and R² may be a straight chain, a branched chain, or a cyclic chain. Examples of the alkyl group represented by R¹ and R² include a methyl group, an ethyl group, an n-propyl group, an iso-propyl group, an n-butyl group, a tert-butyl group, a sec-butyl group, an iso-butyl group, an n-pentyl group, a sec-pentyl group, an iso-pentyl group, an n-hexyl group, a sec-hexyl group, an iso-hexyl group, and a cyclohexyl group. Among these, a methyl group, an ethyl group, an n-propyl group, an iso-propyl group, an iso-butyl group, and a cyclohexyl group are more preferred.

In General Formula (K-A), the alkyl group represented by R¹ and R² may further have a substituent. The substituent is not particularly limited as long as the reactivity between a ketenimine group and a carboxyl group is not degraded, and examples thereof include the same substituents described above. Meanwhile, the number of carbon atoms in the alkyl group represented by R¹ and R² represents the number of carbon atoms not including the substituent.

In General Formula (K-A), the aryl group represented by R¹ and R² is preferably an aryl group having 6 to 20 carbon atoms and more preferably an aryl group having 6 to 12 carbon atoms. Examples of the aryl group represented by R¹ and R² include a phenyl group and a naphthyl group, and, among these, a phenyl group is particularly preferred.

In General Formula (K-A), the aryl group represented by R¹ and R² includes a heteroaryl group. The heteroaryl group refers to a 5-membered, 6-membered, or 7-membered ring, which exhibits aromaticity, or a condensed ring thereof in which at least one ring-constituting atom is substituted with a hetero atom. Examples of the heteroaryl group include an imidazolyl group, a pyridyl group, a quinolyl group, a furyl group, a thienyl group, a benzoxazolyl group, an indolyl group, a benzimidazolyl group, a benzothiazolyl group, a carbazolyl group, and an azepinyl group. The hetero atom included in the heteroaryl group is preferably an oxygen atom, a sulfur atom, or a nitrogen atom, and, among these, an oxygen atom or a nitrogen atom is preferred.

In General Formula (K-A), the aryl group represented by R¹ and R² or the heteroaryl group may further have a substituent, and the substituent is not particularly limited as long as the reactivity between the ketenimine group and the carboxyl group is not degraded. Meanwhile, the number of carbon atoms in the aryl group represented by R¹ and R² or the heteroaryl group represents the number of carbon atoms not including the substituent.

In General Formula (K-A), the alkoxy group represented by R¹ and R² is preferably an alkoxy group having 1 to 20 carbon atoms, more preferably an alkoxy group having 1 to 12 carbon atoms, and particularly preferably an alkoxy group having 2 to 6 carbon atoms. The alkoxy group represented by R¹ and R² may be a straight chain, a branched chain, or a cyclic chain. A preferred example of the alkoxy group represented by R¹ and R² is a group in which —O— is linked to the terminal of the alkyl group represented by R¹ and R². The alkoxy group represented by R¹ and R² may further have a substituent, and the substituent is not particularly limited as long as the reactivity between the ketenimine group and the carboxyl group is not degraded. Meanwhile, the number of carbon atoms in the alkoxy group represented by R¹ and R² represents the number of carbon atoms not including the substituent.

In General Formula (K-A), the alkoxycarbonyl group represented by R¹ and R² is preferably an alkoxycarbonyl group having 2 to 20 carbon atoms, more preferably an alkoxycarbonyl group having 2 to 12 carbon atoms, and particularly preferably an alkoxycarbonyl group having 2 to 6 carbon atoms. Examples of an alkoxy portion of the alkoxycarbonyl group represented by R¹ and R² include the above-described examples of the alkoxy group.

In General Formula (K-A), the aminocarbonyl group represented by R¹ and R² is preferably an alkylaminocarbonyl group having 1 to 20 carbon atoms or an arylaminocarbonyl group having 6 to 20 carbon atoms. A preferred example of the alkylamine portion in the alkylaminocarbonyl group is a group in which —NH— is linked to the terminal of the alkyl group represented by R¹ and R². The alkylaminocarbonyl group represented by R¹ and R² may further have a substituent, and the substituent is not particularly limited as long as the reactivity between the ketenimine group and the carboxyl group is not degraded. A preferred example of the arylamine portion in the arylaminocarbonyl group having 6 to 20 carbon atoms is a group in which —NH— is linked to the terminal of the aryl group represented by R¹ and R². The arylaminocarbonyl group represented by R¹ and R² may further have a substituent, and the substituent is not particularly limited as long as the reactivity between the ketenimine group and the carboxyl group is not degraded. Meanwhile, the number of carbon atoms in the alkylaminocarbonyl group represented by R¹ and R² represents the number of carbon atoms not including the substituent.

In General Formula (K-A), the aryloxy group represented by R¹ and R² is preferably an aryloxy group having 6 to 20 carbon atoms and more preferably an aryloxy group having 6 to 12 carbon atoms. Examples of the aryl portion in the aryloxy group represented by R¹ and R² include the above-described examples of the aryl group.

In General Formula (K-A), the acyl group represented by R¹ and R² is preferably an acyl group having 2 to 20 carbon atoms, more preferably an acyl group having 2 to 12 carbon atoms, and particularly preferably an acyl group having 2 to 6 carbon atoms. The acyl group represented by R¹ and R² may further have a substituent, and the substituent is not particularly limited as long as the reactivity between the ketenimine group and the carboxyl group is not degraded. Meanwhile, the number of carbon atoms in the acyl group represented by R¹ and R² represents the number of carbon atoms not including the substituent.

In General Formula (K-A), the aryloxycarbonyl group represented by R¹ and R² is preferably an aryloxycarbonyl group having 7 to 20 carbon atoms and more preferably an aryloxycarbonyl group having 7 to 12 carbon atoms. Examples of the aryl portion in the aryloxycarbonyl group represented by R¹ and R² include the above-described examples of the aryl group.

In General Formula (K-A), R³ represents an alkyl group or an aryl group. The alkyl group is preferably an alkyl group having 1 to 20 carbon atoms and more preferably an alkyl group having 1 to 12 carbon atoms. The alkyl group represented by R³ may be a straight chain, a branched chain, or a cyclic chain. Examples of the alkyl group represented by R³ include a methyl group, an ethyl group, an n-propyl group, an iso-propyl group, an n-butyl group, a tert-butyl group, a sec-butyl group, an iso-butyl group, an n-pentyl group, a sec-pentyl group, an iso-pentyl group, an n-hexyl group, a sec-hexyl group, an iso-hexyl group, and a cyclohexyl group. Among these, a methyl group, an ethyl group, an n-propyl group, an iso-propyl group, an n-butyl group, an iso-butyl group, and a cyclohexyl group are more preferred.

In General Formula (K-A), the alkyl group represented by R³ may further have a substituent, and the substituent is not particularly limited as long as the reactivity between the ketenimine group and the carboxyl group is not degraded. Examples of the substituent include the same examples described above.

In General Formula (K-A), the aryl group represented by R³ is preferably an aryl group having 6 to 20 carbon atoms and more preferably an aryl group having 6 to 12 carbon atoms. Examples of the aryl group represented by R³ include a phenyl group and a naphthyl group, and, among these, a phenyl group is more preferred.

In General Formula (K-A), the aryl group represented by R³ includes a heteroaryl group. The heteroaryl group refers to a 5-membered, 6-membered, or 7-membered ring, which exhibits aromaticity, or a condensed ring thereof in which at least one ring-constituting atom is substituted with a hetero atom. Examples of the heteroaryl group include an imidazolyl group, a pyridyl group, a quinolyl group, a furyl group, a thienyl group, a benzoxazolyl group, an indolyl group, a benzimidazolyl group, a benzothiazolyl group, a carbazolyl group, and an azepinyl group. The hetero atom included in the heteroaryl group is preferably an oxygen atom, a sulfur atom, or a nitrogen atom, and, among these, an oxygen atom or a nitrogen atom is preferred.

In General Formula (K-A), the aryl group represented by R³ or the heteroaryl group may further have a substituent, and the substituent is not particularly limited as long as the reactivity between the ketenimine group and the carboxyl group is not degraded.

Meanwhile, General Formula (K-A) may include a repetition unit. In this case, at least one of R¹ and R³ is the repetition unit, and the repetition unit preferably includes a ketenimine portion.

As the ketenimine compound, a ketenimine compound represented by General Formula (K-B) described below is also preferably used.

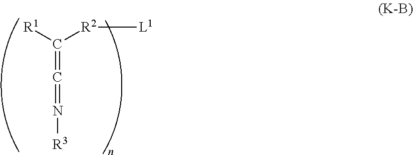

In General Formula (K-B), R¹ represents an alkyl group, an aryl group, an alkoxy group, an alkoxycarbonyl group, an aminocarbonyl group, an aryloxy group, an acyl group, or an aryloxycarbonyl group. R² represents an alkyl group, an aryl group, an alkoxy group, an alkoxycarbonyl group, an aminocarbonyl group, an aryloxy group, an acyl group, or an aryloxycarbonyl group which has L¹ as a substituent. R³ represents an alkyl group or an aryl group. n represents an integer from 2 to 4, and L¹ represents a n-valent linking group. The molecular weight of a (R¹—C(═C)—R²—)ₙ-L¹ group is preferably 320 or more.

In General Formula (K-B), R¹ is the same as R¹ in General Formula (K-A) and also has the same preferred range.

In General Formula (K-B), R² represents an alkyl group, an aryl group, an alkoxy group, an alkoxycarbonyl group, an aminocarbonyl group, an aryloxy group, an acyl group, or an aryloxycarbonyl group which has L₁ that is an n-valent linking group. The alkyl group, the aryl group, the alkoxy group, the alkoxycarbonyl group, the aminocarbonyl group, the aryloxy group, the acyl group, or the aryloxycarbonyl group are the same as those in General Formula (K-A) and also have the same preferred ranges.

In General Formula (K-B), R³ is the same as R³ in General Formula (K-A) and also has the same preferred range.

In General Formula (K-B), L¹ is an n-valent linking group, and n represents an integer from 2 to 4.

In General Formula (K-B), specific examples of a divalent linking group represented by L¹ include, for example, groups represented by —NR⁸— (R⁸ represents a hydrogen atom, an alkyl group which may have a substituent, or an aryl group which may have a substituent and is preferably a hydrogen atom), —SO₂—, —CO—, a substituted or unsubstituted alkylene group, a substituted or unsubstituted alkenylene group, an alkynylene group, a substituted or unsubstituted phenylene group, a substituted or unsubstituted biphenylene group, a substituted or unsubstituted naphthalene group, —O—, —S—, —SO—, and groups obtained by combining two or more thereof.

In General Formula (K-B), specific examples of a trivalent linking group represented by L¹ include, for example, groups obtained by removing one hydrogen atom from a linking group having a substituent out of the linking groups exemplified as the divalent linking group.

In General Formula (K-B), specific examples of a tetravalent linking group represented by L¹ include, for example, groups obtained by removing two hydrogen atoms from a linking group having a substituent out of the linking groups exemplified as the divalent linking group.

In General Formula (K-B), when a di- to tetravalent linking group is used as the linking group represented by L¹, it is possible to produce a compound having two or more ketenimine portions in the molecule and to exhibit a superior terminal-encapsulating effect. In addition, when a compound having two or more ketenimine portions in the molecule is used, it is possible to decrease the molecular weight per ketenimine group and to cause the ketenimine compound and the terminal carboxyl group in the polyester to be effectively reacted with each other. Furthermore, when two or more ketenimine portions are included, it is possible to suppress the sublimation of the ketenimine compound or a ketene compound.

In General Formula (K-B), n is more preferably 3 or 4. When n is set to 3 or 4, it is possible to produce a compound including three or four ketenimine portions in one molecule and to exhibit a superior terminal-encapsulating effect. In addition, when n is set to 3 or 4, it is possible to suppress the sublimation of the ketenimine compound even in a case in which the molar molecular weight of the substituent of R¹ or R² in General Formula (K-B) is set to be small.

As the ketenimine compound, a ketenimine compound represented by General Formula (K-C) described below is also preferably used.

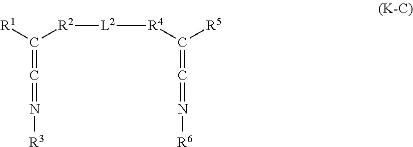

In General Formula (K-C), R¹ and R⁵ represent alkyl groups, aryl groups, alkoxy groups, alkoxycarbonyl groups, aminocarbonyl groups, aryloxy groups, acyl groups, or aryloxycarbonyl groups. R² and R⁴ represent alkyl groups, aryl groups, alkoxy groups, alkoxycarbonyl groups, aminocarbonyl groups, aryloxy groups, acyl groups, or aryloxycarbonyl groups which have L² as a substituent. R³ and R⁶ represent alkyl groups or aryl groups. L² represents a single bond or a divalent linking group. The molecular weight of a R¹—C(═C)—R²-L²-R⁴—C(═C)—R⁵ group is preferably 320 or more.

In General Formula (K-C), R¹ is the same as R¹ in General Formula (K-A) and also has the same preferred range. In addition, R⁵ is the same as R¹ in General Formula (K-A) and also has the same preferred range.

In General Formula (K-C), R² is the same as R² in General Formula (K-B) and also has the same preferred range. In addition, R⁴ is the same as R¹ in General Formula (K-B) and also has the same preferred range.

In General Formula (K-C), R³ is the same as R³ in General Formula (K-A) and also has the same preferred range. In addition, R⁶ is the same as R³ in General Formula (K-A) and also has the same preferred range.

In General Formula (K-C), L² represents a single bond or a divalent linking group. Specific examples of the divalent linking group include the linking groups exemplified as L¹ in General Formula (K-B).

Here, the molecular weight of a portion excluding the nitrogen atom and the substituent bonded to the nitrogen atom in the ketenimine compound is preferably 320 or more. The molecular weight of the portion excluding the nitrogen atom and the substituent bonded to the nitrogen atom in the ketenimine compound may be 320 or more, preferably 400 or more, and more preferably 500 or more. In addition, the molar molecular weight of the ketenimine compound with respect to the number of the ketenimine portions in one molecule (the molar molecular weight/the number of the ketenimine portions) is preferably 1000 or less, more preferably 500 or less, and still more preferably 400 or less. When the molecular weight of the substituent on carbon in the ketenimine portion of the ketenimine compound and the molar molecular weight of the ketenimine compound with respect to the number of the ketenimine portions are set in the above-described ranges, the sublimation of the ketenimine compound is suppressed, the sublimation of the ketene compound occurring when the terminal carboxyl group of the polyester is encapsulated is suppressed, and furthermore, it is possible to encapsulate the terminal carboxyl group of the polyester with a small amount of the ketenimine compound added.

The ketenimine compound having at least one ketenimine group can be synthesized with reference to the method described in, for example, J. Am. Chem. Soc., 1953, 75(3), pp. 657 to 660.

Hereinafter, specific preferred examples of the ketenimine compounds represented by General Formulae (K-A) to (K-C) will be illustrated, but the present invention is not limited thereto.

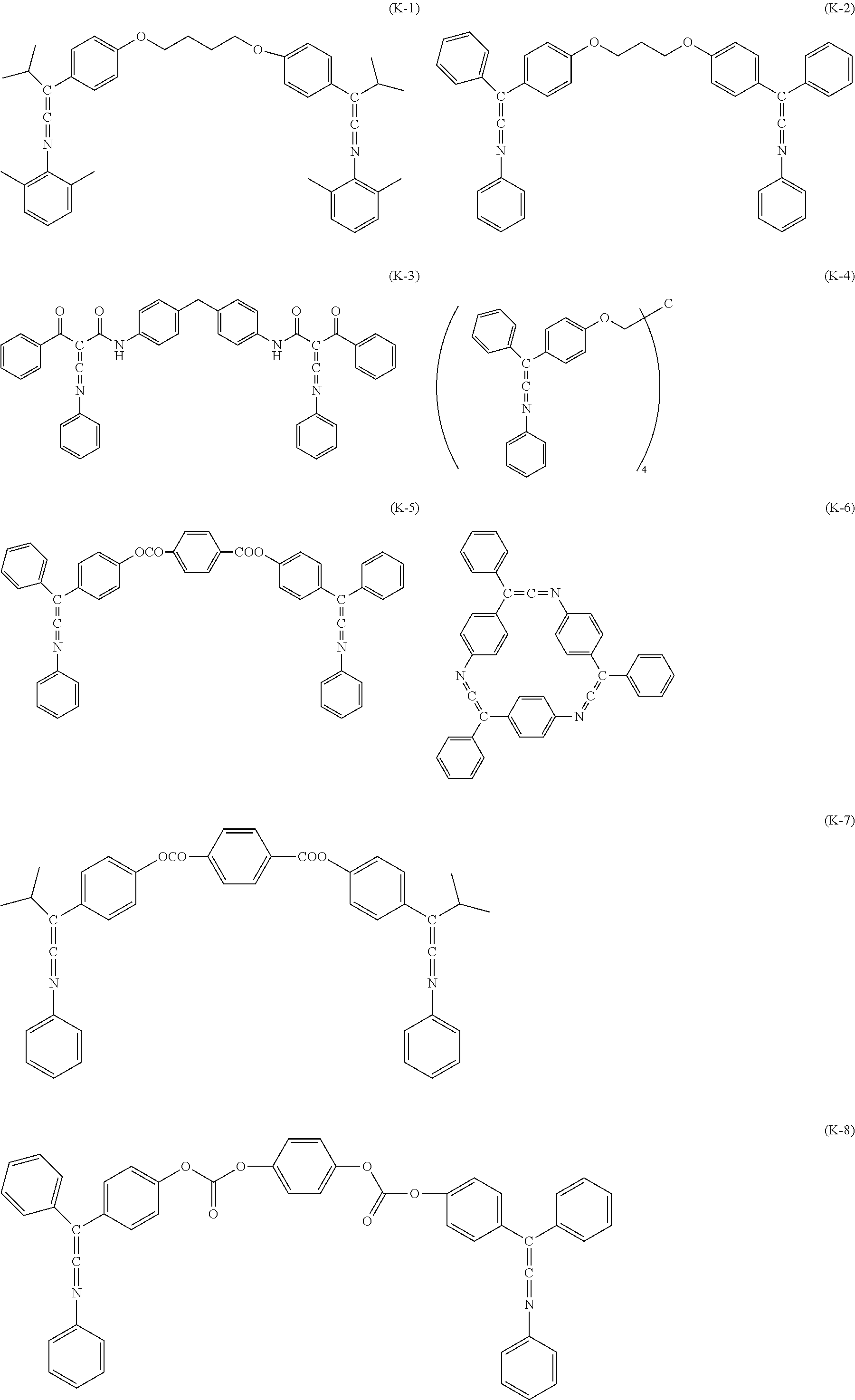

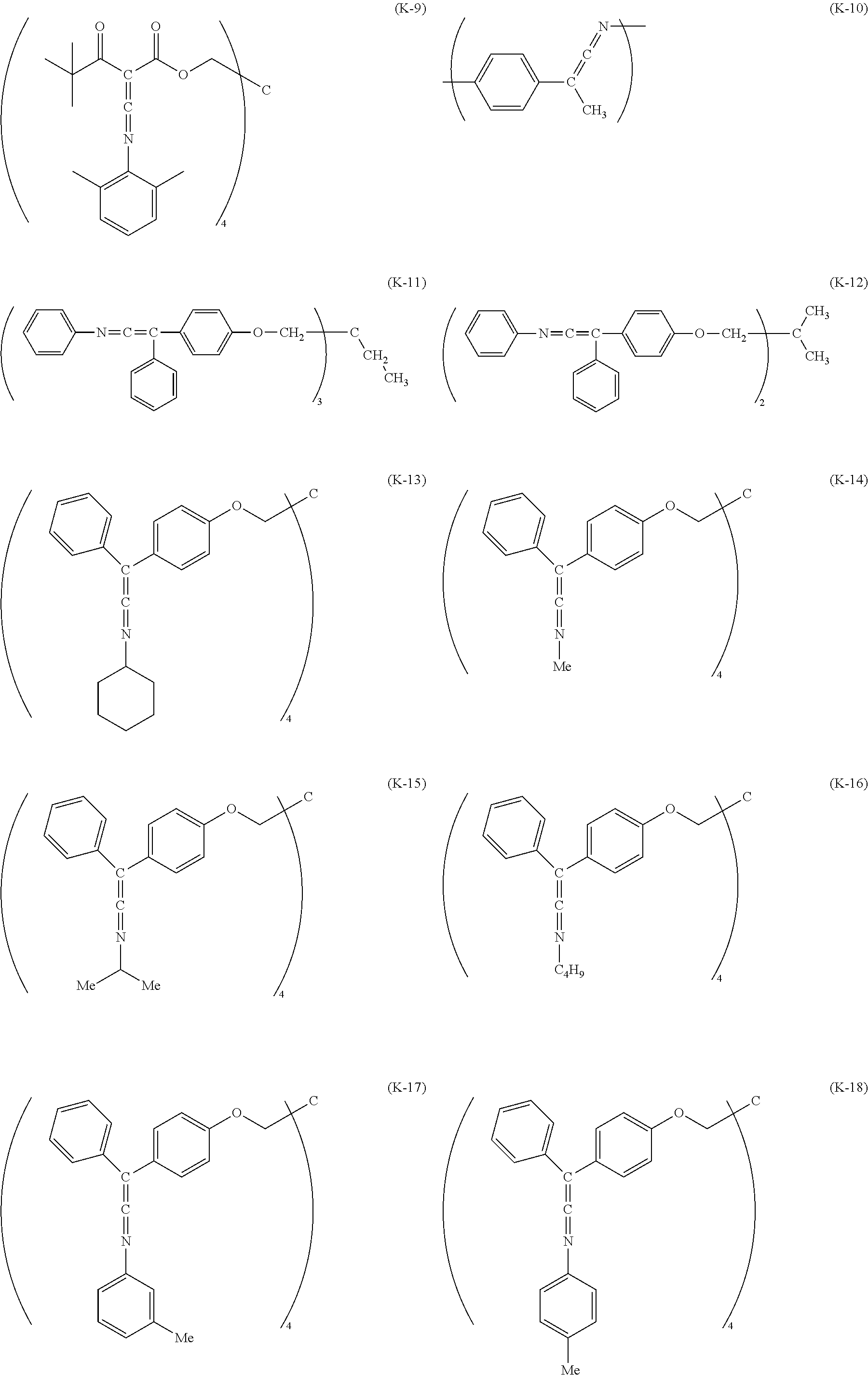

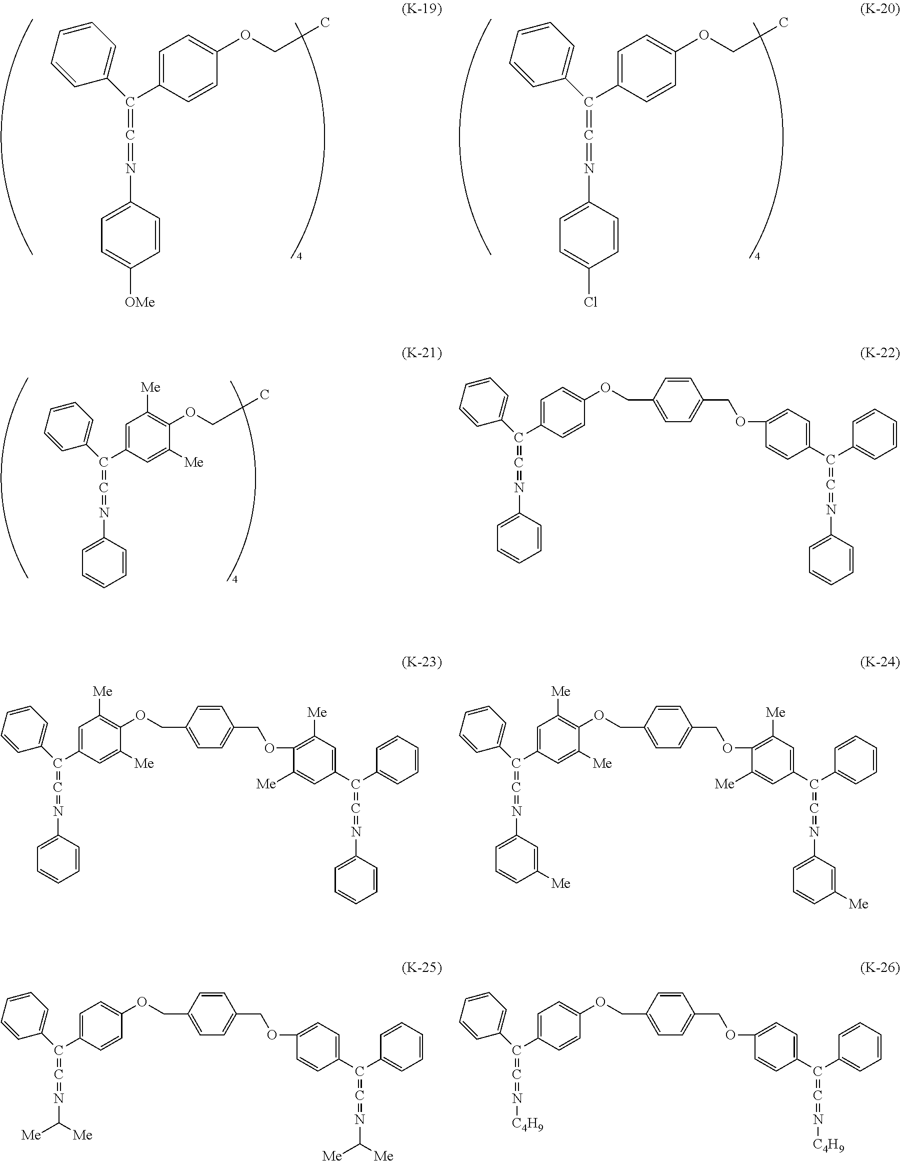

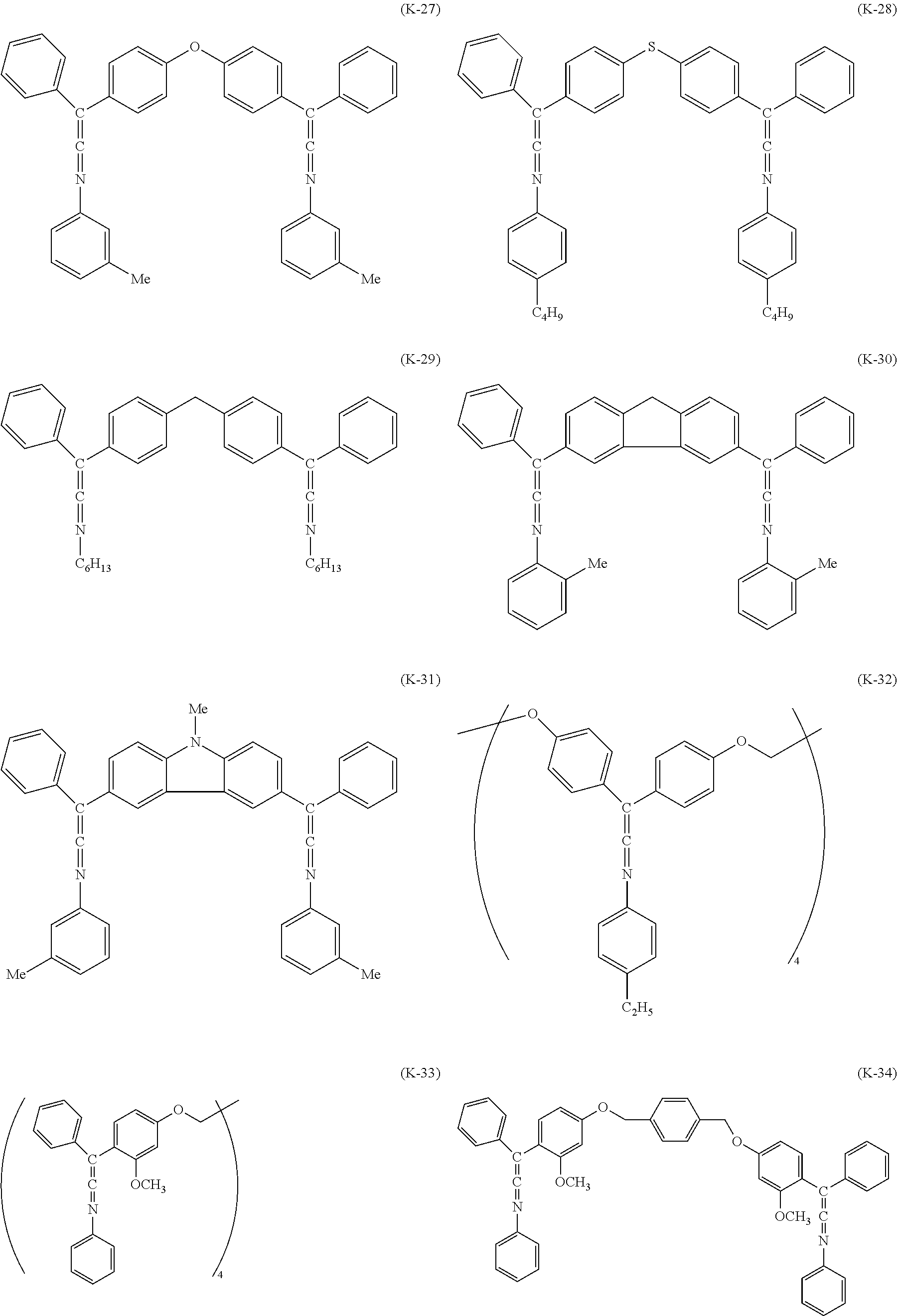

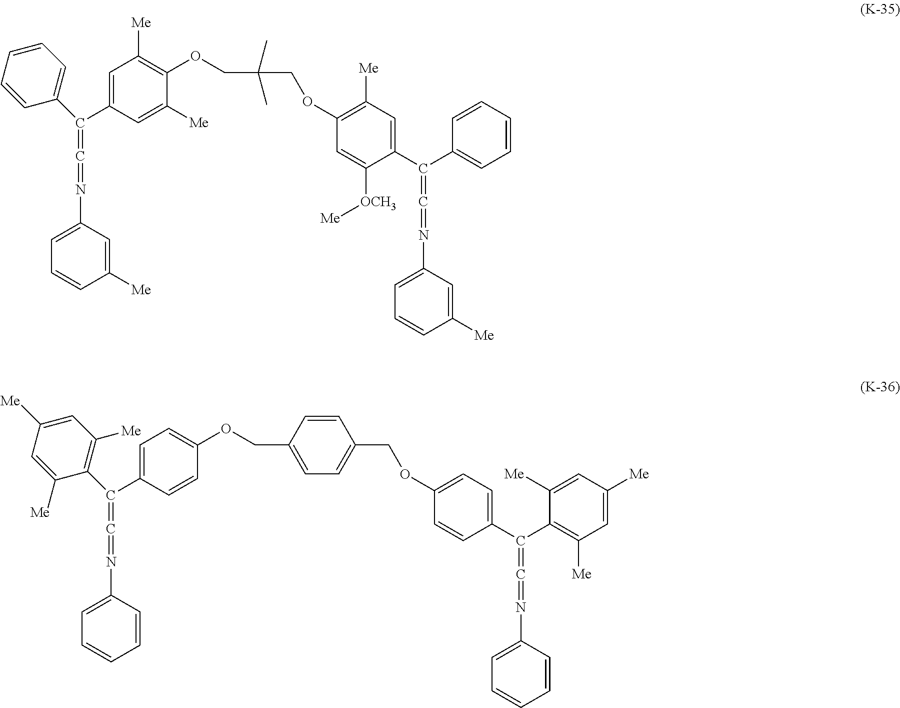

As illustrated in the above-exemplified compounds, the ketenimine compound is more preferably a trifunctional or tetrafunctional compound. In such a case, it is possible to further enhance the terminal-encapsulating effect and to effectively suppress the sublimation of the ketenimine compound or the ketene compound.

In addition, in a case in which the ketenimine compound has a cyclic structure in which a cyclic skeleton is formed in the ketenimine portion as illustrated in Exemplary Compound (K-6), in General Formulae (K-A) to (K-C), R¹ and R³ are linked to each other so as to form a cyclic structure, and R³ is formed of an alkylene group or an arylene group having a cyclic skeleton. In this case, R¹ has a linking group including the ketenimine portion.

Exemplary Compound (K-10) illustrates the repetition unit of which as many as n are included in General Formulae (K-A) to (K-C), and n represents an integer of 3 or more. The left terminal illustrated in Exemplary Compound (K-10) is a hydrogen atom, and the right terminal is a phenyl group.

—Method for Manufacturing Supporter—

Hereinafter, a preferred aspect of a method for manufacturing the supporter will be described using a case in which the supporter is the polyester as an example.

The supporter is preferably a biaxial stretched film obtained by, for example, melt-extruding the polyester in a film form, solidifying the polyester film through cooling using a casting drum so as to produce an unstretched film, stretching the unstretched film in the longitudinal direction once or more at a temperature in a range of the glass transition temperature (Tg, unit: ° C.) to (Tg+60° C.) so that the total ratio reaches three times to six times, and then stretching the film in the width direction at a temperature in a range of Tg to (Tg+60° C.) so that the ratio reaches three times to five times.

Furthermore, the polyester film may be subjected to a thermal treatment at a temperature in a range of 180° C. to 230° C. for 1 second to 60 seconds.

Hereinafter, as a preferred aspect of the method for manufacturing the supporter, an example of the method for manufacturing a polyester film will be described.

Polyester Film-Forming Step:

In a polyester film-forming step, that is, a step of forming a polyester film, it is possible to form a (unstretched) film by causing a molten body obtained by melting the polyester included in a resin composition and at least one of the ketenimine compound and the carbodiimide compound to pass through a gear pump or a filter, then, extruding the molten body through a die into a cooling roll, and solidifying the molten body through cooling. The melting is carried out using an extruder, but a monoaxial extruder may be used or a diaxial extruder may be used.

The carbodiimide compound or the ketenimine compound may be directly added to the extruder, but it is preferable to form a master batch with the polyester in advance and inject the master batch into the extruder from the viewpoint of extrusion stability. In a case in which the master batch is formed, it is preferable to vary the supply amount of the master batch including the ketenimine compound. Meanwhile, regarding the concentration of ketenimine in the master batch, a ketenimine-condensed master batch is preferably used, and the concentration of ketenimine is preferably set in a range of 2 times to 100 times and more preferably set in a range of 5 times to 50 times the concentration of ketenimine in the film after the formation of the film.

The extrusion is preferably carried out under evacuation or in an inert gas atmosphere. In such a case, it is possible to suppress the decomposition of ketenimine, the carbodiimide compound, and the like. The temperature of the extruder is preferably in a range of the melting point of the polyester being used to the melting point+80° C., more preferably in a range of the melting point+10° C. to the melting point+70° C., and still more preferably in a range of the melting point+20° C. to the melting point+60° C. When the temperature of the extruder is below the above-described range, the resin is not sufficiently melted, and, on the other hand, when the temperature of the extruder is above the above-described range, the polyester, the ketenimine compound, the carbodiimide compound, and the like are easily decomposed. Meanwhile, it is preferable to dry the polyester or the master patches of the ketenimine compound, the carbodiimide compound, and the like before the extrusion, and the water content ratio is preferably in a range of 10 ppm to 300 ppm and more preferably in a range of 20 ppm to 150 ppm.

Meanwhile, the extruded molten body is caused to pass through a gear pump, a filter, and a multilayer die and flow onto a casting drum. As the multilayer die, either of a multi-manifold die and a feedblock die can be preferably used. Regarding the shape of the die, any of a T die, a coat hanger die, and a fish tail may be used. At the front end of the above-described die (die lip), a change in temperature as described above is preferably imparted. On the casting drum, it is possible to closely attach the molten resin (melt) to the cooling roll using an electrostatic application method. At this time, it is preferable to impart a change as described above to the driving speed of the casting drum. The surface temperature of the casting drum can be set in a range of approximately 10° C. to 40° C. The diameter of the casting drum is preferably in a range of 0.5 m to 5 m and more preferably in a range of 1 m to 4 m. The driving speed of the casting drum (the linear speed of the outermost circumference) is preferably in a range of 1 m/minute to 50 m/minute and more preferably in a range of 3 m/minute to 30 m/minute.

Stretching Step:

The (unstretched) film formed through the film-forming step can be subjected to a stretching treatment in the stretching step. The stretching is preferably carried out in at least one direction of the vertical direction (MD) and the horizontal direction (TD) and more preferably carried out in both directions of MD and TD since the properties of the film are balanced. The above-described bidirectional stretching may be sequentially carried out in the vertical and horizontal directions or may be carried out at the same time. In the stretching step, the (unstretched) film solidified through cooling using the cooling roll is preferably stretched in one or two directions and more preferably stretched in two directions. The stretching in two directions (biaxial stretching) is preferably a combination of stretching in the longitudinal direction (MD: machine direction) (hereinafter, also referred to as “vertical stretching”) and stretching in the width direction (TD: transverse direction) (hereinafter, also referred to as “horizontal stretching”). The vertical stretching and the horizontal stretching may be carried out once respectively or may be carried out a plurality of times, and the stretching may be carried out vertically and horizontally at the same time.

The stretching treatment is preferably carried out at a temperature in a range of the glass transition temperature (Tg, unit: ° C.) to (Tg+60° C.), more preferably carried out at a temperature in a range of (Tg+3° C.) to (Tg+40° C.), and still more preferably carried out at a temperature in a range of (Tg+5° C.) to (Tg+30° C.). At this time, it is preferable to impart a temperature distribution as described above.

The preferred stretch ratio is, at least in a single direction, in a range of 280% to 500%, more preferably in a range of 300% to 480%, and still more preferably in a range of 320% to 460%. In the case of biaxial stretching, the polyester film may be equally stretched vertically and horizontally, but it is more preferable to unequally stretch the polyester film by setting the stretch ratio in one direction to be greater than that in the other direction. Any stretch ratio in the vertical direction (MD) or in the horizontal direction (TD) may be set to be greater. The stretch ratio mentioned herein is obtained using the following expression.

Stretch ratio (%)=100×{(length after stretching)/(length before stretching)}

The biaxial stretching treatment can be carried out by, for example, stretching the polyester film once or more in the longitudinal direction at a temperature in a range of the glass transition temperature of the film (Tg₁)° C. to (Tg₁+60)° C. so that the total ratio reaches three times to six times, and then stretching the film in the width direction at a temperature in a range of (Tg₁)° C. to (Tg₁+60)° C. so that the ratio reaches three times to five times.

In the vertical biaxial stretching treatment, the polyester film can be stretched in the longitudinal direction using two or more pairs of nip rollers having an increased outlet-side circumferential speed (vertical stretching), or the polyester film may be stretched by gripping the polyester film in the width direction using chucks and then widening the gap between the chucks in the longitudinal direction.

The horizontal stretching can be carried out by gripping both ends of the film using chucks and widening both ends in an orthogonal direction (a direction perpendicular to the longitudinal direction) (horizontal stretching).

The simultaneous stretching can be carried out by combining the gripping of the polyester film using chucks, an operation of widening the gap between the chucks in the longitudinal direction, and an operation of widening the gap between the chucks in the width direction.

A step of coating an undercoat layer described below is preferably combined with these stretching steps. The undercoat layer is preferably formed on the surface of the polyester film through coating before the above-described stretching steps or between the stretching steps. That is, in the present invention, it is preferable to stretch a polyester film base material at least once.

For example, the stretching step and the coating step can be carried out in a combination as described below.
(a) Vertical stretching→coating→horizontal stretching
(b) Coating→vertical stretching→horizontal stretching
(c) Coating→vertical and horizontal stretching at the same time
(d) Vertical stretching→horizontal stretching→coating→vertical stretching
(e) Vertical stretching→horizontal stretching→coating-horizontal stretching

Among these, (a), (b), and (c) are preferred, and (a) is more preferred. This method is preferred since the adhering force is strongest and a facility therefor is also compact.

In the stretching step, it is possible to carry out a thermal treatment on the film before or after the stretching treatment, preferably, after the stretching treatment. When the thermal treatment is carried out, fine crystals are generated, and mechanical characteristics or durability can be improved. The film may be subjected to a thermal treatment at a temperature in a range of 180° C. to 240° C. (more preferably in a range of 200° C. to 230° C.) for 1 second to 60 seconds (more preferably for 2 seconds to 30 seconds).

In the stretching step, it is possible to carry out a thermal relaxation treatment after the thermal treatment. The thermal relaxation treatment refers to a treatment of applying heat to the film in order for the relaxation of stress so as to contract the film. The thermal relaxation treatment is preferably carried out in both directions of MD and TD of the film. Regarding a variety of conditions for the thermal relaxation treatment, the thermal relaxation treatment is preferably carried out at a temperature lower than the thermal treatment temperature, which is preferably in a range of 130° C. to 220° C. In addition, in the thermal relaxation treatment, the thermal contraction ratio (150° C.) of the film is preferably in a range of −1% to 12% and more preferably in a range of 0% to 10% in both MD and TD. Furthermore, the thermal contraction ratio (150° C.) can be obtained by cutting out a sample which is 350 mm long in the measurement direction and is 50 mm wide, marking reference points in the vicinities of both edges of the sample in the longitudinal direction at intervals of 300 mm, fixing one edge to an oven having a temperature adjusted to 150° C., leaving the other edge to be free for 30 minutes, then, measuring the distances between the reference points at room temperature, defining this length as L (mm), and obtaining the thermal contraction ratio from the following expression using the measurement values.

Thermal contraction ratio (%) at 150° C.=100×(300−L)/300

In addition, a positive thermal contraction ratio indicates contraction, and a negative thermal contraction ratio indicates elongation.

Through the above-described steps, the polyester film as the supporter is manufactured.

—Other Items—

The thickness of the supporter is preferably in a range of 30 μm to 350 μm; however, from the viewpoint of voltage resistance, the thickness thereof is more preferably in a range of 160 μm to 300 μm, and still more preferably in a range of 180 μm to 280 μm.

After the supporter is stored for 50 hours under conditions of 120° C. and a relative humidity of 100%, the breaking elongation is preferably 50% or more of the breaking elongation before the storage (hereinafter, the retention ratio of the breaking elongation before and after the treatment of the supporter that has been subjected to a heat-and-humid treatment under the above-described conditions will also be simply referred to as “breaking elongation retention ratio”). When the breaking elongation retention ratio is 50% or higher, a change in response to hydrolysis is suppressed, and, in the case of long-term use, the adhesion state in the adhesion interface between a coated layer and the supporter is stably retained, whereby the peeling or the like of the supporter over time is prevented. Therefore, for example, even in a case in which the backsheet is placed for a long period of time in a high temperature and humidity environment such as outdoors or under the exposure to light, high durability performance is exhibited. More preferably, the time taken for the breaking elongation retention ratio to reach 50% is preferably in a range of 70 hours to 200 hours and more preferably in a range of 75 hours to 180 hours.

It is preferable that, after the supporter is thermally treated for 50 hours at 180° C., the breaking elongation is 50% or more of the breaking elongation before the thermal treatment. It is more preferable that, after the supporter is thermally treated for 80 hours at 180° C., the breaking elongation is 50% or more of the breaking elongation before the thermal treatment. It is still more preferable that, after the supporter is thermally treated for 100 hours at 180° C., the breaking elongation is 50% or more of the breaking elongation before the thermal treatment. In such a case, it is possible to make heat resistance favorable when the supporter is exposed to a high temperature.

When the supporter is thermally treated for 30 minutes at 150° C., the thermal contraction ratio is preferably 1% or less and more preferably 0.5% or less in both MD and TD. When the thermal contraction ratio is maintained to be 1% or less, it is possible to prevent warping when a solar cell module is formed.

The supporter may be subjected to surface treatments such as a corona discharge treatment, a flame treatment, and a glow discharge treatment as necessary. Among these, the corona discharge treatment can be carried out at a low cost and thus is a preferred surface treatment method.

In the corona discharge treatment, a high frequency and a high voltage are applied between a metallic roll which is generally coated with a dielectric body (dielectric roll) and an insulated electrode so as to cause the insulation breakdown of air between electrodes, whereby the air between the electrodes is ionized and corona discharge is generated between the electrodes. In addition, the supporter is caused to pass through this corona discharge.

Regarding preferred treatment conditions used in the present invention, it is preferable that the gap clearance between the electrode and the dielectric roll is in a range of 1 mm to 3 mm, the frequency is in a range of 1 kHz to 100 kHz, and the applied energy is in a range of approximately 0.2 kV·A·minutes/m² to 5 kV·A·minutes/m².

The glow discharge treatment is a method which is also called a vacuum plasma treatment or a glow discharge treatment and in which plasma is generated through discharging in a gas in a low-pressure atmosphere (plasma gas), thereby treating the surface of a base material. Low-pressure plasma used in the treatment of the present invention is non-equilibrium plasma generated under a condition in which the pressure of the plasma gas is low. The treatment of the present invention is carried out by placing a film to be treated in this low-pressure plasma atmosphere.

As the method for generating plasma in the glow discharge treatment, it is possible to use a method of direct-current glow discharge, high-frequency discharge, microwave discharge, or the like. The power supply used for the discharge may be a direct current or an alternating current. In a case in which an alternating current is used, the frequency is preferably in a range of approximately 30 Hz to 20 MHz.

In a case in which an alternating current is used, a commercial frequency of 50 Hz or 60 Hz may be used or a high frequency in a range of approximately 10 kHz to 50 kHz may be used. In addition, a method of using a high frequency of 13.56 MHz is also preferred.

As the plasma gas used in the glow discharge treatment, it is possible to use an inorganic gas such as oxygen gas, nitrogen gas, water vapor gas, argon gas, or helium gas, and oxygen gas or a gas mixture of oxygen gas and argon gas is particularly preferred. Specifically, the gas mixture of oxygen gas and argon gas is desirably used. In a case in which oxygen gas and argon gas are used, the partial pressure ratio between both gases (oxygen gas and argon gas) is preferably in a range of approximately 100:0 to 30:70 and more preferably in a range of approximately 90:10 to 70:30. In addition, particularly, a method in which gas is not introduced into a treatment container, and gas such as air entering the treatment container through leaking or water vapor emitted from a substance to be treated is used as the plasma gas is also preferred.

Here, as the pressure of the plasma gas, a low pressure capable of achieving non-equilibrium plasma conditions is required. A specific pressure of the plasma gas is preferably in a range of approximately 0.005 Torr to 10 Torr and more preferably in a range of approximately 0.008 Torr to 3 Torr. In a case in which the pressure of the plasma gas is lower than 0.005 Torr, there are cases in which the adhesiveness-improving effect is insufficient, and conversely, when the pressure of the plasma gas exceeds 10 Torr, there are cases in which an electric current increases and thus discharging becomes unstable.

While it is not possible to say the specific value of the plasma output since the plasma output varies depending on the shape or size of the treatment container, the shape of the electrode, and the like, but the plasma output is preferably in a range of approximately 100 W to 2500 W and more preferably in a range of approximately 500 W to 1500 W.

The treatment time of the glow discharge treatment is preferably in a range of approximately 0.05 seconds to 100 seconds and more preferably in a range of approximately 0.5 seconds to 30 seconds. In a case in which the treatment time is shorter than 0.05 seconds, there are cases in which the adhesiveness-improving effect is insufficient, and conversely, when the treatment time exceeds 100 seconds, there are cases in which a problem of the deformation or discoloration of a film to be treated occurs.

The discharge treatment intensity of the glow discharge treatment varies depending on the plasma output and the treatment time, but is preferably in a range of 0.01 kV·A·minutes/m² to 10 kV·A·minutes/m² and more preferably in a range of 0.1 kV·A·minutes/m² to 7 kV·A·minutes/m². When the discharge treatment intensity is set to 0.01 kV·A·minutes/m² or higher, a sufficient adhesiveness-improving effect can be obtained, and, when the discharge treatment intensity is set to 10 kV·A·minutes/m² or lower, it is possible to avoid the problem of the deformation or discoloration of the film to be treated.

In the glow discharge treatment, it is also preferable to heat the film to be treated in advance. In such a case, compared with a case in which the film is not heated in advance, favorable adhesiveness can be obtained within a short period of time. The temperature of the heating is preferably in a range of 40° C. to (the softening temperature of the film to be treated+20° C.) and more preferably in a range of 70° C. to the softening temperature of the film to be treated. When the temperature of the heating is set to 40° C. or higher, a sufficient adhesiveness-improving effect can be obtained. In addition, when the temperature of the heating is set to the softening temperature or lower of the film to be treated, it is possible to ensure favorable handling properties of the film to be treated in a vacuum.

Specific examples of a method for increasing the temperature of the film to be treated in a vacuum include heating using an infrared heater and heating by bringing the film into contact with a hot roll.

(A Layer)

The A layer is a layer including the nonionic surfactant (S) and is constituted by, for example, including a binder and the nonionic surfactant (S) as an antistatic material.

Meanwhile, the A layer may include other additives as necessary.

Binder

Examples of the binder include one or more polymers selected from polyolefin resins, acrylic resins, polyester resins, and polyurethane resins. These resins are preferably used since an adhering force can be easily obtained. More specific examples of the binder include the following resins.

The acrylic resin is preferably, for example, a polymer containing polymethyl methacrylate or polyethyl acrylate, or the like. The acrylic resin is also preferably a composite resin of acryl and silicone. A commercially available acrylic resin on sale may be used, and examples thereof include AS-563A (manufactured by Daicel FineChem Ltd.), and JURYMER ET-410 and JURYMER SEK-301 (both manufactured by Nippon Junyaku K.K.). Examples of the composite resin of acryl and silicone include CERANATE WSA1060, CERANATE WSA1070 (both manufactured by DIC Corporation), H7620, H7630, and H7650 (all manufactured by Asahi Kasei Chemicals Corporation).

The polyester resin is preferably a modified polyester resin or the like. A commercially available polyester resin on sale may be used, and, for example, VYLONAL MD-1245 (manufactured by Toyobo Co., Ltd.) can be preferably used.

The polyurethane resin is preferably, for example, a carbonate-based urethane resin, and, for example, SUPERFLEX 460 (manufactured by DKS Co., Ltd.) can be preferably used.

The polyolefin resin is preferably, for example, a modified polyolefin copolymer. A commercially available polyolefin resin on sale may be used, and examples thereof include ARROW-BASE SE-1013N, SD-1010, TC-4010, TD-4010 (all manufactured by Unitika Limited), HITECH S3148, HITECH S3121, HITECH S8512 (all manufactured by Toho Chemical Industry Co., Ltd.), CHEMIPAL S-120, CHEMIPAL S-75N, CHEMIPAL V100, CHEMIPAL EV210H (manufactured by Mitsui Chemicals, Inc.), and the like. Among these, ARROW-BASE SE-1013N manufactured by Unitika Limited, which is a ternary copolymer of low-density polyethylene, acrylic acid ester, and maleic acid anhydride, is preferably used since the adhesiveness is improved.

These polyolefin resins may be used singly or two or more polyolefin resins may be jointly used. In a case in which two or more polyolefin resins are jointly used, a combination of an acrylic resin and a polyolefin resin, a combination of a polyester resin and a polyolefin resin, or a combination of a urethane resin and a polyolefin resin is preferred and a combination of an acrylic resin and a polyolefin resin is more preferred.

In a case in which a combination of an acrylic resin and a polyolefin resin is used, the content of the acrylic resin in relation to the total of the polyolefin resin and the acrylic resin in the A layer is preferably in a range of 3% by mass to 50% by mass, more preferably in a range of 5% by mass to 40% by mass, and particularly preferably in a range of 7% by mass to 25% by mass.

It is possible to preferably combine a polyester resin (for example, VYLONAL MD-1245 (manufactured by Toyobo Co., Ltd.)) and the polyolefin resin and use the combination. In addition, it is also preferable to add a polyurethane resin to the polyolefin resin, and the polyurethane resin is preferably, for example, a carbonate-based urethane resin, and, for example, SUPERFLEX 460 (manufactured by DKS Co., Ltd.) can be preferably used.

—Crosslinking Agent—

The binder (resin) may be crosslinked using a crosslinking agent. The binder is more preferably crosslinked since the adhesiveness can be improved. Examples of the crosslinking agent include epoxy-based, isocyanate-based, melamine-based, carbodiimide-based, and oxazoline-based crosslinking agents. Among these, in the present invention, the crosslinking agent is preferably an oxazoline-based crosslinking agent. As a crosslinking agent having an oxazoline group, it is possible to use EPOCROS K2010E, EPOCROS K2020E, EPOCROS K2030E, EPOCROS WS-500, EPOCROS WS-700 (manufactured by Nippon Shokubai Co., Ltd.), or the like.

The amount of the crosslinking agent added is preferably in a range of 0.5% by mass to 50% by mass, more preferably in a range of 3% by mass to 40% by mass, and particularly preferably in a range of 5% by mass to lower than 30% by mass of the binder. Particularly, when the amount of the crosslinking agent added is 0.5% by mass or higher, a sufficient crosslinking effect is obtained while maintaining the intensity and adhesiveness of the A layer; when the amount thereof is 50% by mass or lower, the pot life of a coating fluid is maintained for a long period of time; when the amount thereof is lower than 40% by mass, the coating surface properties can be improved.

—Catalyst for Crosslinking Agent—

A catalyst for the crosslinking agent may be jointly used with the crosslinking agent.

When a catalyst for the crosslinking agent is included, a crosslinking reaction between the binder (resin) and the crosslinking agent is accelerated, and the solvent resistance is improved.

In addition, the favorable progress of crosslinking may lead to an improvement of the adhesiveness of the A layer.

Particularly, in a case in which a crosslinking agent having an oxazoline group (an oxazoline-based crosslinking agent) is used as the crosslinking agent, the catalyst for the crosslinking agent is preferably used.

Examples of the catalyst for the crosslinking agent include onium compounds.

Preferable examples of the onium compounds include ammonium salts, sulfonium salts, oxonium salts, iodonium salts, phosphonium salts, nitronium salts, nitrosonium salts, diazonium salts, and the like.

Specific examples of the onium compounds include
ammonium salts such as monoammonium phosphate, diammonium phosphate, ammonium chloride, ammonium sulfate, ammonium nitrate, ammonium p-toluenesulfonate, ammonium sulfamate, ammonium imidodisulfonate, tetrabutylammonium chloride, benzyltrimethylammonium chloride, triethylbenzylammonium chloride, tetrabutylammonium tetrafluoroboron, tetrabutylammonium phosphorous hexafluoride, tetrabutylammonium perchlorate, and tetrabutylammonium sulfate;
sulfonium salts such as trimethylsulfonium iodide, trimethylsulfonium tetrafluoroboron, diphenylmethylsulfonium tetrafluoroboron, benzyltetramethylenesulfonium tetrafluoroboron, 2-butenyltetramethylenesulfonium antimony hexafluoride, and 3-methyl-2-butenyltetramethylensulfonium antimony hexafluoride; oxonium salts such as trimethyloxonium tetrafluoroboron;
iodonium salts such as diphenyl iodonium chloride and diphenyl iodonium tetrafluoroboron;
phosphonium salts such as cyanomethyltributylphosphonium antimony hexafluoride and ethoxycarbonylmethyltributylphosphonium tetrafluoroboron; nitronium salts such as nitronium tetrafluoroboron; nitrosonium salts such as nitrosonium tetrafluoroboron;
diazonium salts such as 4-methoxybenzenediazonium chloride; and
the like.

Among these, the onium compounds are more preferably the ammonium salts, the sulfonium salts, the iodonium salts, and the phosphonium salts in terms of shortening the curing time; among these, the ammonium salts are more preferred, and, from the viewpoint of safety, pH, and cost, phosphoric acid-based salts and benzyl chloride-based salts are preferred. The onium compound is more particularly preferably ammonium diphosphate.

One catalyst for the crosslinking agent may be used or two or more catalysts for the crosslinking agent may be jointly used.

The amount of the catalyst for the crosslinking agent added is preferably in a range of 0.1% by mass to 15% by mass, more preferably in a range of 0.5% by mass to 12% by mass, particularly preferably in a range of 1% by mass to 10% by mass, and more particularly preferably in a range of 2% by mass to 7% by mass of the crosslinking agent. The amount of the catalyst for the crosslinking agent of 0.1% by mass or higher of the crosslinking agent means that the crosslinking agent actively includes the catalyst for the crosslinking agent, and the inclusion of the catalyst for the crosslinking agent causes a crosslinking reaction between the binder and the crosslinking agent to favorably proceed, and superior solvent resistance is obtained. In addition, the inclusion of 15% by mass or lower of the catalyst for the crosslinking agent is advantageous in terms of solubility, filtering properties, and adhesion.

—Antistatic Material—

The nonionic surfactant (S) is included as an antistatic material. In addition, as the antistatic material, an antistatic material other than the nonionic surfactant (S) may be jointly used with the nonionic surfactant.

The nonionic surfactant (S) is a nonionic surfactant which has an ethylene glycol chain (polyoxyethylene chain; —(CH₂—CH₂—O)ₙ—) but does not have a carbon-carbon triple bond (alkyne bond). That is, the nonionic surfactant (S) is a nonionic surfactant which has a polyethylene oxide structure but does not have an acetylene group.

The repetition number n of the ethylene glycol chain in the nonionic surfactant (S) is preferably in a range of 5 to 30, more preferably in a range of 7 to 30, and still more preferably in a range of 10 to 20. Meanwhile, the repetition number n of the ethylene glycol chain is the number “n” of the “—(CH₂—CH₂—O)ₙ—” structure and represents the average degree of polymerization of the ethylene glycol.

When the repetition number n of the ethylene glycol chain is set to 5 or greater, the solubility in water or an alcohol solvent (methanol, ethanol, or the like) is easily increased. When the repetition number n of the ethylene glycol chain is set to greater than 30, precipitation on the surface of the A layer becomes poor and there are cases in which it becomes difficult to ensure a desired partial discharge voltage.

Specific examples of the nonionic surfactant (S) include at least one selected from the group consisting of nonionic surfactants represented by General Formulae (SI), (SII), (SIII-A), and (SIII-B).

First, the nonionic surfactant represented by General Formula (SI) will be described.

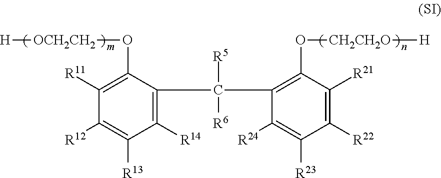

In General Formula (SI), each of R¹¹, R¹³, R²¹, and R²³ independently represents a substituted or unsubstituted alkyl group, aryl group, alkoxy group, halogen atom, acyl group, amide group, sulfonamide group, carbamoyl group, or sulfamoyl group, is preferably a substituted or unsubstituted alkyl group, aryl group, or alkoxy group and most preferably a substituted or unsubstituted alkyl group.

Each of R¹², R¹⁴, R²², and R²⁴ independently represents a hydrogen atom or a substituted or unsubstituted alkyl group, aryl group, alkoxy group, halogen atom, acyl group, amide group, sulfonamide group, carbamoyl group, or sulfamoyl group, and is preferably a hydrogen atom or a substituted or unsubstituted alkyl group.

Each of R⁵ and R⁶ independently represents a hydrogen atom or a substituted or unsubstituted alkyl group or aryl group, and is preferably a hydrogen atom or a substituted or unsubstituted alkyl group.

R¹¹ and R¹², R¹³ and R¹⁴, R²¹ and R²², R²³ and R²⁴, and R⁵ and R⁶ may be bonded to each other so as to form a substituted or unsubstituted ring. Each of m and n independently represents the repetition number (average degree of polymerization) of the polyoxyethylene chain and is a number from 2 to 50. Meanwhile, the substituents on the two phenyl rings in General Formula (SI) may or may not be bilaterally asymmetric.

In General Formula (SI), R¹¹ to R¹⁴ and R²¹ to R²⁴ preferably represent substituted or unsubstituted alkyl groups having 1 to 20 carbon atoms such as methyl, ethyl, i-propyl, t-butyl, t-amyl, t-hexyl, t-octyl, nonyl, decyl, dodecyl, trichloromethyl, tribromomethyl, 1-phenylethyl, and 2-phenyl-2-propyl; substituted or unsubstituted aryl groups such as phenyl groups and p-chlorophenyl groups; and substituted or unsubstituted alkoxy groups or aryloxy groups represented by —OR³³ (here, R³³ represents a substituted or unsubstituted alkyl group or aryl group having 1 to 20 carbon atoms, which shall apply below); halogen atoms such as chlorine atoms and bromine atoms; acyl groups represented by —COR³³; amide groups represented by —NR³⁴COR³³ (here, R³⁴ represents a hydrogen atom or an alkyl group having 1 to 20 carbon atoms, which shall apply below); sulfonamide groups represented by —NR³⁴SO₂R³³; carbamoyl groups represented by —CON(R³⁴)₂; or sulfamoyl groups represented by —SO₂N(R³⁴)₂. Here, R¹², R¹⁴, R²², and R²⁴ may be hydrogen atoms. R¹¹ to R¹⁴ and R²¹ to R²⁴ are preferably substituted or unsubstituted alkyl groups.

Among these, in General Formula (SI), R¹¹, R¹³, R²¹, and R²³ are preferably alkyl groups or halogen atoms and particularly preferably bulky tertiary alkyl groups such as t-butyl groups, t-amyl groups, and t-octyl groups. R¹² to R¹⁴ and R²² to R²⁴ are particularly preferably hydrogen atoms. R⁵ to R⁶ are preferably substituted or unsubstituted alkyl groups such as hydrogen atoms, methyl groups, ethyl groups, n-propyl groups, i-propyl groups, n-heptyl groups, 1-ethylamyl groups, n-undecyl groups, trichloromethyl groups, and tribromomethyl groups; or substituted or unsubstituted aryl groups such as α-furyl groups, phenyl groups, naphthyl groups, p-chlorophenyl groups, p-methoxyphenyl groups, and m-nitrophenyl groups. R¹¹ and R¹², R¹³ and R¹⁴, R²¹ and R²², R²³ and R²⁴, and R⁵ and R⁶ may be bonded to each other so as to form a substituted or unsubstituted ring, for example, form a cyclohexyl ring. Among these, R⁵ and R⁶ particularly preferably represent hydrogen atoms, alkyl groups having 1 to 8 carbon atoms, phenyl groups, or furyl groups. m and n are preferably numbers from 5 to 30 (more preferably numbers from 7 to 30 and still more preferably numbers from 10 to 20). m and n may be identical to or different from each other.

Hereinafter, specific examples of the nonionic surfactant represented by General Formula (SI) will be illustrated, but the present invention is not limited thereto.

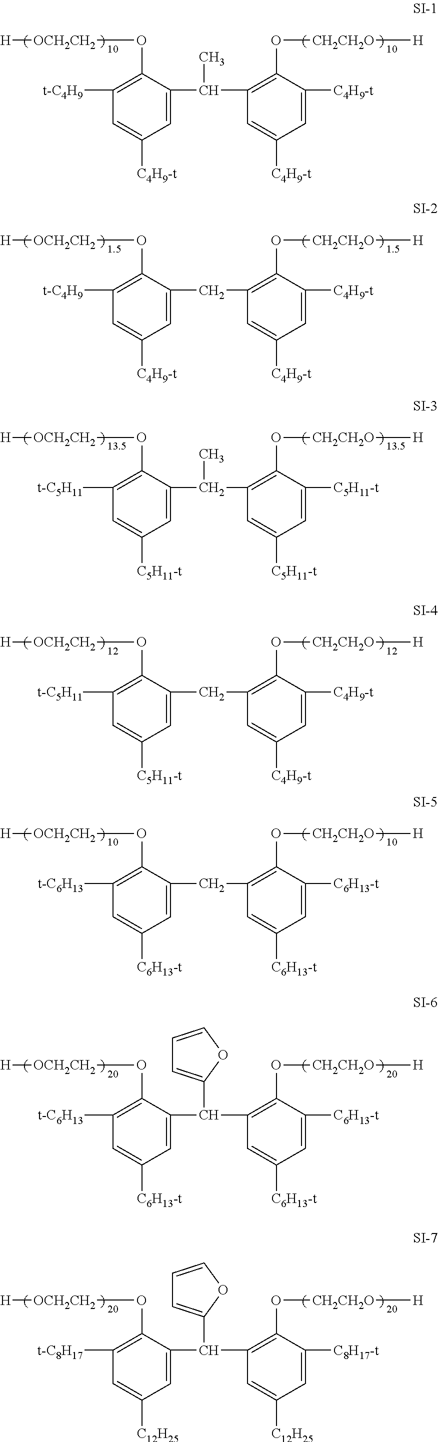

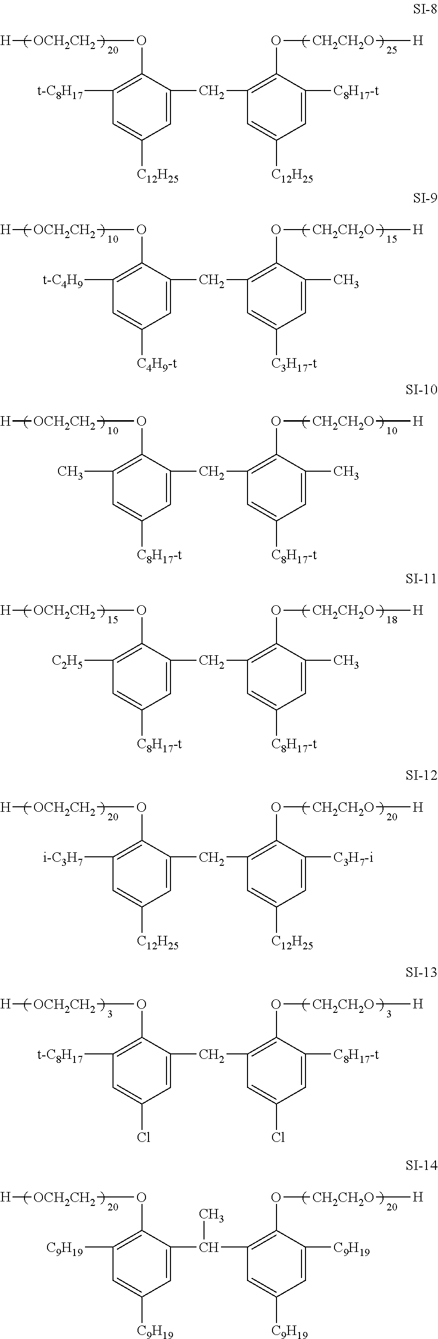

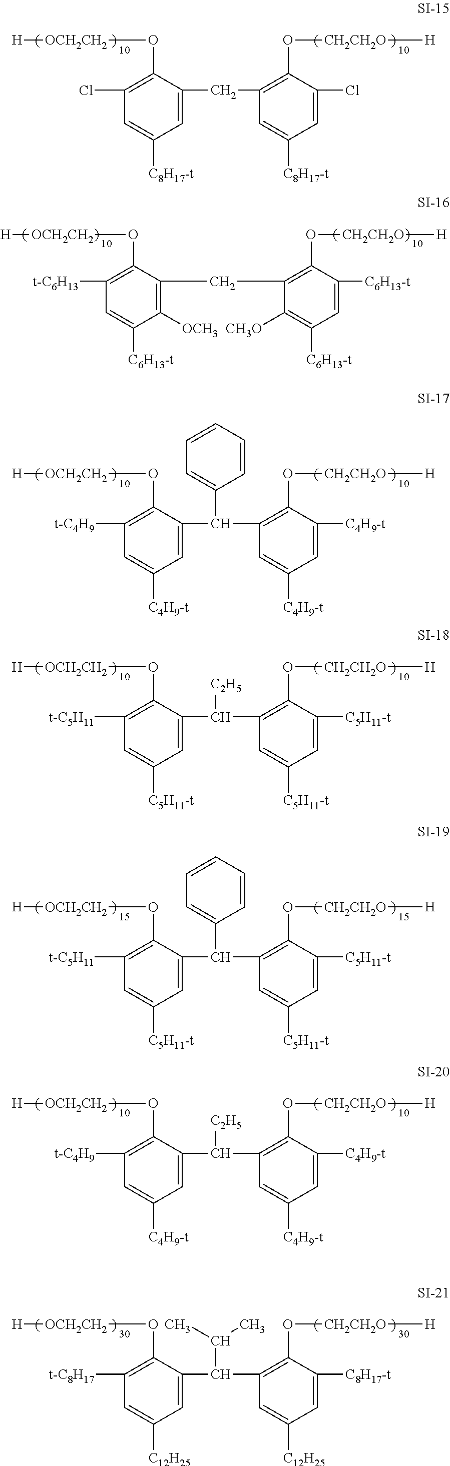

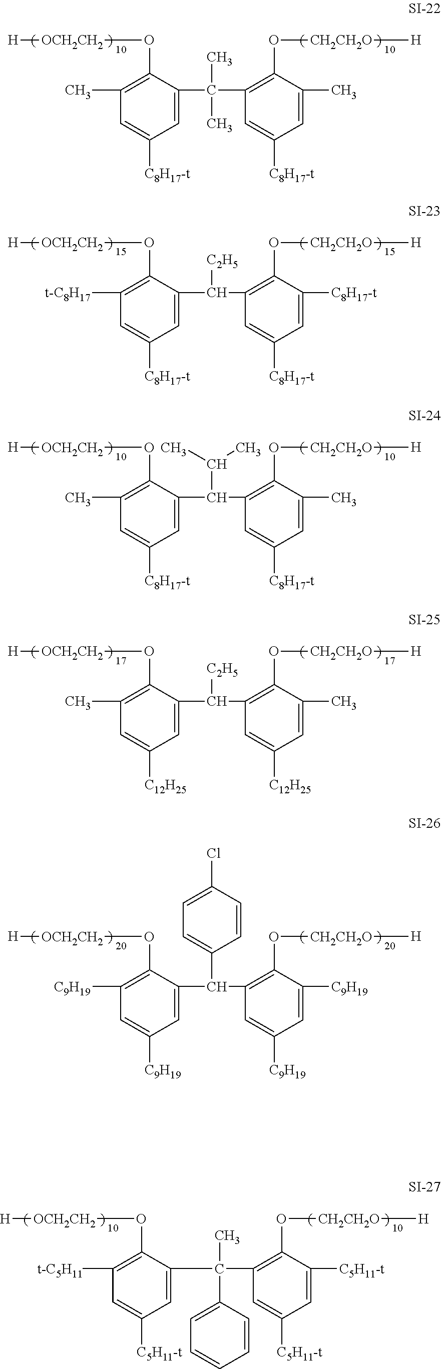

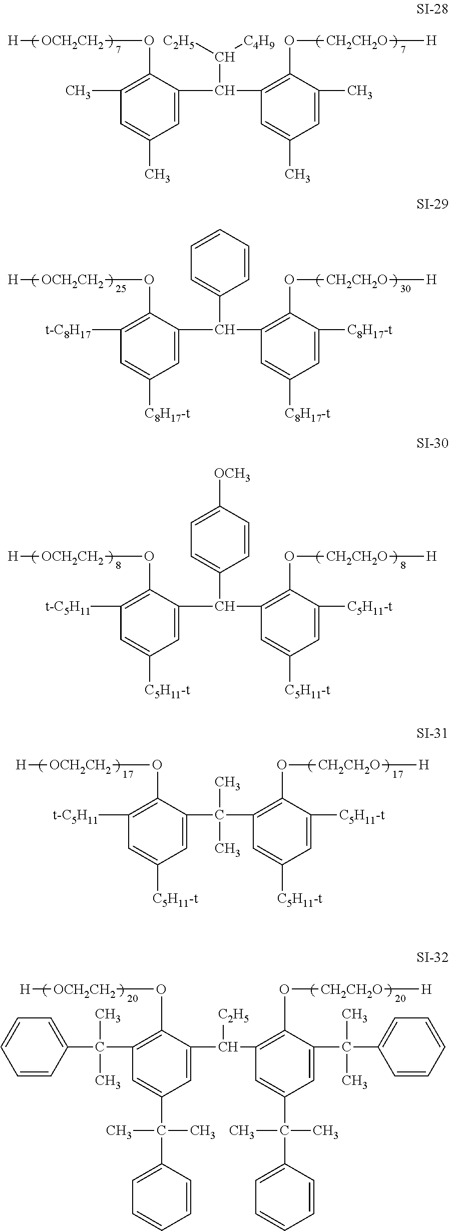

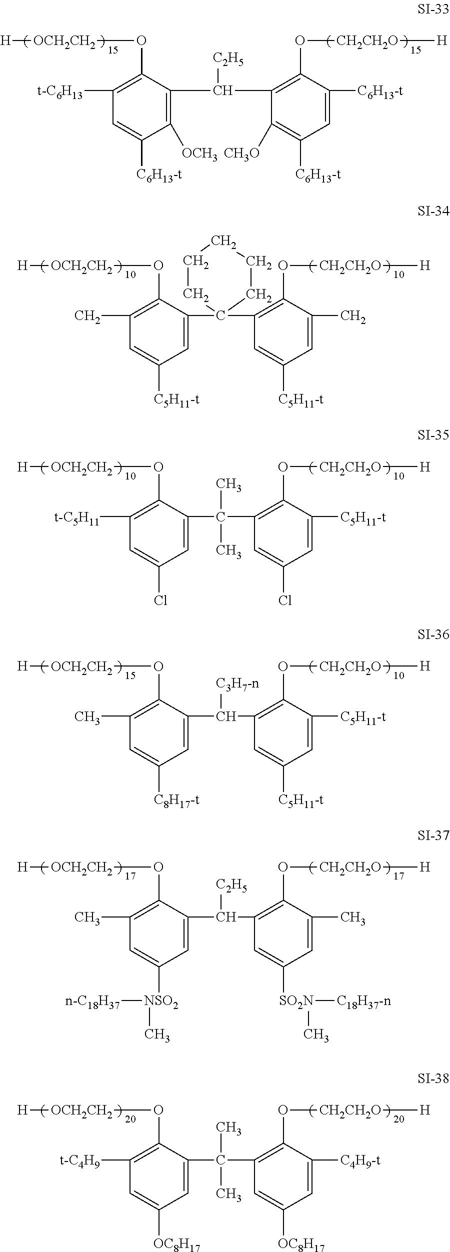

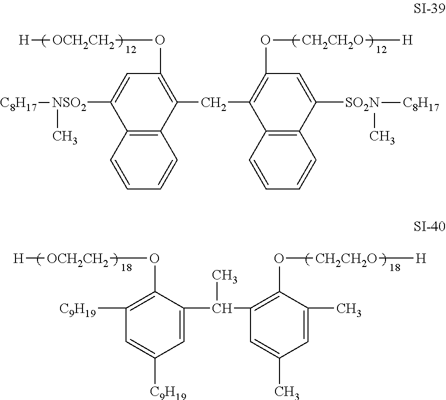

The nonionic surfactant represented by General Formula (SII) will be described.

H₂ₘ₊₁Cₘ—O—(CH₂CH₂O)ₙ—H (SII):

In General Formula (SII), m represents an integer from 0 to 40 (preferably an integer from 0 to 30 and more preferably an integer from 0 to 20). n represents the repetition number (average degree of polymerization) of the polyoxyethylene chain and is a number from 2 to 50 (preferably a number from 5 to 50, more preferably a number from 7 to 30, and still more preferably a number from 10 to 20)).

Hereinafter, specific examples of the nonionic surfactant represented by General Formula (SII) will be illustrated, but the present invention is not limited thereto.
(SII-1): hexaethylene glycol monododecyl ether
(SII-2): 3,6,9,12,15-pentaoxahexadecan-1-ol
(SII-3): hexaethylene glycol monomethyl ether
(SII-4): tetraethylene glycol monododecyl ether
(SII-5): pentaethylene glycol monododecyl ether
(SII-6): heptaethylene glycol dodecyl ether
(SII-7): octaethylene glycol monododecyl ether

The nonionic surfactants represented by General Formulae (SIII-A) and (SIII-B) will be described.

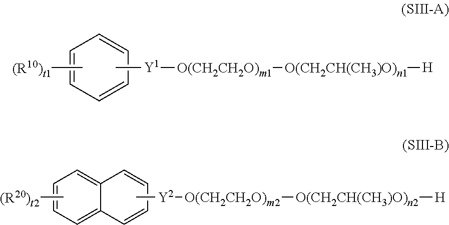

In General Formulae (SIII-A) and (SIII-B), each of R¹⁰ and R²⁰ independently represents a hydrogen atom or an organic group having 1 to 100 carbon atoms, each of t1 and t2 independently represents 1 or 2, each of Y¹ and Y² independently represents a single bond or an alkylene group having 1 to 10 carbon atoms, each of m1 and n1 independently represents 0 or a number from 1 to 100; here, m1 is not 0, and is not 1 in a case in which n1 is 0, and each of m2 and n2 independently represents 0 or a number from 1 to 100; here, m2 is not 0, and is not 1 in a case in which n2 is 0.

In General Formula (SIII-A), when t1 represents 2 and R¹⁰ represents an organic group having 1 to 100 carbon atoms, the two R¹⁰s may be identical to or different from each other, and the two R¹⁰s may be bonded to each other so as to form a ring.

In General Formula (SIII-B), when t2 represents 2 and R²⁰ represents an organic group having 1 to 100 carbon atoms, the two R²⁰s may be identical to or different from each other, and the two R²⁰s may be bonded to each other so as to form a ring.

In General Formulae (SIII-A) and (SIII-B), specific examples of the organic group having 1 to 100 carbon atoms represented by R¹⁰ or R²⁰ include aliphatic hydrocarbon groups and aromatic hydrocarbon groups which may be saturated or unsaturated and may be straight chains or branched chains, and examples thereof include an alkyl group, an alkenyl group, an alkynyl group, an aryl group, and an aralkyl group.

In General Formulae (SIII-A) and (SIII-B), R¹⁰ or R²⁰ is preferably a hydrogen atom or a straight-chain or branched-chain alkyl group having 1 to 10 carbon atoms, an alkoxy group having 1 to 10 carbon atoms, an alkoxycarbonyl group, an N-alkylamino group, an N,N-dialkylamino group, an N-alkylcarbamoyl group, an acyloxy group, an acylamino group, a polyoxyalkylene chain having approximately 5 to 20 repetition units, an aryl group having 6 to 20 carbon atoms, or an aryl group to which a polyoxyalkylene chain having approximately 5 to 20 repetition units is bonded.

In the nonionic surfactants represented by General Formulae (SIII-A) and (SIII-B), the number of repetition units of the polyoxyethylene chain may be in a range of 3 to 50 (preferably in a range of 5 to 50, more preferably in a range of 7 to 30, and still more preferably in a range of 10 to 20). The number of repetition units of a polyoxypropylene chain is preferably in a range of 0 to 10 and more preferably in a range of 0 to 5. The arrangement of a polyoxyethylene portion and a polyoxypropylene portion may be random or block.

Examples of the nonionic surfactant represented by General Formula (SIII-A) include polyoxyethylene phenyl ether, polyoxyethylene methyl phenyl ether, polyoxyethylene octyl phenyl ether, and polyoxyethylene nonyl phenyl ether.

Examples of the nonionic surfactant represented by General Formula (SIII-B) include polyoxyethylene naphthyl ether, polyoxyethylene methyl naphthyl ether, polyoxyethylene octyl naphthyl ether, and polyoxyethylene nonyl naphthyl ether.

Hereinafter, specific examples of the nonionic surfactant represented by General Formula (SIII-A) or (SIII-B) will be illustrated, but the present invention is not limited thereto.

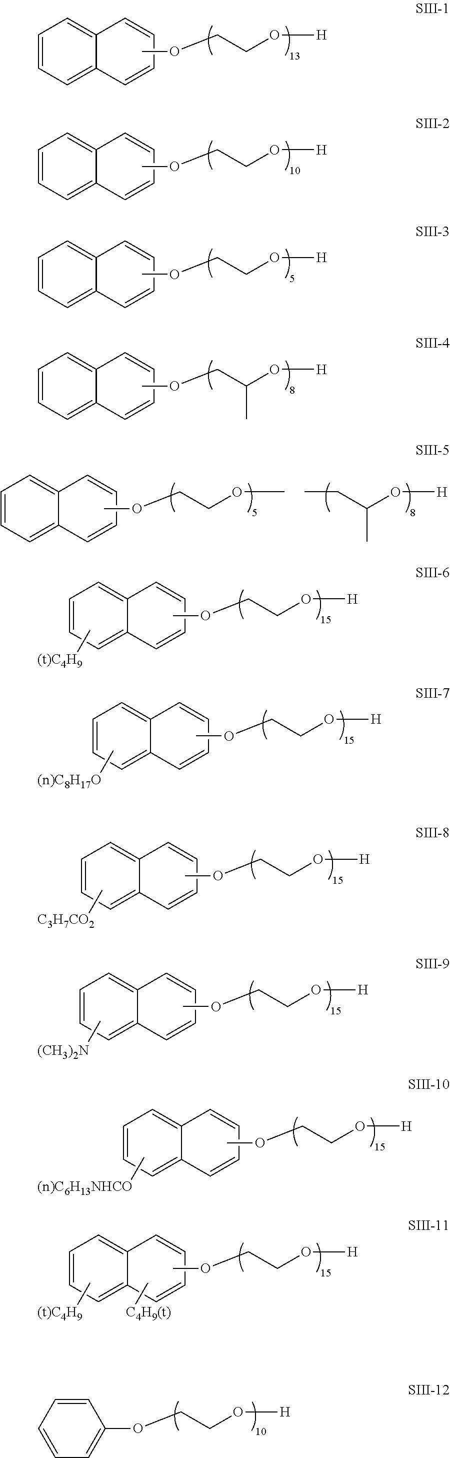

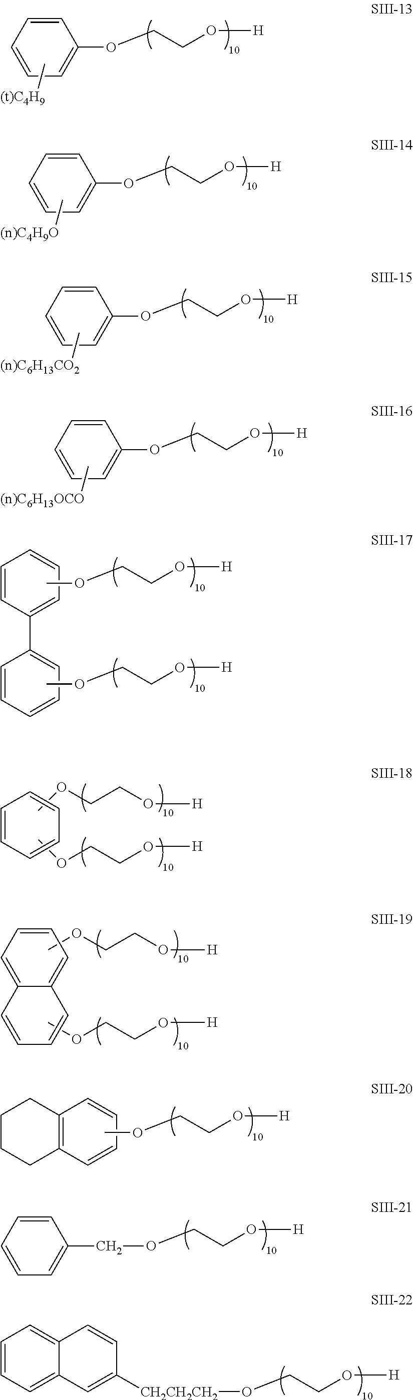

In a case in which the A layer is the outermost layer, the content of the above-described nonionic surfactant (S) is preferably in a range of 2.5% by mass to 50% by mass, more preferably in a range of 5.0% by mass to 40% by mass, and still more preferably in a range of 10% by mass to 30% by mass of the total mass of the A layer.

When the content of the nonionic surfactant (S) is set to 2.5% by mass or higher, a decrease in the partial discharge voltage is suppressed. When the content of the nonionic surfactant (S) is set to 50% by mass or lower, favorable adhesiveness of an encapsulating material (for example, an ethylene vinyl acetate (EVA) copolymer) that encapsulates a solar cell element to the A layer is ensured.

Here, examples of an antistatic material other than the nonionic surfactant (S) include organic conductive materials, inorganic conductive materials, and organic/inorganic complex conductive materials.

Examples of the organic conductive materials include cationic conductive compounds having a cationic substituent such as an ammonium group, an amine base, or a quaternary ammonium group in the molecule; anionic conductive compounds having anionic properties such as a sulfonate group, a phosphate group, or a carboxylate group; ionic conductive materials such as amphoteric conductive compounds having both an anionic substituent and a cationic substituent; and conductive macromolecular compounds having a conjugated polyene-based skeleton such as polyacetylene, polyparaphenylene, polyaniline, polythiophene, polyparaphenylene vinylene, and polypyrrole.

Examples of the inorganic conductive materials include substances obtained by oxidizing, sub-oxidizing, or hyper-oxidizing a substance mainly containing an inorganic substance such as gold, silver, copper, platinum silicon, boron, palladium, rhenium, vanadium, osmium, cobalt, iron, zinc, ruthenium, praseodymium, chromium, nickel, aluminum, tin, zinc, titanium, tantalum, zirconium, antimony, indium, yttrium, lanthanum, magnesium, calcium, cerium, hafnium, or barium; mixtures of the above-described inorganic substance and a substance obtained by oxidizing, sub-oxidizing, or hyper-oxidizing the above-described inorganic substance (hereinafter, referred to as inorganic oxides); substances obtained by nitriding, sub-nitriding, or hyper-nitriding a substance mainly containing the above-described inorganic substance; mixtures of the above-described inorganic substance and a substance obtained by nitriding, sub-nitriding, or hyper-nitriding the above-described inorganic substance (hereinafter, referred to as inorganic nitrides); substances obtained by oxynitriding, sub-oxynitriding, or hyper-oxynitriding a substance mainly containing the above-described inorganic substance; mixtures of the above-described inorganic substance and a substance obtained by oxynitriding, sub-oxynitriding, or hyper-oxynitriding the above-described inorganic substance (hereinafter, referred to as inorganic oxynitrides); substances obtained by carbonizing, sub-carbonizing, or hyper-carbonizing a substance mainly containing the above-described inorganic substance; mixtures of the above-described inorganic substance and a substance obtained by carbonizing, sub-carbonizing, or hyper-carbonizing the above-described inorganic substance (hereinafter, referred to as inorganic carbides); substances obtained by halogenating, sub-halogenating, or hyper-halogenating at least one of a fluoride, a chloride, a bromide, and an iodide of a substance mainly containing the above-described inorganic substance; mixtures of the above-described inorganic substance and a substance obtained by halogenating, sub-halogenating, or hyper-halogenating the above-described inorganic substance (hereinafter, referred to as inorganic halides); substances obtained by sulfurizing, sub-sulfurizing, or hyper-sulfurizing a substance mainly containing the above-described inorganic substance; mixtures of the above-described inorganic substance and a substance obtained by sulfurizing, sub-sulfurizing, or hyper-sulfurizing the above-described inorganic substance (hereinafter, referred to as inorganic sulfides); substances obtained by doping a different element into the inorganic substance; carbon-based compounds such as graphite-form carbon, diamond-like carbon, carbon fibers, carbon nanotubes, and fullerene (hereinafter, referred to as carbon-based compounds); and mixtures thereof.

—Other Additives—

Examples of other additives include, depending on functions imparted to the A layer, a colorant, an ultraviolet absorber, an antioxidant, and fine particles (for example, inorganic particle of silica, calcium carbonate, magnesium oxide, magnesium carbonate, and tin oxide).

—Thickness of A Layer—

In a case in which the A layer is the outermost layer, the thickness of the A layer is preferably in a range of 0.05 μm to 5.0 μm, more preferably in a range of 0.05 μm to 1.0 μm, and still more preferably in a range of 0.05 μm to 0.5 μm. In a case where the thickness of the A layer is set to 5.0 μm or smaller, when the backsheet is adhered to the encapsulating material that encapsulates the solar cell element, the degree of elongation of the A layer increases, and a phenomenon of the surface of the supporter moving toward the encapsulating material side is suppressed due to the concentration of stress on the surface of the supporter.

The A layer is preferably thin from the viewpoint of localizing the nonionic surfactant (S) on the surface of the layer. Therefore, from the viewpoint of ease of realizing both the improvement of the partial discharge voltage and the adhesiveness to the encapsulating material that encapsulates the solar cell element, the thickness of the A layer is most preferably 0.3 μm or smaller.

—Method for Forming A Layer—

As the method for forming the A layer, there is a method in which coating is used. The method in which coating is used is preferred since it is possible to easily form a highly uniform thin film. As the coating method, for example, a well-known method such as gravure coating or bar coating can be used. A solvent for a coating fluid used in the coating may be water or an organic solvent such as toluene or methyl ethyl ketone. The solvent may be used singly or a mixture of two or more solvents may be used.

In a case in which the A layer is formed through coating, it is preferable to carry out the drying and thermal treatment of a coated film at the same time in a drying zone to which the coated film is moved after the thermal treatment. This shall apply to a case in which a coloring layer described below or other functional layers are formed through coating. In addition, it is also preferable to carry out a surface treatment such as a corona discharge treatment, a glow treatment, an atmospheric-pressure plasma treatment, a flame treatment, or an UV treatment on the surface of a material to be coated before the coating of the A layer.

It is preferable to provide a step for drying the coated film after a coating fluid for forming the A layer is applied. The drying step is a step of supplying drying air to the coated film. The average rate of the drying air is preferably in a range of 5 m/second to 30 m/second, more preferably in a range of 7 m/second to 25 m/second, and still more preferably in a range of 9 m/second to 20 m/second.

(Weather-Resistant Layer)

The weather-resistant layer is provided in the backsheet as necessary and is a layer for imparting weather resistance to the backsheet. Therefore, the weather-resistant layer is preferably provided on the surface on a side opposite to a surface provided with the A layer of the supporter.

The weather-resistant layer includes either or both a fluorine-based resin and a silicone-based complex polymer (hereinafter, referred to as “complex polymer”). However, the composition of the weather-resistant layer is not limited thereto. When the complex polymer is included, it becomes possible to make the adhesiveness of the weather-resistant layer to an adjacent layer (including the supporter) particularly favorable and to prevent the adhesiveness from being significantly degraded even after a long period of time elapses.

—Fluorine-Based Resin—

Examples of a fluorine-based resin include chlorotrifluoroethylene, tetrafluoroethylene, hexafluoropropylene, vinylidene fluoride, trifluoroethylene, chlorotrifluoroethylene-ethylene copolymers, and tetrafluoroethylene-perfluoroalkyl vinyl ether copolymers. Among these, from the viewpoint of solubility and weather resistance, chlorotrifluoroethylene-vinyl ether copolymers copolymerized with a vinyl-based compound are preferred.

Examples of the fluorine-based resin include OBBLIGATO SW0011F [manufactured by AGC Coat-Tech Co., Ltd.], LUMIFLON LF200 (manufactured by Asahi Glass Co., Ltd.), ZEFFLE GK570 (manufactured by Daikin Industries, Ltd.), and the like.

From the viewpoint of weather resistance and film strength, the content of the fluorine-based resin is preferably in a range of 40% by mass to 90% by mass and more preferably in a range of 50% by mass to 80% by mass of the mass of the total solid content in the weather-resistant layer.

—Complex Polymer—

The complex polymer refers to a polymer having a (Si(R¹)(R²)—O)ₙ— portion (hereinafter, referred to as “polysiloxane portion”) and a polymer structure part that is copolymerized with the above-described portion in the molecule. The polymer structure part that is copolymerized with the polysiloxane portion is not particularly limited, and examples thereof include an acryl-based polymer, a polyurethane-based polymer, a polyester-based polymer, and a rubber-based polymer. Among these, an acryl-based polymer is particularly preferred from the viewpoint of durability. That is, the complex polymer is particularly preferably a composite resin of acryl and silicone.

In the polysiloxane portion (the portion of “(Si(R¹)(R²)—O)ₙ—”) of the complex polymer, R¹ and R² may be identical to or different from each other and represent monovalent organic groups capable of forming a covalent bond with a Si atom.

In the polysiloxane portion of the complex polymer, examples of the “monovalent organic group capable of forming a covalent bond with a Si atom” represented by R¹ and R² include a substituted or unsubstituted alkyl group (for example, a methyl group or an ethyl group), a substituted or unsubstituted aryl group (for example, a phenyl group), a substituted or unsubstituted aralkyl group (for example, a benzyl group or phenylethyl), a substituted or unsubstituted alkoxy group (for example, a methoxy group, an ethoxy group, or a propoxy group), a substituted or unsubstituted aryloxy group (for example, a phenoxy group), a substituted or unsubstituted amino group (for example, an amino group or a diethylamino group), a mercapto group, an amide group, a hydrogen atom, and a halogen atom (for example, a chlorine atom).

Among these, each of R¹ and R² preferably independently represents a substituted or unsubstituted alkyl group having 1 to 4 carbon atoms (particularly, a methyl group or an ethyl group), a substituted or unsubstituted phenyl group, a mercapto group, an unsubstituted amino group, or an amide group.

Specific examples of the polysiloxane portion of the complex polymer include a hydrolytic condensate of dimethyldimethoxysilane, a hydrolytic condensate of dimethyldimethoxysilane/γ-methacryloxytrimethoxysilane, a hydrolytic condensate of dimethyldimethoxysilane/vinyltrimethoxysilane, a hydrolytic condensate of dimethyldimethoxysilane/2-hydroxyethyltrimethoxysilane, a hydrolytic condensate of dimethyldimethoxysilane/3-glycidoxypropyltriethoxysilane, and a hydrolytic condensate of dimethyldimethoxysilane/diphenyl/dimethoxysilane/γ-methacryloxytrimethoxysilane.

The polysiloxane portion of the complex polymer may have a linear structure or a branched structure. Furthermore, a part of a molecular chain may form a ring. The ratio of the polysiloxane portion of the complex polymer to the total mass of the complex polymer is preferably in a range of 15% by mass to 85% by mass and particularly preferably in a range of 20% by mass to 80% by mass.

When the ratio of the polysiloxane portion is set to 15% by mass or higher, a decrease in adhesiveness caused when the weather-resistant layer is exposed to a humid and hot environment is suppressed, and, when the ratio of the polysiloxane portion is set to 85% by mass or lower, a coating fluid for forming the weather-resistant layer becoming unstable is suppressed.

The molecular weight of the polysiloxane portion of the complex polymer is in a range of approximately 30000 to 1000000 in terms of the polystyrene-equivalent weight-average molecular weight, but is more preferably in a range of approximately 50000 to 300000.

The method for synthesizing the polysiloxane portion of the complex polymer is not particularly limited, and a well-known synthesis method can be used. Specifically, there is a method in which an acid is added to an aqueous solution of an alkoxysilane compound such as dimethylmethoxysilane or dimethylethoxysilane, is hydrolyzed, and then is condensed.

Meanwhile, as a monomer for forming the acryl-based polymer which is the polymer structure portion of the complex polymer, it is possible to use a polymer obtained from an ester of acrylic acid (for example, ethyl acrylate, butyl acrylate, hydroxyethyl acrylate, or 2-ethylhexyl acrylate) or an ester of methacrylic acid (for example, methyl methacrylate, butyl methacrylate, hydroxyethyl methacrylate, glycidyl methacrylate, or dimethylamino ethyl methacrylate). Furthermore, examples of the monomer include a carboxylic acid such as acrylic acid, methacrylic acid, or itaconic acid, styrene, acrylonitrile, vinyl acetate, acrylamide, and divinylbenzene. The acryl-based polymer is a polymer obtained by polymerizing one or more of the above-described monomers and may be either a homopolymer or a copolymer. The method for synthesizing the acryl-based polymer is not particularly limited, and a well-known synthesis method can be used.

Specific examples of the acryl-based polymer include a methyl methacrylate/ethyl acrylate/acrylic acid copolymer, a methyl methacrylate/ethyl acrylate/2-hydroxyethyl methacrylate/methacrylic acid copolymer, a methyl methacrylate/butyl acrylate/2-hydroxyethyl methacrylate/methacrylic acid/γ-methacryloxytrimethoxysilane copolymer, and a methyl methacrylate/ethyl acrylate/glycidyl methacrylate/acrylic acid copolymer.

As the polyurethane-based polymer which is the polymer structure portion of the complex polymer, it is possible to use a polyurethane-based polymer obtained using a polyisocyanate such as toluene diisocyanate, hexamethylene diisocyanate, or isophorone diisocyanate and a polyol such as diethylene glycol, triethylene glycol, or neopentyl glycol as monomers. The method for synthesizing the polyurethane-based polymer is not particularly limited, and a well-known synthesis method can be used.

Specific examples of the polyurethane-based polymer include urethane obtained from toluene diisocyanate and diethylene glycol, urethane obtained from toluene diisocyanate and diethylene glycol/neopentyl glycol, and urethane obtained from hexamethylene diisocyanate and diethylene glycol.

As the polyester-based polymer which is the polymer structure portion of the complex polymer, it is possible to use a polyester-based polymer obtained using a polycarboxylic acid such as terephthalic acid, isophthalic acid, adipic acid, or sulfoisophthalic acid and the polyol described in the section of the polyurethane. The method for synthesizing the polyester-based polymer is not particularly limited, and a well-known synthesis method can be used.

Specific examples of the polyester-based polymer include polyester obtained from terephthalic acid/isophthalic acid and diethylene glycol, polyester obtained from terephthalic acid/isophthalic acid/sulfoisophthalic acid and diethylene glycol, and polyester obtained from adipic acid/isophthalic acid/sulfoisophthalic acid and diethylene glycol.

As the rubber-based polymer which is the polymer structure portion of the complex polymer, it is possible to use a copolymer of a polymer obtained from a diene-based monomer such as butadiene, isoprene, or chloroprene and a monomer such as a diene-based monomer thereof or styrene capable of being copolymerized with the diene-based monomer. The method for synthesizing the rubber-based polymer is also not particularly limited, and a well-known synthesis method can be used.

Specific examples of the rubber-based polymer include a rubber-based polymer made up of butadiene/styrene/methacrylic acid, a rubber-based polymer made up of butadiene/methyl methacrylate/methacrylic acid, a rubber-based polymer made up of isoprene/methyl methacrylate/methacrylic acid, or a rubber-based polymer made up of chloroprene/acrylonitrile/methacrylic acid.

The polymer which is the polymer structure portion of the complex polymer may be used singly or two or more polymers may be jointly used. Furthermore, each polymer may be either a homopolymer or a copolymer.

The molecular weight of the polymer structure portion of the complex polymer is in a range of approximately 3000 to 1000000 in terms of the polystyrene-equivalent weight-average molecular weight, but is more preferably in a range of approximately 5000 to 300000.

The method for chemically bonding the polysiloxane portion and the polymer structure portion which is copolymerized with the polysiloxane portion in the complex polymer is not particularly limited, and examples thereof include a method in which the polysiloxane portion and the polymer structure portion which is copolymerized with the polysiloxane portion are individually polymerized and individual polymers are chemically bonded together, a method in which the polysiloxane portion is polymerized in advance and then is graft-polymerized, and a method in which a copolymerized polymer portion is polymerized in advance and then the polysiloxane portion is graft-polymerized into the copolymerized polymer portion. The two latter methods are preferred since synthesis is easy. For example, as a method for copolymerizing an acryl polymer into the polysiloxane portion, there is a method in which a polysiloxane portion into which γ-methacryloxytrimethylsilane or the like has been copolymerized is produced and the polysiloxane portion and an acryl monomer are radical-polymerized together. In addition, as a method for copolymerizing polysiloxane into an acryl polymer portion, there is a method in which an alkoxysilane compound is added to an aqueous dispersion of an acryl polymer including γ-methacryloxytrimethylsilane and hydrolysis and condensation polymerization are caused.

In the complex polymer, in a case in which the polymer structure portion that is copolymerized with the polysiloxane portion is an acryl-based polymer, it is possible to use a well-known polymerization method such as emulsion polymerization or bulk polymerization, but emulsion polymerization is particularly preferred since synthesis is easy and a water-based polymer-dispersed substance can be obtained.

In addition, a polymerization initiator used for the graft polymerization is not particularly limited, and a well-known polymerization initiator such as potassium persulfate, ammonium persulfate, or azobisisobutyronitrile can be used.

The complex polymer is preferably used in the form of a water-based polymer-dispersed substance (so-called latex). In the latex of the complex polymer, the preferred particle diameter is in a range of approximately 50 nm to 500 nm and the preferred concentration is in a range of approximately 15% by mass to 50% by mass.

In a case in which a water-based polymer is made into a latex form, the complex polymer preferably has a hydrophilic functional group such as a carboxyl group, a sulfonic acid group, a hydroxyl group, or an amide group. In a case in which the silicone-based complex polymer has a carboxyl group, the carboxyl group may be neutralized using sodium, ammonium, amine, or the like.

In addition, in a case in which the water-based polymer is used in a latex form, the latex may include an emulsion stabilizer such as a surfactant (for example, an anionic or nonionic surfactant) or a polymer (for example, polyvinyl alcohol) in order to improve the stability. Furthermore, well-known compounds may be added as necessary as additives for the latex such as a pH adjuster (for example, ammonia, triethylamine, or sodium hydrogen carbonate), a preservative (for example, 1,3,5-hexahydro-(2-hydroxyethyl)-s-triazine, 2-(4-thiazolyl)benzimidazole), a viscosity improver (for example, sodium polyacrylate, methyl cellulose), and a film-forming aid (for example, butyl carbitol acetate).

There are commercially available complex polymers. Among the complex polymers, specific examples of the commercially available product of a silicone acryl composite resin include CERANATE WSA1060 and CERANATE WSA1070 (all manufactured by DIC Corporation) and POLYDUREX H7620, H7630, and H7650 (all manufactured by Asahi Kasei Chemicals Corporation).

From the viewpoint of weather resistance and film strength, the content of the complex polymer is preferably in a range of 40% by mass to 90% by mass and more preferably in a range of 50% by mass to 80% by mass of the mass of the total solid content in the weather-resistant layer.

The weather-resistant layer may include a variety of additives such as an ultraviolet absorber, an antioxidant, fine particles (for example, inorganic particle of silica, calcium carbonate, magnesium oxide, magnesium carbonate, and tin oxide), and a surfactant.

The thickness of the weather-resistant layer is preferably in a range of 0.5 μm to 15 m and more preferably in a range of 3 μm to 10 μm. When the thickness of the weather-resistant layer is set to 0.5 μm or larger, weather resistance can be sufficiently developed, and, when the thickness of the weather-resistant layer is set to 15 μm or smaller, it is possible to suppress the deterioration of surface properties.

Meanwhile, the weather-resistant layer may be a single layer or a laminate of two or more layers.

The method for forming the weather-resistant layer is not particularly limited, but the weather-resistant layer is preferably formed through coating. As a coating method, it is possible to use, for example, gravure coating or bar coating.

As a solvent for the coating fluid for forming the weather-resistant layer, water is preferably used, and the content of water in the solvent included in the coating fluid is preferably 60% by mass or higher. A water-based coating fluid is preferred since there is only a small burden on the environment, and the fraction of water is advantageously 60% by mass or higher in terms of proofness and safety. The fraction of water in the coating fluid for forming the weather-resistant layer is desirably higher from the viewpoint of the environmental burden, and the fraction of water is more preferably 70% by mass or higher of the total solvent.

Here, the respective layers may include an ultraviolet absorber and, as the ultraviolet absorber, for example, an organic ultraviolet absorber and an inorganic ultraviolet absorber may be singly or jointly used. Examples of the organic ultraviolet absorber include a salicylic acid-based ultraviolet absorber, a benzophenone-based ultraviolet absorber, a benzotriazole-based ultraviolet absorber, a triazine-based ultraviolet absorber, a cyanoacrylate-based ultraviolet absorber, and a hindered amine-based ultraviolet stabilizer. The triazine-based ultraviolet absorber is more preferred due to its high resistance to the repetitive absorption of ultraviolet rays. The ultraviolet absorber is preferably used after being dissolved and dispersed with the binder.

(Gas-Barrier Layer)

The gas-barrier layer is a layer for imparting a moisture-proof function with which the intrusion of water or gas into the polyester is prevented. Therefore, the gas-barrier layer is preferably provided on the surface on a side opposite to a surface provided with the A layer of the supporter from the viewpoint of preventing the entry of water and moisture.

The amount of water vapor penetrating through the gas-barrier layer (the degree of water vapor transmission) is preferably in a range of 10² g/m²·d to 10⁻⁶ g/m²·d, more preferably in a range of 10¹ g/m²·d to 10⁻⁵ g/m²·d, and still more preferably in a range of 10⁰ g/m²·d to 10⁻⁴ g/m²·d.

In order to form the gas-barrier layer having the above-described degree of water vapor transmission, a dry method is preferred. Examples of a method for forming the gas-barrier layer that blocks gas using the dry method include a vacuum deposition method such as resistance heating evaporation, electron beam evaporation, induced heating evaporation, or an assist method in which plasma or ion beams are used for the above-described methods, a sputtering method such as a reactive sputtering method, an ion beam sputtering method, or an electron cyclotron resonance (ECR) sputtering method, a physical vapor deposition method (PVD method) such as an ion plating method, and a chemical vapor deposition method (CVD method) in which heat, light, plasma, or the like is used. Among these, the vacuum deposition method in which the gas-barrier layer is formed using a deposition method in a vacuum is preferred.

Here, in a case in which a material for forming the gas-barrier layer includes an inorganic oxide, an inorganic nitride, an inorganic halide, an inorganic halogenated substance, an inorganic sulfide, or the like as a main constituent component, the gas-barrier layer can be formed using 1) a method in which a material having the same composition as a barrier layer to be formed is used as a source of volatilization and the material is volatilized while supplementarily introducing into the system oxygen gas in the case of an inorganic oxide, nitrogen gas in the case of an inorganic nitride, a gas mixture of oxygen gas and nitrogen gas in the case of an inorganic halide, halogen-based gas in the case of an inorganic halogenated substance, and sulfur-based gas in the case of an inorganic sulfide respectively, 2) a method in which a group of inorganic substances is used as a source of volatilization, while volatilizing the inorganic substance group, oxygen gas, nitrogen gas, a gas mixture of oxygen gas and nitrogen gas, halogen-based gas, and sulfur-based gas are respectively introduced into the system in the same manner as described above, and the inorganic substance is accumulated on the surface of a base material while being reacted with the introduced gas, or 3) a method in which a group of inorganic substances used as a source of volatilization is volatilized, a layer of the group of inorganic substances is formed, then, the layer of the inorganic substance is held in an oxygen gas atmosphere in the case of an inorganic oxide, in a nitrogen gas atmosphere in the case of an inorganic nitride, in an atmosphere of a gas mixture of oxygen gas and nitrogen gas in the case of an inorganic oxynitride, in a halogen-based gas atmosphere in the case of an inorganic halide, and in a sulfur-based gas atmosphere in the case of an inorganic sulfide so as to be reacted with the introduced gas.

Among these, the method 2) or 3) is preferred in terms of ease of volatilization from the source of volatilization. Furthermore, the method 2) is preferred in terms of ease of the control of film qualities. In addition, in a case in which the barrier layer is an inorganic oxide, a method in which a group of inorganic substances is used as a source of volatilization, the group of inorganic substances is volatilized so as to form a layer of the group of inorganic substances, and the layer is left to stand in the air, whereby the group of inorganic substances is naturally oxidized is preferred from the viewpoint of ease of the formation of the gas-barrier layer.

Meanwhile, the gas-barrier layer may be produced by attaching an aluminum foil.

The thickness of the gas-barrier layer is preferably in a range of 1 μm to 30 μm. When the thickness thereof is 1 μm or larger, the gas-barrier layer does not easily allow water to intrude into the supporter over time (thermo) and the hydrolysis resistance is excellent, and when the thickness thereof is 30 μm or smaller, an inorganic layer does not become excessively thick, and there is no case in which accretion is generated in the supporter due to stresses in the inorganic layer.

(Undercoat Layer)

The undercoat layer is a layer that is provided as necessary between the supporter and the A layer. In a case in which a functional layer is provided on the surface on a side opposite to a surface provided with the A layer of the supporter, the undercoat layer may be provided between the supporter and the functional layer.

The undercoat layer preferably includes at least one polymer selected from a polyolefin resin, an acrylic resin, a polyester resin, and a polyurethane resin. The polymer is preferably a polyolefin resin, an acrylic resin, or a polyester resin and most preferably a polyolefin resin or an acrylic resin.

The polyolefin resin is preferably, for example, a modified polyolefin copolymer. A commercially available polyolefin resin on sale may be used, and examples thereof include ARROW-BASE SE-1013N, SD-1010, TC-4010, and TD-4010 (all manufactured by Unitika Limited), HITECH S3148, HITECH S3121, and HITECH S8512 (all manufactured by Toho Chemical Industry Co., Ltd.), CHEMIPAL S-120, CHEMIPAL S-75N, CHEMIPAL V100, and CHEMIPAL EV210H (manufactured by Mitsui Chemicals, Inc.), and the like. Among these, ARROW-BASE SE-1013N manufactured by Unitika Limited, which is a ternary copolymer of low-density polyethylene, acrylic acid ester, and maleic acid anhydride, is preferably used.

The acrylic resin is preferably a polymer or the like including, for example, polymethyl methacrylate or polyethyl acrylate. A commercially available acrylic resin on sale may be used, and, for example, AS-563A (manufactured by Daicel FineChem Ltd.) can be preferably used.

The polyester resin is preferably, for example, polyethylene terephthalate (PET), polyethylene-2,6-naphthalate (PEN), or the like. A commercially available polyester resin on sale may be used, and, for example, VYLONAL MD-1245 (manufactured by Toyobo Co., Ltd.) can be preferably used.

The polyurethane resin is preferably, for example, a carbonate-based urethane resin, and, for example, SUPERFLEX 460 (manufactured by DKS Co., Ltd.) can be preferably used.

Among these, from the viewpoint of ensuring adhesiveness between the supporter and a layer adjacent to the supporter, the polyolefin resin is preferably used. In addition, these polymers may be used singly or two or more polymers may be jointly used. In a case in which two or more polymers are jointly used, a combination of the acrylic resin and the polyolefin resin is preferred.

The binder (resin) may be crosslinked using a crosslinking agent. The binder (resin) is more preferably crosslinked since the durability of the undercoat layer can be improved. Examples of the crosslinking agent include epoxy-based, isocyanate-based, melamine-based, carbodiimide-based, and oxazoline-based crosslinking agents. Among these, the crosslinking agent is preferably a crosslinking agent having an oxazoline group (oxazoline-based crosslinking agent). As the oxazoline-based crosslinking agent, it is possible to use EPOCROS K2010E, EPOCROS K2020E, EPOCROS K2030E, EPOCROS WS-500, EPOCROS WS-700 (manufactured by Nippon Shokubai Co., Ltd.), or the like.

The amount of the crosslinking agent added is preferably in a range of 0.5% by mass to 30% by mass, more preferably in a range of 5% by mass to 20% by mass, and particularly preferably in a range of 3% by mass to lower than 15% by mass of the binder. Particularly, when the amount of the crosslinking agent added is 0.5% by mass or higher, a sufficient crosslinking effect is obtained while maintaining the intensity and adhesiveness of the undercoat layer; when the amount thereof is 30% by mass or lower, the pot life of the coating fluid is maintained for a long period of time; when the amount thereof is lower than 15% by mass, the coating surface properties can be improved.

The undercoat layer preferably includes an anionic or nonionic surfactant. As the surfactant, it is possible to use, for example, a well-known surfactant such as an anionic, cationic, or nonionic surfactant, and specific examples thereof include DEMOL EP [manufactured by Kao Corporation] and NAROACTY CL95 [manufactured by Sanyo Chemical industries, Ltd.]. Among these, an anionic surfactant is preferred. The surfactant may be used singly or a plurality of surfactants may be used.

The amount of the surfactant applied is preferably in a range of 0.1 mg/m² to 10 mg/m² and more preferably in a range of 0.5 mg/m² to 3 mg/m². When the amount of the surfactant applied is 0.1 mg/m² or more, the generation of cissing is suppressed and thus the layer can be favorably formed, and when the amount thereof is 10 mg/m² or less, it is possible to favorably adhere the supporter to a layer adjacent to the supporter.

The thickness of the undercoat layer is preferably 2 μm or smaller, more preferably in a range of 0.005 μm to 2 μm, and still more preferably in a range of 0.01 μm to 1.5 μm. When the thickness of the undercoat layer is 0.005 μm or larger, coating unevenness is not easily caused, and, when the thickness of the undercoat layer is 2 μm or smaller, the layer becoming sticky is suppressed, and the workability improves.

As the method for forming the undercoat layer, a well-known coating method for applying a coating fluid for forming the undercoat layer is appropriately selected. For example, it is possible to use any coating method in which a reverse roll coater, a gravure coater, a rod coater, an air doctor coater, a spray, or a brush is used. In addition, the undercoat layer may be formed by immersing the supporter in the coating fluid for forming the undercoat layer. In addition, in terms of cost, the coating fluid for forming the undercoat layer is preferably applied using a so-called inline coating method in which the supporter is coated with the coating fluid for forming the undercoat layer in a step for manufacturing the supporter. Specifically, it is possible to use a method in which, in the production of the supporter, the raw material resin of the supporter is, for example, extruded and is cast onto a cooling drum while jointly using an electrostatic adhesion method or the like, thereby obtaining a sheet, then, the sheet is stretched in the vertical direction, subsequently, the coating fluid for forming the undercoat layer is applied to a single surface of the vertically-stretched supporter, and then the supporter is stretched in the horizontal direction. The conditions for the drying and the thermal treatment during the coating vary depending on the thickness of a coating and the conditions of an apparatus, but it is preferable to send the supporter to a perpendicular-direction stretching step immediately after the coating and dry the supporter in a preheating zone or a stretching zone for the stretching step. In such a case, the supporter is stretched at a temperature, generally, in a range of approximately 50° C. to 250° C. Meanwhile, a corona discharge treatment and other surface activation treatments may be carried out on the supporter.

Meanwhile, the concentration of the solid content in the coating fluid for forming the undercoat layer is preferably 30% by mass or lower and particularly preferably 10% by mass or lower. The lower limit of the concentration of the solid content is preferably 1% by mass, still more preferably 3% by mass, and particularly preferably 5% by mass. When the concentration of the solid content in the coating fluid for forming the undercoat layer is in the above-described range, an undercoat layer having favorable surface properties can be formed.

[Solar Cell Module]

In the solar cell module of the present invention, a solar cell element for converting the optical energy of sunlight to electrical energy is disposed between a transparent substrate on which sunlight is incident and a back sheet for solar cells, and a space between the substrate and the backsheet is encapsulated with an encapsulating material such as an ethylene-vinyl vinyl copolymer or the like.

Specifically, the solar cell module of the present invention includes a transparent base material on which sunlight is incident, an element structure portion which is provided on the base material and has a solar cell element and an encapsulating material that encapsulates the solar cell element, and a back sheet for solar cells disposed on a side opposite to a side on which the base material of the element structure portion is located. In addition, as the back sheet for solar cells, the backsheet of the present invention is applied.

Regarding members other than the solar cell module, the solar cell, and the backsheet, for example, “The Constituent Materials of Photovoltaic Power Generation Systems” (edited by Eiichi Sugimoto and published by Kogyo Chosakai Publishing Co., Ltd. in 2008) describes them in detail.

The transparent front substrate needs to have light permeability so as to be capable of transmitting sunlight and can be appropriately selected from base materials transmitting light. From the viewpoint of power generation efficiency, the light permeability is preferably higher, and, as the above-described substrate, for example, a glass substrate, a transparent resin such as an acrylic resin, or the like can be preferably used.

As the solar cell element, it is possible to apply a variety of well-known solar cell elements such as a solar cell element based on silicon such as monocrystalline silicon, polycrystalline silicon, or amorphous silicon or a solar cell element based on a III-V group or II-VI group compound such as copper-indium-gallium-selenium, copper-indium-selenium, cadmium-tellurium, or gallium-arsenic.

### Examples

Hereinafter, the present invention will be more specifically described using examples, but the present invention is not limited to the following examples within the scope of the gist of the present invention. Meanwhile, unless particularly otherwise described, “parts”, “%”, and “ratios” are on the basis of mass.

(Production of Supporter)

Synthesis of Polyester

High-purity terephthalic acid (100 kg, manufactured by Mitsui Chemicals, Inc.) and a slurry of ethylene glycol (45 kg, manufactured by Nippon Junyaku K.K.) were sequentially supplied over four hours to an esterification reaction vessel to which bis(hydroxyethyl)terephthalate (approximately 123 kg) had been previously added and was held at a temperature of 250° C. and a pressure of 1.2×10⁵ Pa and, after the completion of the supply, an esterification reaction was further caused for one hour. After that, the obtained esterification reaction product (123 kg) was moved to a condensation polymerization reaction vessel.

Subsequently, 0.3% of ethylene glycol in relation to the obtained polymer was added to the condensation polymerization reaction vessel to which the esterification reaction product had been moved. After five minutes of stirring, cobalt acetate and an ethylene glycol solution of manganese acetate were added so that the contents thereof respectively reached 30 ppm and 15 ppm in relation to the obtained polymer. Furthermore, after five minutes of stirring, a 2% ethylene glycol solution of a titanium alkoxide compound was added so that the content thereof reached 5 ppm in relation to the obtained polymer. After five minutes, a 10% ethylene glycol solution of triethyl phosphonoacetate was added so that the content thereof reached 5 ppm in relation to the obtained polymer. After that, while stirring a lower polymer at 30 rpm, the reaction system was gradually heated from 250° C. to 285° C., and the pressure was lowered to 40 Pa. The time periods necessary to reach the final temperature and the final pressure were both set to 60 minutes. When a predetermined stirring torque was reached, the reaction system was purged with nitrogen, the pressure was returned to normal pressure, and the condensation polymerization reaction was stopped. In addition, the reaction product was discharged into cold water in a strand shape and was, immediately, cut into polymer pellets (with a diameter of approximately 3 mm and a length of approximately 7 mm). Meanwhile, the time period taken from the initiation of depressurization to the predetermined stirring torque being reached was three hours.

Meanwhile, as the titanium alkoxide compound, the titanium alkoxide compound (with a content of Ti of 4.44%) synthesized in Example 1 of Paragraph [0083] of JP2005-340616A was used.

—Solid-State Polymerization—

The pellets obtained above were held at a temperature of 220° C. for 30 hours in a vacuum container held at 40 Pa, thereby causing solid-state polymerization.

—Formation of Base—

The pellet which had been subjected to solid-state polymerization as described above was melted at 280° C. and was cast on a metallic drum, thereby producing an unstretched base having a thickness of approximately 3 mm. After that, the base was stretched 3.4 times in the vertical direction at 90° C., a corona discharge treatment was carried out under the following conditions, and then a coating fluid for forming an A layer having the following composition was applied using an inline coating method onto the corona-treated surface of a polyethylene terephthalate supporter so that the amount of the coating fluid applied reached 5.1 ml/m² after stretching in MD but before stretching in TD, thereby forming a 0.1 m-thick A layer. Meanwhile, the pellet was stretched 4.5 times in the TD direction at a TD stretching temperature of 105° C., a thermal treatment was carried out on a film surface at 200° C. for 15 seconds, and thermal relaxation was carried out at 190° C. in the MD and TD directions at a MD relaxation ratio of 5% and a TD relaxation ratio of 11%, thereby obtaining a 250 μm-thick biaxial stretched polyethylene terephthalate supporter on which the A layer was formed (hereinafter, referred to as “A layer-attached PET supporter”).

(Corona Discharge Treatment)

The conditions for the corona discharge treatment carried out on one surface of the PET supporter were as described below.
Gap clearance between the electrode and a dielectric roll: 1.6 mm
Treatment frequency: 9.6 kHz
Treatment rate: 20 m/minute
Treatment intensity: 0.375 kV·A·minute/m²

(Composition of Coating Fluid for Forming A Layer)

| | |
|---|---|
| Water dispersion of polyolefin resin | 3.74 parts |
| [ARROW-BASE SE-1013N, manufactured by | |
| Unitika Limited, solid content: 20.2%] | |
| Water dispersion of acrylic resin | 0.3 parts |
| [AS-563A, manufactured by Daicel FineChem | |
| Ltd., solid content: 28% of latex] | |
| Water-soluble oxazoline-based crosslinking agent | 0.85 parts |
| [EPOCROS WS-700, manufactured by Nippon | |
| Shokubai Co., Ltd., solid content: 25%] | |
| Additives | shown in |
| | Tables 1 and 2 |
| Distilled water | 100 parts |

Back sheets for solar cells of Comparative Examples 1 to 14 and back sheets for solar cells of Examples 1 to 36 were produced in the above-described manner.

[Production of Cell Backsheet of Example 37]

An A layer was formed in the same manner as in the production of the back sheet for solar cells 30. A corona discharge treatment was carried out on the surface of this A layer having a film thickness of 0.5 μm under a condition of 730 J/m², then, the coating fluid for forming the A layer used in the production of the back sheet for solar cells of Comparative Example 1 was applied so that the thickness reached 0.1 μm, and then the same steps were carried out in the same manner as in the production of the back sheet for solar cells of Comparative Example 1, thereby producing a back sheet for solar cells of Example 37.

[Production of Cell Backsheet of Example 38]

A PET supporter was transported at a transportation rate of 80 m/minute, a corona discharge treatment was carried out on the PET surfaces under a condition of 730 J/m², then, a coating fluid for forming an intermediate layer 1 having the following composition was applied so that the amount of the coating fluid applied reached 17.25 cc/m² and was dried at 170° C. for two minutes, thereby providing a 1 μm-thick intermediate layer 1. After a corona discharge treatment was carried out on the surface of the intermediate layer 1 under a condition of 730 J/m², an A layer was formed in the same manner as in the method for forming the A layer for the back sheet for solar cells 34, thereby producing a back sheet for solar cells of Example 38.

(Composition of Coating Fluid for Forming Intermediate Layer 1)

| | |
|---|---|
| Water dispersion of acrylic resin | 11.8 parts |
| [BONRON XPS002, manufactured by | |
| Mitsui Chemicals, Inc., solid content: 45.0%] | |
| Water-soluble oxazoline-based crosslinking agent | 1.6 parts |
| [EPOCROS WS-700, manufactured by Nippon | |
| Shokubai Co., Ltd., solid content: 25.0%] | |
| Anionic surfactant | 0.4 parts |
| [sodium-1.2-{bis(3,3,3,4,4,5,5,6,6,6-nanofluorohexyl | |
| carbonyl)}ethanesulfonate] | |
| [solid content: 2.0% (dissolved at a ratio between | |
| water and ethanol of 2:1)] | |
| Distilled water | 86.3 parts |

[Production of Back Sheet for Solar Cells of Example 39]

A back sheet for solar cells of Example 39 was produced in the same manner as in the production of the back sheet for solar cells of Example 38 except for the fact that a white intermediate layer 2 was formed using a coating fluid for forming the intermediate layer 2 having the following composition instead of the intermediate layer 1.

(Composition of Coating Fluid for Forming Intermediate Layer 2)

| | |
|---|---|
| Water dispersion of acrylic resin | 10.6 parts |
| [BONRON XPS002, manufactured by | |
| Mitsui Chemicals, Inc., solid content: 45.0%] | |
| Water-soluble oxazoline-based crosslinking agent | 1.4 parts |
| [EPOCROS WS-700, manufactured by Nippon | |
| Shokubai Co., Ltd., solid content: 25.0%] | |
| Anionic surfactant | 0.4 parts |
| [sodium-1.2-{bis(3,3,3,4,4,5,5,6,6,6-nanofluorohexyl | |
| carbonyl)}ethanesulfonate] | |
| [solid content: 2.0% (dissolved at a ratio between | |
| water and ethanol of 2:1)] | |
| Dispersion of titanium oxide | 4.4 parts |

[Method for preparing the dispersion of titanium oxide: titanium dioxide was dispersed using a Dyno-Mill disperser so that the average particle diameter of titanium dioxide reached 0.45, thereby preparing a dispersion of titanium dioxide. Meanwhile, the average particle diameter of titanium dioxide was measured using a MICROTRACK FRA manufactured by Honeywell Inc.

(the composition of the dispersion of titanium dioxide: titanium dioxide . . . 455.8 parts (TIPAQUE CR-95, manufactured by Ishihara Sangyo Kaisha, Ltd., powder), aqueous solution of PVA . . . 227.9 parts (DEMOL EP, manufactured by Kao Corporation, concentration of 25%), distilled water . . . 310.8 parts]

| | |
|---|---|
| Distilled water | 83.2 parts |

[Production of Back Sheet for Solar Cells of Example 40]

A back sheet for solar cells of Example 40 was produced in the same manner as in the production of the back sheet for solar cells of Example 38 except for the fact that a black intermediate layer 3 was formed using a coating fluid for forming the intermediate layer 3 having the following composition instead of the intermediate layer 1.

(Composition of Coating Fluid for Forming Intermediate Layer 3)

| | |
|---|---|
| Water dispersion of acrylic resin | 11.7 parts |
| [BONRON XPS002, manufactured by | |
| Mitsui Chemicals, Inc., solid content: 45.0%] | |
| Water-soluble oxazoline-based crosslinking agent | 1.6 parts |
| [EPOCROS WS-700, manufactured by Nippon | |
| Shokubai Co., Ltd., solid content: 25.0%] | |
| Anionic surfactant | 0.4 parts |
| [sodium-1.2-{bis(3,3,3,4,4,5,5,6,6,6-nanofluorohexyl | |
| carbonyl)}ethanesulfonate] | |
| [solid content: 2.0% (dissolved at a ratio between | |
| water and ethanol of 2:1)] | |
| Dispersion of carbon black | 0.4 parts |
| [MF5630 Black, manufactured by Dainichiseika | |
| Color & Chemicals Mfg. Co., Ltd., solid content: 31.5%] | |
| Distilled water | 86.0 parts |

[Evaluations]

For the back sheets for solar cells obtained in the respective examples, the surface resistance values SR of the surfaces on the side provided with the A layer of the backsheet according to the above-described method were measured, and the following evaluations were carried out.

(Partial Discharge Voltage)

After the back sheet for solar cells was left to stand indoors for one night at 23° C. and 65% Rh, the partial discharge voltage was measured ten times using a partial discharging tester KPD2050 (manufactured by Kikusui Electronics Corp.), and the average value thereof was used as the partial discharge voltage of the backsheet. Meanwhile, the testing conditions are as described below.
As the output voltage application pattern in an output sheet, a pattern made up of three steps in which the first step has a pattern of simply increasing the voltage from 0 V to a predetermined testing voltage, the second step have a pattern of maintaining the predetermined testing step, and the third step have a pattern of simply decreasing the voltage from the predetermined testing step to 0 V is selected.
The frequency is set to 50 Hz.
The testing voltage is set to 1 kV; however, in a case in which partial discharging has not observed, the testing voltage is increased by 1 kV until partial discharging is observed, thereby measuring the partial discharge voltage.
The time period T1 for the first step is set to 10 seconds, the time period T2 for the second step is set to 2 seconds, and the time period T3 for the third step is set to 10 seconds.
The counting method in a pulse count sheet is “+” (positive) and the detection level is 50%.

In addition, after the measurement of the partial discharge voltage, the backsheets were evaluated according to the following ranks on the basis of the measured values.

Rank 1: 0.82 kV to 0.87 kV

Rank 2: 0.88 kV to 0.93 kV

Rank 3: 0.94 kV to 0.99 kV

Rank 4: 1.00 kV to 1.05 kV

Rank 5: 1.06 kV to 1.11 kV

(Adhering Force of EVA)

The back sheet for solar cells obtained in each of the examples was cut into a piece that was 8.0 cm long in the MD direction and was 3.0 cm long in the TD direction. Next, an ethylene-vinyl acetate (EVA) copolymer film, which is used as an encapsulating material, was placed on a glass substrate, and the cut piece of the backsheet was superimposed on the film with the A layer-formed surface facing the EVA side, and then the cut piece, the film, and the glass substrate were laminated under conditions of 145° C., four minutes of evacuation, and 10 minutes of pressurization using a vacuum lamination apparatus (LAMINATOR 0505S) manufactured by Nisshinbo Mechatronics Inc. After that, the adjustment of the humidity was carried out for 24 hours or longer under conditions of 23° C. 50%, and then two notches were made in the MD direction of the backsheet using a cutter so as to obtain a portion with a width of 10 mm.

The 10 mm-wide portion of the back sheet for solar cells including the notches was pulled at 180 degrees using a TENSILON (RTF-1310 manufactured by A&D Company, Limited) at a rate of 100 mm/min, and the backsheet was evaluated according to the following ranks on the basis of a force (unit: N/mm) measured when the back sheet for solar cells was peeled off from the EVA surface.

Rank 1: 3 N/mm or lower

Rank 2: 3 N/mm to 5 N/mm

Rank 3: 5 N/mm to 7 N/mm

Rank 4: 7 N/mm to 9 N/mm

Rank 5: 9 N/mm or higher

Hereinafter, the details and the evaluation results of the respective examples will be shown in Tables 1 and 2. Meanwhile, in the tables, the “EO chain length” represents the repetition number n of ethylene oxide in the ethylene glycol chain included in the surfactant.

Hereinafter, abbreviations of product names in the respective tables will be described in detail.
EMALEX102: an exemplary compound with m=16 and n=2 in General Formula (SII) (manufactured by Nihon Emulsion Co., Ltd.)
EMALEX105: an exemplary compound with m=16 and n=5 in General Formula (SII) (manufactured by Nihon Emulsion Co., Ltd.)
EMALEX110: an exemplary compound with m=16 and n=10 in General Formula (SII) (manufactured by Nihon Emulsion Co., Ltd.)
EMALEX120: an exemplary compound with m=16 and n=20 in General Formula (SII) (manufactured by Nihon Emulsion Co., Ltd.)
EMALEX130: an exemplary compound with m=16 and n=30 in General Formula (SII) (manufactured by Nihon Emulsion Co., Ltd.)
Baytron: a conductive polymer “a water-dispersed body of a water-insoluble polythiophene-based conductive macromolecule (manufactured by Bayer Holding Ltd./manufactured by H.C. Starck GmbH)”
PELEX NBL: an anionic surfactant “sodium alkyl naphthalene sulfonate (manufactured by Kao Corporation)”
DENTALL WK-500: an inorganic conductive material “acicular TiO₂ particles (manufactured by Otsuka Chemical Co., Ltd.)”
BONDEIP-PM: a water-dispersed body of a water-insoluble cationic conductive material (manufactured by Konish Co., Ltd.)
OLFINE EXP4150F: a nonionic surfactant having an acetylene group (manufactured by Nissin Chemical Co., Ltd.)

TABLE 1

| | Additives in A layer such as surfactant | | | | Evaluation results | | |
|---|---|---|---|---|---|---|---|
| | | | Amount added | Film | Surface | | |
| Back sheet | | EO | (% by mass of total | thickness | resistance | Partial | Adhering |
| for solar | | chain | amount of solid | of A layer | value | discharge | force of |
| cells | Compound | length | content in A layer) | (μm) | (Ω/□) | voltage | EVA |
| Comparative | — | — | — | (0.1) | 9.8 × 10¹⁵ | 1 | 5 |
| Example 1 | | | | | | | |
| Comparative | Exemplary Compound SI-3 | 13.5 | 0.1 | 0.1 | 7.8 × 10¹⁵ | 1 | 5 |
| Example 2 | | | | | | | |
| Example 1 | Exemplary Compound SI-3 | 13.5 | 2.5 | 0.1 | 4.8 × 10¹⁵ | 2 | 5 |
| Example 2 | Exemplary Compound SI-3 | 13.5 | 5 | 0.1 | 9.7 × 10¹⁴ | 4 | 5 |
| Example 3 | Exemplary Compound SI-3 | 13.5 | 7.5 | 0.1 | 6.4 × 10¹⁴ | 4 | 5 |
| Example 4 | Exemplary Compound SI-3 | 13.5 | 10 | 0.1 | 4.5 × 10¹⁴ | 5 | 5 |
| Example 5 | Exemplary Compound SI-3 | 13.5 | 15 | 0.1 | 3.0 × 10¹⁴ | 5 | 5 |
| Example 6 | Exemplary Compound SI-3 | 13.5 | 20 | 0.1 | 5.1 × 10¹³ | 5 | 5 |
| Example 7 | Exemplary Compound SI-3 | 13.5 | 30 | 0.1 | 5.0 × 10¹² | 5 | 5 |
| Example 8 | Exemplary Compound SI-3 | 13.5 | 40 | 0.1 | 2.7 × 10¹¹ | 4 | 3 |
| Example 9 | Exemplary Compound SI-3 | 13.5 | 50 | 0.1 | 1.5 × 10¹⁰ | 3 | 2 |
| Comparative | Exemplary Compound SI-3 | 13.5 | 60 | 0.1 | 9.5 × 10⁹ | 1 | 1 |
| Example 3 | | | | | | | |
| Example 10 | Exemplary Compound SI-2 | 1.5 | 20 | 0.1 | 4.4 × 10¹⁵ | 3 | 5 |
| Example 11 | Exemplary Compound SI-5 | 10 | 20 | 0.1 | 8.2 × 10¹³ | 5 | 5 |
| Example 12 | Exemplary Compound SI-21 | 30 | 20 | 0.1 | 5.4 × 10¹⁵ | 4 | 5 |
| Example 13 | Mixture of Exemplary | 13.5 | 20 | 0.1 | 8.2 × 10¹³ | 5 | 5 |
| | Compound SI-3 and Exemplary | 10 | | | | | |
| | Compound SI-5 at mass ratio of 1:1 | | | | | | |
| Example 14 | Mixture of Exemplary Compound | 13.5 | 20 | 0.1 | 5.4 × 10¹⁵ | 4 | 5 |
| | SI-3, Exemplary Compound SI-5, | 10 | | | | | |
| | and Exemplary Compound | 30 | | | | | |
| | SI-21 at mass ratio of 1:1:1 | | | | | | |
| Example 15 | EMALEX110 | 10 | 2.5 | 0.1 | 3.9 × 10¹⁵ | 2 | 5 |
| Example 16 | EMALEX110 | 10 | 5 | 0.1 | 8.8 × 10¹⁴ | 3 | 5 |
| Example 17 | EMALEX110 | 10 | 7.5 | 0.1 | 6.8 × 10¹⁴ | 4 | 5 |
| Example 18 | EMALEX110 | 10 | 10 | 0.1 | 5.0 × 10¹⁴ | 5 | 5 |
| Example 19 | EMALEX110 | 10 | 15 | 0.1 | 3.4 × 10¹⁴ | 5 | 5 |
| Example 20 | EMALEX110 | 10 | 20 | 0.1 | 6.5 × 10¹³ | 5 | 5 |
| Example 21 | EMALEX110 | 10 | 30 | 0.1 | 7.9 × 10¹² | 5 | 5 |
| Example 22 | EMALEX110 | 10 | 40 | 0.1 | 5.3 × 10¹¹ | 4 | 4 |
| Example 23 | EMALEX110 | 10 | 50 | 0.1 | 2.6 × 10¹⁰ | 3 | 3 |
| Example 24 | EMALEX102 | 2 | 20 | 0.1 | 5.0 × 10¹⁵ | 2 | 4 |
| Example 25 | EMALEX105 | 5 | 20 | 0.1 | 3.3 × 10¹⁵ | 2 | 4 |
| Example 26 | EMALEX120 | 20 | 20 | 0.1 | 6.8 × 10¹³ | 5 | 5 |
| Example 27 | EMALEX130 | 30 | 20 | 0.1 | 6.5 × 10¹⁴ | 4 | 5 |
| Example 28 | Mixture of EMALEX110 and | 10 | 20 | 0.1 | 7.5 × 10¹³ | 5 | 5 |
| | EMALEX120 at mass ratio of 1:1 | 20 | | | | | |

TABLE 2

| | Additives in A layer such as surfactant | | | | Evaluation results | | | |
|---|---|---|---|---|---|---|---|---|
| | | | Amount added | Film | Surface | | | |
| | | | (% by massof total | thickness | resistance | Partial | | |
| Back sheet | | EO chain | amount of solid | of A layer | value | discharge | Adhering | |
| for solar cells | Compound | length | content in A layer) | (μm) | (Ω/□) | voltage | force of EVA | Notes |
| Comparative | Baytron | NA | 2.5 | 0.1 | 7.9 × 10¹⁴ | 1 | 4 | Conductive polymer |
| Example 4 | (polythiophene) | | | | | | | |
| Comparative | Baytron | NA | 40 | 0.1 | 7.9 × 10¹⁴ | 5 | 1 | Conductive polymer |
| Example 5 | (polythiophene) | | | | | | | |
| Comparative | Sodium alkyl | NA | 2.5 | 0.1 | 7.9 × 10¹⁴ | 1 | 4 | Anionic surfactant |
| Example 6 | naphthalene | | | | | | | |
| | sulfonate | | | | | | | |
| Comparative | Sodium alkyl | NA | 40 | 0.1 | 7 .9 × 10¹² | 5 | 1 | Anionic surfactant |
| Example 7 | naphthalene | | | | | | | |
| | sulfonate | | | | | | | |
| Comparative | DENTALL | NA | 2.5 | 0.1 | 7.9 × 10¹² | 1 | 3 | Conductive inorganic |
| Example 8 | WK-500 | | | | | | | material |
| Comparative | DENTALL | NA | 40 | 0.1 | 7.9 × 10¹⁰ | 4 | 1 | Conductive inorganic |
| Example 9 | WK-500 | | | | | | | material |
| Comparative | BONDEIP-PM | NA | 2.5 | 0.1 | 7 .9 × 10¹² | 2 | 4 | Cationic surfactant |
| Example 10 | | | | | | | | |
| Comparative | BONDEIP-PM | NA | 40 | 0.1 | 7.9 × 10¹⁰ | 5 | 1 | Cationic surfactant |
| Example 11 | | | | | | | | |
| Comparative | OLFINE | — | 0.1 | 0.1 | 8.1 × 10¹⁵ | 1 | 4 | Nonionic surfactant (having |
| Example 12 | EXP4150F | | | | | | | carbon-carbon triple bond) |
| Comparative | OLFINE | — | 2.5 | 0.1 | 7.5 × 10¹⁵ | 2 | 4 | Nonionic surfactant (having |
| Example 13 | EXP4150F | | | | | | | carbon-carbon triple bond) |
| Comparative | OLFINE | — | 40 | 0.1 | 9.0 × 10¹³ | 5 | 1 | Nonionic surfactant (having |
| Example 14 | EXP4150F | | | | | | | carbon-carbon triple bond) |
| Example 29 | Exemplary | 13.5 | 20 | 0.3 | 4.8 × 10¹⁴ | 5 | 5 | |
| | Compound SI-3 | | | | | | | |
| Example 30 | Exemplary | 13.5 | 20 | 0.5 | 1.0 × 10¹⁴ | 5 | 4 | |
| | Compound SI-3 | | | | | | | |
| Example 31 | Exemplary | 13.5 | 20 | 1.0 | 9.0 × 10¹³ | 5 | 3 | |
| | Compound SI-3 | | | | | | | |
| Example 32 | Exemplary | 13.5 | 20 | 1.5 | 2.2 × 10¹² | 5 | 2 | |
| | Compound SI-3 | | | | | | | |
| Example 33 | EMALEX110 | 10 | 20 | 0.3 | 3.9 × 10¹⁴ | 5 | 5 | |
| Example 34 | EMALEX110 | 10 | 20 | 0.5 | 2.1 × 10¹⁴ | 5 | 4 | |
| Example 35 | EMALEX110 | 10 | 20 | 1.0 | 7.5 × 10¹³ | 5 | 3 | |
| Example 36 | EMALEX110 | 10 | 20 | 1.5 | 3.0 × 10¹² | 5 | 2 | |
| Example 37 | Exemplary | 13.5 | 20 | 0.5 | 3.5 × 10¹⁵ | 4 | 5 | A layer (thickness: 0.1 μm) |
| | Compound SI-3 | — | — | 0.1 | | | | of Comparative Example |
| | (lower layer) | | | | | | | 1 provided |
| | None (surface | | | | | | | on surface of A |
| | layer) | | | | | | | layer of Example 30 |
| Example 38 | None (lower | — | — | 1.0 | 2.0 × 10¹³ | 5 | 5 | Intermediate layer 1 |
| | layer) | 10 | 20 | 0.5 | | | | (thickness: 1.0 μm) provided |
| | EMALEX110 | | | | | | | as lower layer between A |
| | (surface layer) | | | | | | | layer (surface layer) |
| | | | | | | | | of Example 34 |
| | | | | | | | | and PET supporter |
| Example 39 | None (lower | — | — | 1.0 | 2.0 × 10¹³ | 5 | 5 | Intermediate layer 2 (white, |
| | layer) | 10 | 20 | 0.5 | | | | thickness: 1.0 μm) provided |
| | EMALEX110 | | | | | | | as lower layer between |
| | (surface layer) | | | | | | | A layer (surface layer) |
| | | | | | | | | of Example 34 and |
| | | | | | | | | PET supporter |
| Example 40 | None (lower | — | — | 1.0 | 6.1 × 10¹² | 5 | 5 | Intermediate layer 3 (black, |
| | layer) | 10 | 20 | 0.50 | | | | thickness: 1.0 μm) provided |
| | EMALEX110 | | | | | | | as lower layer between |
| | (surface layer) | | | | | | | A layer (surface layer) |
| | | | | | | | | of Example 34 and |
| | | | | | | | | PET supporter |

From the above-described results it is found that, in the present examples, favorable results can be obtained in the evaluations of both the partial discharge voltage and the adhering force with the encapsulating material (EVA). On the basis of the above-described finding, it is found that the back sheet for solar cells of the present invention is capable of achieving both the improvement of the partial discharge voltage and the adhesiveness to the encapsulating material that encapsulates the solar cell element.

The description of the specific aspects of the present invention is provided for the purpose of description and explanation. There is no intention of limiting the present invention to the disclosed aspects or making the present invention exhaustive. Clearly, it is evident that a person skilled in the art can modify or transform the present invention to a significant extent. The aspects are simply selected in order to most appropriately describe the concept and actual applications of the present invention and aim to let other persons skilled in the art understand the present invention so that those persons can carry out a variety of aspects or transformations in order to make the present invention suitable for a specific use they have in their mind.

The descriptions disclosed in JP2013-078078, filed on Apr. 3, 2013, JP2013-169244, filed on Aug. 16, 2013, and JP2013-269889, filed on Dec. 26, 2013, are all incorporated herein by reference.

Publications, patent applications, and technical standards described in the present specification are, in a case in which those publications, patent applications, and technical standards are respectively designated as references or to be incorporated, all considered to be incorporated herein within the same restrictive ranges as the references. It is intended that the scope of the present invention is determined on the basis of the scope of the claims and their equivalents.

1. A back sheet for solar cells comprising:
a supporter; and
an A layer including at least a nonionic surfactant which has an ethylene glycol chain but does not have a carbon-carbon triple bond on at least one surface side of the supporter,
wherein a surface resistance value SR on the side provided with the A layer of the back sheet for solar cells is in a range of 1.0×10¹⁰Ω/□ to 5.5×10¹⁵Ω/□.

2. The back sheet for solar cells according to claim 1,
wherein the surface resistance value SR is in a range of 1.0×10¹¹Ω/□ to 1.0×10¹⁵Ω/□.

3. The back sheet for solar cells according to claim 1,
wherein the A layer is an outermost layer.

4. The back sheet for solar cells according to claim 1,
wherein the repetition number n of the ethylene glycol chain in the nonionic surfactant is in a range of 7 to 30.

5. The back sheet for solar cells according to claim 1,
wherein the repetition number n of the ethylene glycol chain in the nonionic surfactant is in a range of 10 to 20.

6. The back sheet for solar cells according to claim 1,
wherein the nonionic surfactant is at least one selected from a group consisting of nonionic surfactants represented by General Formula (SI) described below, nonionic surfactants represented by General Formula (SII) described below, nonionic surfactants represented by General Formula (SIII-A) described below, and nonionic surfactants represented by General Formula (SIII-B) described below: 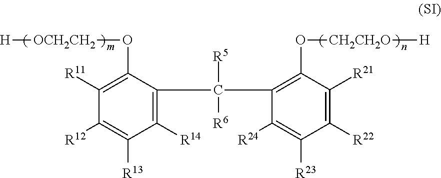
in General Formula (SI), each of R¹¹, R¹³, R²¹, and R²³ independently represents a substituted or unsubstituted alkyl group, aryl group, alkoxy group, halogen atom, acyl group, amide group, sulfonamide group, carbamoyl group, or sulfamoyl group, each of R¹², R¹⁴, R²², and R²⁴ independently represents a hydrogen atom or a substituted or unsubstituted alkyl group, aryl group, alkoxy group, halogen atom, acyl group, amide group, sulfonamide group, carbamoyl group, or sulfamoyl group, and each of R⁵ and R⁶ independently represents a hydrogen atom or a substituted or unsubstituted alkyl group or aryl group;
R¹¹ and R¹², R¹³ and R¹⁴, R²¹ and R²², R²³ and R²⁴, and R⁵ and R⁶ may be bonded to each other so as to form a substituted or unsubstituted ring; each of m and n independently represents the average repetition number of a polyoxyethylene chain and is a number from 2 to 50;
H₂ₘ₊₁Cₘ—O—(CH₂CH₂O)ₙ—H (SII):
in General Formula (SII), m represents an integer from 0 to 40, and n represents the average repetition number of the polyoxyethylene chain and is a number from 2 to 50; 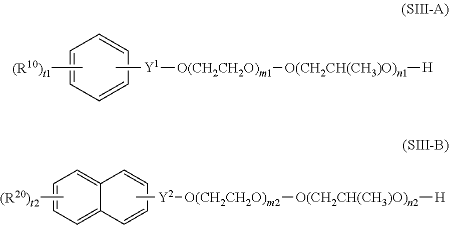
in General Formulae (SIII-A) and (SIII-B), each of R¹⁰ and R²⁰ independently represents a hydrogen atom or an organic group having 1 to 100 carbon atoms, each of t1 and t2 independently represents 1 or 2, each of Y¹ and Y² independently represents a single bond or an alkylene group having 1 to 10 carbon atoms, each of m1 and n1 independently represents 0 or a number from 1 to 100; here, m1 is not 0, and is not 1 in a case in which n1 is 0, and each of m2 and n2 independently represents 0 or a number from 1 to 100; here, m2 is not 0, and is not 1 in a case in which n2 is 0.

7. The back sheet for solar cells according to claim 6,
wherein each of R¹¹, R¹³, R²¹, and R²³ in General Formula (SI) independently represents a substituted or unsubstituted alkyl group, aryl group, or alkoxy group, m and n in General Formula (SII) respectively represent an integer from 0 to 20 and a number from 7 to 30, and each of R¹⁰ and R²⁰ in General Formula (SIII-A) and General Formula (SIII-B) is independently a hydrogen atom, a straight-chain or branched-chain alkyl group having 1 to 10 carbon atoms, an alkoxy group having 1 to 10 carbon atoms, an alkoxycarbonyl group, an N-alkylamino group, an N,N-dialkylamino group, an N-alkylcarbamoyl group, an acyloxy group, an acylamino group, a polyoxyalkylene chain having 5 to 20 repetition units, an aryl group having 6 to 20 carbon atoms, or an aryl group to which a polyoxyalkylene chain having 5 to 20 repetition units is bonded.

8. The back sheet for solar cells according to claim 7,
wherein the repetition number n of the ethylene glycol chain in the nonionic surfactant is in a range of 7 to 30.

9. The back sheet for solar cells according to claim 7,
wherein the repetition number n of the ethylene glycol chain in the nonionic surfactant is in a range of 10 to 20.

10. The back sheet for solar cells according to claim 7,
wherein the A layer is an outermost layer.

11. The back sheet for solar cells according to claim 8,
wherein the A layer is an outermost layer.

12. The back sheet for solar cells according to claim 9,
wherein the A layer is an outermost layer.

13. The back sheet for solar cells according to claim 1,
wherein a content of the nonionic surfactant in the A layer is in a range of 2.5% by mass to 50% by mass of the total amount of a solid content in the A layer.

14. The back sheet for solar cells according to claim 12,
wherein a content of the nonionic surfactant in the A layer is in a range of 2.5% by mass to 50% by mass of the total amount of a solid content in the A layer.

15. The back sheet for solar cells according to claim 1 further comprising:
an intermediate layer including a resin between the supporter and the A layer.

16. The back sheet for solar cells according to claim 14 further comprising:
an intermediate layer including a resin between the supporter and the A layer.

17. The back sheet for solar cells according to claim 15,
wherein the intermediate layer includes a white coloring material.

18. The back sheet for solar cells according to claim 15,
wherein the intermediate layer includes a black coloring material.

19. A solar cell module comprising:
a transparent base material on which sunlight is incident;
an element structure portion which is provided on the base material and has a solar cell element and an encapsulating material that encapsulates the solar cell element; and
the back sheet for solar cells according to claim 1 disposed on a side opposite to a side on which the base material of the element structure portion is located.

20. The back sheet for solar cells according to claim 19 further comprising:
an intermediate layer including a resin between the supporter and the A layer.
